(19) United States
(12) Patent Application Publication
(10) Pub. No.: US 2026/0323906 A1
(43) Pub. Date: Oct. 15, 2026

(54) SEMICONDUCTOR DEVICE AND METHOD FOR MANUFACTURING THE SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Hitoshi KUNITAKE, Machida (JP); Hajime KIMURA, Atsugi (JP); Tsutomu MURAKAWA, Isehara (JP)

(21) Appl. No.: 19/484,977

(22) PCT Filed: May 20, 2024
(86) PCT No.: PCT/IB2024/054866

§ 371 Date: Nov. 17, 2025

(30) Foreign Application Priority Data
May 25, 2023 (JP) 2023-086439

(51) Int. Cl. H10B 12/00

(52) U.S. Cl. CPC H10B 12/00

(57) ABSTRACT

A semiconductor device that operates at high speed is provided. The semiconductor device includes a first transistor and a second transistor over the first transistor. The first transistor includes a first to a third conductive layer. The second transistor includes the third to a fifth conductive layer. Insulating layers are provided between the first conductive layer and the second conductive layer and between the third conductive layer and the fourth conductive layer. An opening portion reaching the first conductive layer and an opening portion reaching the third conductive layer are provided in the insulating layers. The first and the third conductive layer each include a depressed portion reaching the opening portion. Semiconductor layers are provided in contact with the depressed portions. The third conductive layer includes a region facing the semiconductor layer with a gate insulating layer of the first transistor therebetween in the opening portion reaching the first conductive layer. The fifth conductive layer includes a region facing a semiconductor layer with a gate insulating layer of the second transistor therebetween in the opening portion reaching the third conductive layer.

### TECHNICAL FIELD

One embodiment of the present invention relates to a semiconductor device, a memory device, and an electronic apparatus. One embodiment of the present invention also relates to a method for manufacturing the semiconductor device.

Note that one embodiment of the present invention is not limited to the above technical field. Examples of the technical field of one embodiment of the present invention include a semiconductor device, a display apparatus, a light-emitting apparatus, a power storage device, a memory device, an electronic apparatus, a lighting device, an input device (e.g., a touch sensor), an input/output device (e.g., a touch panel), a method for driving any of them, and a method for manufacturing any of them.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display apparatus, a light-emitting apparatus, a lighting device, and an electronic apparatus themselves are semiconductor devices and also include a semiconductor device.

### BACKGROUND ART

In recent years, semiconductor devices have been developed, and an LSI (Large Scale Integration), a CPU (Central Processing Unit), a memory, and the like are mainly used as the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic apparatuses.

A technique by which a transistor is formed using a thin semiconductor film formed over a substrate having an insulating surface has been attracting attention. The transistor is used in a wide range of electronic devices such as an integrated circuit (IC) and a display apparatus. A silicon-based semiconductor material is widely known as a thin semiconductor film applicable to a transistor, and an oxide semiconductor has been attracting attention as another material.

A transistor including an oxide semiconductor is known to have an extremely low leakage current in an off state. For example, Patent Document 1 discloses a low-power-consumption CPU utilizing a characteristic of a low leakage current of the transistor including an oxide semiconductor. Furthermore, for example, Patent Document 2 discloses a memory device and the like that can retain stored data for a long time by utilizing a characteristic of a low leakage current of the transistor including an oxide semiconductor.

In recent years, demand for an integrated circuit with higher density has risen with reductions in size and weight of electronic apparatuses. In addition, the productivity of a semiconductor device including an integrated circuit is desired to be improved. For example, Patent Document 3 and Non-Patent Document 1 disclose a technique to achieve an integrated circuit with higher density by making a plurality of memory cells overlap with each other by stacking a first transistor including an oxide semiconductor film and a second transistor including an oxide semiconductor film. Patent Document 4 discloses a technique for achieving an integrated circuit with higher density by placing a channel of a transistor including an oxide semiconductor film in the vertical direction.

### REFERENCES

### Patent Documents

[Patent Document 1] Japanese Published Patent Application No. 2012-257187

[Patent Document 2] Japanese Published Patent Application No. 2011-151383

[Patent Document 3] PCT International Publication No. 2021/053473

[Patent Document 4] Japanese Published Patent Application No. 2013-211537

### [Non-Patent Document]

[Non-Patent Document 1] M. Oota, et al., “3D-Stacked CAAC-In-Ga-Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device with a high operation speed. Another object of one embodiment of the present invention is to provide a low-cost semiconductor device. Another object of one embodiment of the present invention is to provide a semiconductor device that can be miniaturized or highly integrated. Another object of one embodiment of the present invention is to provide a semiconductor device including a transistor with favorable electrical characteristics. Another object of one embodiment of the present invention is to provide a semiconductor device including a transistor with a high on-state current. Another object of one embodiment of the present invention is to provide a semiconductor device with high reliability. Another object of one embodiment of the present invention is to provide a low-power-consumption semiconductor device. Another object of one embodiment of the present invention is to provide a novel semiconductor device. Another object of one embodiment of the present invention is to provide a method for manufacturing the semiconductor device.

Note that the description of these objects does not preclude the existence of other objects. One embodiment of the present invention does not necessarily achieve all of these objects. Other objects can be derived from the description of the specification, the drawings, and the claims.

### Means for Solving the Problems

A semiconductor device includes a first transistor, a second transistor, a first insulating layer, a second insulating layer, and a third insulating layer. The first transistor includes a first semiconductor layer, a first conductive layer, a second conductive layer, a third conductive layer, and a fourth insulating layer. The second transistor includes a second semiconductor layer, the third conductive layer, a fourth conductive layer, a fifth conductive layer, and a fifth insulating layer. The first insulating layer is located over the first conductive layer. The second conductive layer is located over the first insulating layer. The first conductive layer includes a first depressed portion. The first insulating layer and the second conductive layer include a first opening portion in a position overlapping with the first depressed portion. The first semiconductor layer is in contact with the top surface of the second conductive layer and the first depressed portion and is in contact with the side surface of the second conductive layer and the side surface of the first insulating layer in the first opening portion. The fourth insulating layer includes a region located over the second conductive layer and a region located over the first semiconductor layer in the first opening portion. The third conductive layer includes a region facing the first semiconductor layer with the fourth insulating layer therebetween in the first opening portion. The third conductive layer includes a region overlapping with the second conductive layer with the fourth insulating layer therebetween. The third conductive layer includes a second depressed portion. The second insulating layer is located over the third conductive layer. The fourth conductive layer is located over the second insulating layer. The second insulating layer and the fourth conductive layer include a second opening portion in a position overlapping with the second depressed portion. The second semiconductor layer is in contact with the top surface of the fourth conductive layer and the second depressed portion and is in contact with the side surface of the fourth conductive layer and the side surface of the second insulating layer in the second opening portion. The fifth insulating layer is located over the second semiconductor layer in the second opening portion. The third insulating layer includes a region overlapping with the fourth conductive layer with the second semiconductor layer therebetween and includes a third opening portion in a position overlapping with the second opening portion. The fifth conductive layer includes a region facing the second semiconductor layer with the fifth insulating layer therebetween in the second opening portion and a region located in the third opening portion.

In the above embodiment, at least part of the second opening portion may overlap with the first opening portion.

In the above embodiment, the semiconductor device may include a sixth insulating layer. The first insulating layer and the first conductive layer may be located over the sixth insulating layer. A shortest distance from the top surface of the sixth insulating layer to the top surface of the first conductive layer that is in contact with the first insulating layer may be longer than a shortest distance from the top surface of the sixth insulating layer to the bottom surface of the fourth insulating layer in a region overlapping with the first depressed portion. A shortest distance from the top surface of the sixth insulating layer to the top surface of the third conductive layer that is in contact with the second insulating layer and overlaps with the second conductive layer may be longer than a shortest distance from the top surface of the sixth insulating layer to the bottom surface of the fifth insulating layer in a region overlapping with the second depressed portion.

In the above embodiment, the semiconductor device may include a sixth insulating layer. The first insulating layer and the first conductive layer may be located over the sixth insulating layer. A shortest distance from the top surface of the sixth insulating layer to the top surface of the first conductive layer that is in contact with the first insulating layer may be longer than or equal to a shortest distance from the top surface of the sixth insulating layer to the bottom surface of the third conductive layer in a region overlapping with the first depressed portion. A shortest distance from the top surface of the sixth insulating layer to the top surface of the third conductive layer that is in contact with the second insulating layer and overlaps with the second conductive layer may be longer than or equal to a shortest distance from the top surface of the sixth insulating layer to the bottom surface of the fifth conductive layer in a region overlapping with the second depressed portion.

In the above embodiment, the first conductive layer may include a sixth conductive layer and a seventh conductive layer over the sixth conductive layer. The third conductive layer may include an eighth conductive layer and a ninth conductive layer over the eighth conductive layer. The seventh conductive layer may include the first depressed portion. The ninth conductive layer may include the second depressed portion.

In the above embodiment, the semiconductor device may include a sixth conductive layer. The sixth conductive layer may be provided in contact with the top surface of the fifth conductive layer.

In the above embodiment, a thickness of the third insulating layer in a region overlapping with the fourth conductive layer and the second semiconductor layer may be greater than a thickness of the fourth insulating layer.

In the above embodiment, at least part of the fifth insulating layer may be located in the third opening portion.

In the above embodiment, the first transistor may include a sixth conductive layer. The second transistor may include a seventh conductive layer. The first insulating layer may include a first layer and a second layer over the first layer. The second insulating layer may include a third layer and a fourth layer over the third layer. The sixth conductive layer may be located over the first layer. The seventh conductive layer may be located over the third layer. The second layer covers the top surface and the side surface of the sixth conductive layer. The fourth layer covers the top surface and the side surface of the seventh conductive layer. In a cross-sectional view, the first semiconductor layer may include a region facing the sixth conductive layer with the second layer therebetween and facing the third conductive layer with the fourth insulating layer therebetween. In a cross-sectional view, the second semiconductor layer may include a region facing the seventh conductive layer with the fourth layer therebetween and facing the fifth conductive layer with the fifth insulating layer therebetween.

In the above embodiment, each of the first semiconductor layer and the second semiconductor layer may include an oxide semiconductor. The oxide semiconductor may include one or more selected from indium, an element M, and zinc. The element M may be one or more kinds selected from aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony.

In the above embodiment, the first insulating layer may include a first region in contact with the first semiconductor layer. The second insulating layer may include a second region in contact with the second semiconductor layer. Each of the first region and the second region may include a halogen element.

In the above embodiment, the halogen element may be one or more kinds selected from chlorine, fluorine, bromine, and iodine.

In the above embodiment, the first semiconductor layer may include a first region in contact with the bottom surface of the first depressed portion and a second region in contact with the top surface of the second conductive layer. The second semiconductor layer may include a third region in contact with the bottom surface of the second depressed portion and a fourth region in contact with the top surface of the fourth conductive layer. Each of the first to fourth regions may include boron or phosphorus.

Another embodiment of the present invention is a method for manufacturing a semiconductor device, including: forming a first conductive layer; forming a first insulating layer over the first conductive layer; forming a second conductive layer over the first insulating layer; forming a first opening portion in the second conductive layer and the first insulating layer in a position overlapping with the first conductive layer, and forming a first depressed portion in the first conductive layer so as to overlap with the first opening portion; forming a first semiconductor layer so as to be in contact with the top surface of the second conductive layer and the first depressed portion and in contact with the side surface of the second conductive layer and the side surface of the first insulating layer in the first opening portion; processing the first semiconductor layer and the second conductive layer to expose part of the top surface of the first insulating layer; forming a second insulating layer so as to include a region located over the second conductive layer and a region located over the first semiconductor layer in the first opening portion; forming a third conductive layer so as to include a region facing the first semiconductor layer with the second insulating layer therebetween in the first opening portion and a region overlapping with the second conductive layer with the second insulating layer therebetween; forming a third insulating layer over the third conductive layer; forming a fourth conductive layer over the third insulating layer; forming a second opening portion in the fourth conductive layer and the third insulating layer in a position overlapping with the third conductive layer, and forming a second depressed portion in the third conductive layer so as to overlap with the second opening portion; forming a second semiconductor layer so as to be in contact with the top surface of the fourth conductive layer and the second depressed portion and in contact with the side surface of the fourth conductive layer and the side surface of the third insulating layer in the second opening portion; processing the second semiconductor layer and the fourth conductive layer to expose part of the top surface of the third insulating layer; forming a sacrificial layer such that at least part of which is located in the second opening portion; forming a fourth insulating layer so as to cover the fourth conductive layer, the second semiconductor layer, and the sacrificial layer; performing planarization treatment on the fourth insulating layer and the sacrificial layer to planarize the top surface of the sacrificial layer; removing the sacrificial layer; forming a fifth insulating layer so as to cover the second opening portion; forming a fifth conductive layer over the fifth insulating layer; and performing planarization treatment on the fifth conductive layer to remove regions of the fifth conductive layer and the fifth insulating layer that overlap with the top surface of the fourth insulating layer.

In the above embodiment, the second opening portion may be formed such that at least part of the second opening portion overlaps with the first opening portion.

In the above embodiment, a sixth conductive layer may be formed so as to be in contact with the top surface of the fifth conductive layer.

In the above embodiment, the fourth insulating layer may be formed to have a thickness greater than that of the second insulating layer.

### Effect of the Invention

According to one embodiment of the present invention, a semiconductor device with a high operation speed can be provided. According to one embodiment of the present invention, a low-cost semiconductor device can be provided. According to one embodiment of the present invention, a semiconductor device that can be miniaturized or highly integrated can be provided. According to one embodiment of the present invention, a semiconductor device including a transistor with favorable electrical characteristics can be provided. According to one embodiment of the present invention, a semiconductor device including a transistor with a high on-state current can be provided. According to one embodiment of the present invention, a semiconductor device with high reliability can be provided. According to one embodiment of the present invention, a low-power-consumption semiconductor device can be provided. According to one embodiment of the present invention, a novel semiconductor device can be provided. According to one embodiment of the present invention, a method for manufacturing the semiconductor device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A to FIG. 1C are circuit diagrams each illustrating an example of a memory cell. FIG. 1D and FIG. 1E are plan views illustrating an example of a semiconductor device. FIG. 1F and FIG. 1G are cross-sectional views illustrating an example of the semiconductor device.

FIG. 2A is a cross-sectional view illustrating an example of a semiconductor device. FIG. 2B is a plan view illustrating an example of the semiconductor device.

FIG. 3A to FIG. 3D are diagrams illustrating a concept of heat treatment.

FIG. 4A and FIG. 4B are cross-sectional views each illustrating an example of a semiconductor device.

FIG. 5A and FIG. 5B are plan views illustrating an example of a semiconductor device. FIG. 5C and FIG. 5D are cross-sectional views illustrating an example of a semiconductor device.

FIG. 6A and FIG. 6B are cross-sectional views illustrating an example of a semiconductor device.

FIG. 7A and FIG. 7B are cross-sectional views illustrating an example of a semiconductor device.

FIG. 8A and FIG. 8B are cross-sectional views illustrating an example of a semiconductor device.

FIG. 9A and FIG. 9B are cross-sectional views illustrating an example of a semiconductor device.

FIG. 10A and FIG. 10B are cross-sectional views illustrating an example of a semiconductor device.

FIG. 11A and FIG. 11B are plan views illustrating an example of a semiconductor device. FIG. 11C and FIG. 11D are cross-sectional views illustrating an example of a semiconductor device.

FIG. 12A to FIG. 12F are cross-sectional views illustrating an example of a method for manufacturing a semiconductor device.

FIG. 13A to FIG. 13D are cross-sectional views illustrating an example of a method for manufacturing a semiconductor device.

FIG. 14A to FIG. 14D are cross-sectional views illustrating an example of a method for manufacturing a semiconductor device.

FIG. 15A to FIG. 15E are cross-sectional views illustrating an example of a method for manufacturing a semiconductor device.

FIG. 16A is a plan view illustrating an example of a memory device. FIG. 16B is a cross-sectional view illustrating an example of the memory device.

FIG. 17 is a cross-sectional view illustrating an example of a memory device.

FIG. 18 is a cross-sectional view illustrating an example of a memory device.

FIG. 19 is a block diagram illustrating a structure example of a semiconductor device.

FIG. 20A and FIG. 20B are perspective views illustrating examples of a semiconductor device.

FIG. 21 is a block diagram illustrating a CPU.

FIG. 22A and FIG. 22B are perspective views illustrating an example of a semiconductor device.

FIG. 23A and FIG. 23B are perspective views illustrating an example of a semiconductor device.

FIG. 24A and FIG. 24B each illustrate a hierarchy of various kinds of memory devices.

FIG. 25A and FIG. 25B illustrate examples of an electronic component.

FIG. 26A to FIG. 26C illustrate examples of large computers. FIG. 26D illustrates an example of a device for space. FIG. 26E illustrates an example of a storage system that can be used in a data center.

### MODE FOR CARRYING OUT THE INVENTION

Embodiments will be described in detail with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each structure illustrated in drawings is not accurately represented in some cases for easy understanding. Therefore, the disclosed invention is not necessarily limited to the position, size, range, or the like disclosed in the drawings.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

A transistor is a kind of semiconductor element and enables amplification of a current or a voltage, switching operation for controlling conduction or non-conduction, and the like. A transistor in this specification includes, in its category, an insulated-gate field effect transistor (IGFET) and a thin film transistor (TFT).

In this specification and the like, a transistor including an oxide semiconductor or a metal oxide in its semiconductor layer and a transistor including an oxide semiconductor or a metal oxide in its channel formation region are each sometimes referred to as an OS transistor. Also, a transistor including silicon in its channel formation region is sometimes referred to as a Si transistor.

In this specification and the like, a transistor is an element including at least three terminals of a gate, a drain, and a source. The transistor includes a region where a channel is formed (also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that impurities in a semiconductor refer to, for example, elements other than the main components of the semiconductor. For example, an element with a concentration of lower than 0.1 atomic % is an impurity. When a semiconductor contains an impurity, an increase in density of defect states or a reduction in crystallinity of the semiconductor may occur, for example. In the case where the semiconductor is an oxide semiconductor, examples of an impurity that changes the characteristics of the semiconductor include Group 1 elements, Group 2 elements, Group 13elements, Group 14 elements, Group 15 elements, and transition metals other than the main components of the oxide semiconductor. Specific examples include hydrogen, lithium, sodium, silicon, boron, phosphorus, carbon, and nitrogen. Note that water also serves as an impurity in some cases. Entry of an impurity may cause oxygen vacancies (also referred to as Vo) in an oxide semiconductor, for example.

Note that in this specification and the like, an oxynitride refers to a material in which an oxygen content is higher than a nitrogen content. A nitride oxide refers to a material in which a nitrogen content is higher than an oxygen content.

The content of an element such as hydrogen, oxygen, carbon, or nitrogen in a film can be analyzed by secondary ion mass spectrometry (SIMS) or X-ray photoelectron spectroscopy (XPS), for example. XPS is suitable when the content of a target element is high (e.g., higher than or equal to 0.5 atomic %, or higher than or equal to 1 atomic %). In contrast, SIMS is suitable when the content of a target element is low (e.g., lower than or equal to 0.5 atomic %, or lower than or equal to 1 atomic %). To compare the contents of elements, analysis with a combination of SIMS and XPS is preferably used.

Note that the terms “film” and “layer” can be used interchangeably depending on the case or the circumstances. For example, the term “conductive layer” can be replaced with the term “conductive film”. As another example, the term “insulating film” can be replaced with the term “insulating layer”.

In this specification and the like, the term “parallel” indicates that the angle formed between two straight lines is greater than or equal to −10° and less than or equal to 10°. Thus, the case where the angle is greater than or equal to −5°and less than or equal to 5° is also included. The term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°. Thus, the case where the angle is greater than or equal to 85° and less than or equal to 95° is also included. In addition, the term “substantially perpendicular” indicates that the angle formed between two straight lines is greater than or equal to 60° and less than or equal to 120°.

In this specification and the like, the term “electrically connected” includes the case where components are connected to each other through an object having any electric function. There is no particular limitation on an “object having any electric function” as long as electric signals can be transmitted and received between components that are connected through the object. Examples of the “object having any electric function” are a switching element such as a transistor, a resistor, a coil, and an element with a variety of functions as well as an electrode and a wiring.

Unless otherwise specified, an off-state current in this specification and the like refers to a leakage current between a source and a drain generated when a transistor is in an off state (also referred to as a non-conducting state or a cutoff state). Unless otherwise specified, the off state of an n-channel transistor means that a gate-source voltage V_{gs} is lower than a threshold voltage Vth (the off state of a p-channel transistor means that V_{gs} is higher than Vth).

Note that “normally-on” in this specification and the like means a state where a channel exists and a current flows through a transistor even when no voltage is applied to a gate. Furthermore, “normally-off” means a state where a current does not flow through a transistor when no potential or a ground potential is applied to a gate.

Note that in this specification and the like, a tapered shape refers to a shape such that at least part of a side surface of a component is inclined with respect to a substrate surface or a formation surface of the component. For example, a tapered shape preferably includes a region where the angle between the inclined side surface and the substrate surface or the formation surface (such an angle is also referred to as a taper angle) is greater than 0° and less than 90°. Note that the side surface of the component, the substrate surface, and the formation surface are not necessarily completely flat and may be substantially flat with a slight curvature or with slight unevenness.

In this specification and the like, when the expression “A is located over B” is used, at least part of A is located over B. In other words, A includes a region located over B, for example. Similarly, when the expression “A is in contact with B” or “A overlaps with B” is used, at least part of A is in contact with or overlaps with B. In other words, A includes a region in contact with B or A includes a region overlapping with B, for example. Similarly, in this specification and the like, when the expression “A covers B” is used, at least part of A covers B. In other words, A includes a region covering B, for example.

For example, in the drawings for this specification, arrows indicating an X direction, a Y direction, and a Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other.

### Embodiment 1

In this embodiment, a semiconductor device of one embodiment of the present invention and a method for manufacturing the semiconductor device will be described with reference to drawings.

The semiconductor device of one embodiment of the present invention is a memory device provided with a memory cell including a first transistor and a second transistor over the first transistor. The semiconductor device of one embodiment of the present invention includes a first insulating layer, a second insulating layer, and a third insulating layer in addition to the first and second transistors.

The first transistor includes a first semiconductor layer, a first conductive layer, a second conductive layer, a third conductive layer, and a fourth insulating layer. The second transistor includes a second semiconductor layer, the third conductive layer, a fourth conductive layer, a fifth conductive layer, and a fifth insulating layer.

The first conductive layer functions as one of the source electrode and the drain electrode of the first transistor. The second conductive layer functions as the other of the source electrode and the drain electrode of the first transistor. The third conductive layer functions as the gate electrode of the first transistor and one of the source electrode and the drain electrode of the second transistor. The fourth conductive layer functions as the other of the source electrode and the drain electrode of the second transistor. The fifth conductive layer functions as the gate electrode of the second transistor. The fourth insulating layer functions as the gate insulating layer of the first transistor. The fifth insulating layer functions as the gate insulating layer of the second transistor.

The first insulating layer is provided between the first conductive layer and the second conductive layer. A first opening portion reaching the first conductive layer is provided in the first insulating layer and the second conductive layer. The first semiconductor layer is in contact with the top surface of the first conductive layer, the side surface of the second conductive layer, and the side surface of the first insulating layer in the first opening portion. The first semiconductor layer is in contact with the top surface of the second conductive layer. The fourth insulating layer includes a region located over the first semiconductor layer in the first opening portion. The third conductive layer includes a region facing the first semiconductor layer with the fourth insulating layer therebetween in the first opening portion.

The second insulating layer is provided between the third conductive layer and the fourth conductive layer. A second opening portion reaching the third conductive layer is provided in the second insulating layer and the fourth conductive layer. The second semiconductor layer is in contact with the top surface of the third conductive layer, the side surface of the fourth conductive layer, and the side surface of the second insulating layer in the second opening portion. The second semiconductor layer is in contact with the top surface of the fourth conductive layer. The fifth insulating layer includes a region located over the second semiconductor layer in the second opening portion. The fifth conductive layer includes a region facing the second semiconductor layer with the fifth insulating layer therebetween in the second opening portion.

In the semiconductor device of one embodiment of the present invention, a first depressed portion is provided in the first conductive layer, and a second depressed portion is provided in the second conductive layer. Thus, the level of the bottom surface of the fourth insulating layer and the level of the bottom surface of the third conductive layer in the first opening portion can be low as compared with the case where the first depressed portion is not provided in the first conductive layer. Similarly, the level of the bottom surface of the fifth insulating layer and the level of the bottom surface of the fifth conductive layer in the second opening portion can be low as compared with the case where the second depressed portion is not provided in the third conductive layer.

This facilitates application of gate electric fields to the first semiconductor layer and the second semiconductor layer. Thus, the electrical characteristics of the first transistor and the second transistor can be improved. For example, the on-state currents of the first transistor and the second transistor can be increased. Thus, the semiconductor device of one embodiment of the present invention can be a semiconductor device with a high operation speed.

In the semiconductor device of one embodiment of the present invention, the fourth insulating layer functioning as the gate insulating layer of the first transistor is provided to cover the first semiconductor layer and the second conductive layer. The third conductive layer functioning as the gate electrode of the first transistor is provided to include a region overlapping with the second conductive layer with the fourth insulating layer therebetween. Thus, in the semiconductor device of one embodiment of the present invention, capacitance is formed in which the fourth insulating layer serves as a dielectric layer and the second conductive layer and the third conductive layer serve as a pair of electrodes. Thus, in the semiconductor device of one embodiment of the present invention, data can be retained even when a capacitor is not formed in the memory cell. Thus, the number of manufacturing processes in the semiconductor device of one embodiment of the present invention can be smaller than that in the case where a capacitor is formed in the memory cell. Accordingly, the semiconductor device of one embodiment of the present invention can be a low-cost semiconductor device. By not forming a capacitor in the memory cell, the area occupied by the memory cell can be reduced in some cases. In that case, the semiconductor device of one embodiment of the present invention can be a semiconductor device that can be miniaturized or highly integrated.

Furthermore, in the semiconductor device of one embodiment of the present invention, the third insulating layer is provided over the second semiconductor layer to include a region overlapping with the fourth conductive layer functioning as the other of the source electrode and the drain electrode of the second transistor. In other words, the third insulating layer is provided to include a region overlapping with the fourth conductive layer with the second semiconductor layer therebetween. The third insulating layer includes a third opening portion in a position overlapping with the second opening portion. The fifth conductive layer is provided in the third opening portion. A sixth conductive layer is provided to be in contact with the top surface of the third insulating layer and the top surface of the fifth conductive layer functioning as the gate electrode of the second transistor. The sixth conductive layer functions as a gate wiring.

In the second transistor, the third insulating layer is provided between the fourth conductive layer and the sixth conductive layer. Here, the thickness of the third insulating layer, for example, the thickness of the third insulating layer in a region overlapping with the fourth conductive layer and the second semiconductor layer is larger than the thickness of the fourth insulating layer functioning as the gate insulating layer of the first transistor. Thus, the parasitic capacitance between the fourth conductive layer and the sixth conductive layer can be smaller than the parasitic capacitance between the second conductive layer and the third conductive layer.

In the above manner, the second transistor can be a transistor with favorable electrical characteristics. For example, the second transistor can be a transistor that operates at high speed. Thus, the semiconductor device of one embodiment of the present invention can be a semiconductor device including a transistor with favorable electrical characteristics.

Note that a groove (slit) may be provided instead of the opening portion in the semiconductor device of one embodiment of the present invention.

In the transistor of one embodiment of the present invention, the source electrode and the drain electrode are located at different levels, and a current flows in the height direction in the semiconductor layer. In other words, the channel length direction can be regarded as including a height (vertical) component; thus, the transistor of one embodiment of the present invention can also be referred to as a vertical field effect transistor (VFET), a vertical transistor, a vertical-channel transistor, a vertical-channel-type transistor, or the like.

In the transistor of one embodiment of the present invention, the source electrode, the semiconductor layer, and the drain electrode can be provided to overlap with each other. Thus, the area occupied by the transistor can be significantly smaller than that occupied by what is called a planar transistor, in which a planar semiconductor layer is provided.

### Structure Example 1 of Semiconductor Device

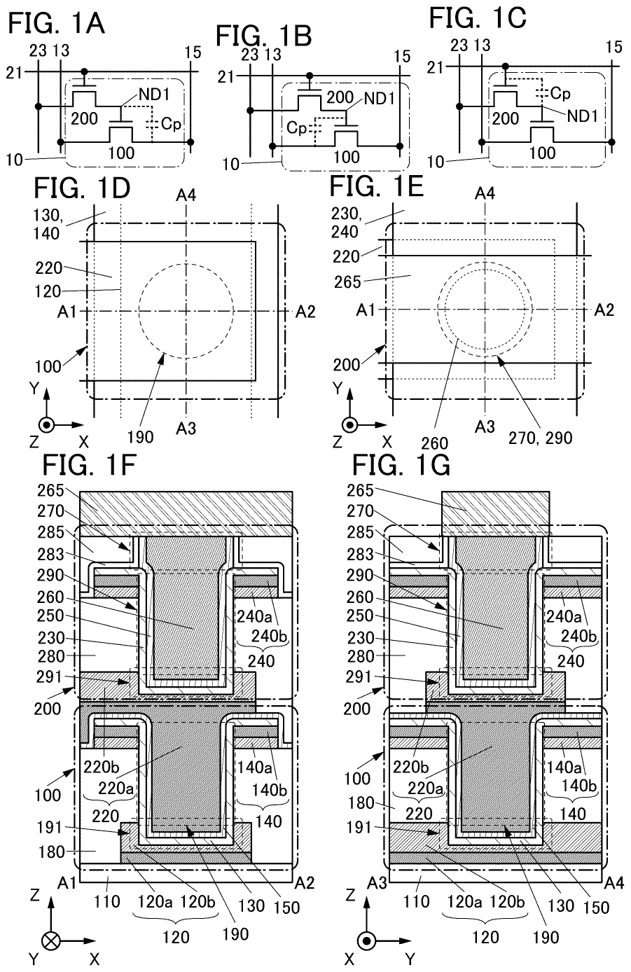

FIG. 1A is a circuit diagram illustrating a structure example of a memory cell 10 included in the semiconductor device of one embodiment of the present invention. The memory cell 10 includes a transistor 100 and a transistor 200.

One of the source and the drain of the transistor 100 is electrically connected to a wiring 13. The other of the source and the drain of the transistor 100 is electrically connected to a wiring 15. The gate of the transistor 100 is electrically connected to one of the source and the drain of the transistor 200. The other of the source and the drain of the transistor 200 is electrically connected to a wiring 23. The gate of the transistor 200 is electrically connected to a wiring 21. Here, a node where the gate of the transistor 100 and the one of the source and the drain of the transistor 200 are connected is referred to as a node ND1.

Capacitance Cp is formed between the electrode functioning as the other of the source and the drain of the transistor 100 and the electrode functioning as the gate of the transistor 100 and the one of the source and the drain of the transistor 200, which will be described later in detail.

The wiring 21 functions as a word line. A signal for controlling the on/off state of the transistor 200 is supplied to the wiring 21.

The wiring 23 functions as a bit line. A data signal to be supplied to the memory cell 10 is supplied to the wiring 23. When the transistor 200 is turned on, data corresponding to the potential of the wiring 23 is written to the memory cell 10. When the transistor 200 is turned off, the data written to the memory cell 10 is retained. Specifically, the potential of the node ND1 is retained.

The wiring 13 functions as a bit line. The wiring 15 functions as a power supply line and is supplied with a power supply potential. When data is written to the memory cell 10 as described above, the potential of the node ND1 becomes a potential corresponding to the data. A current with a level corresponding to the potential of the node ND1 flows between the wiring 15 and the wiring 13. Thus, the potential of the wiring 13 becomes a potential corresponding to the data retained in the memory cell 10. Through the above operation, the data retained in the memory cell 10 can be read. This reading can be non-destructive reading.

In the above manner, data is written to the memory cell 10 through the wiring 23, and the data retained in the memory cell 10 is read through the wiring 13. Therefore, the wiring 23 can be referred to as a write bit line, and the wiring 13 can be referred to as a read bit line.

FIG. 1B and FIG. 1C are circuit diagrams each illustrating a structure example of the memory cell 10 and each illustrate an example in which the position of the capacitance Cp is different from that of the memory cell 10 illustrated in FIG. 1A. FIG. 1B illustrates an example in which the capacitance Cp is formed between the electrode functioning as the one of the source and the drain of the transistor 100 and the electrode functioning as the gate of the transistor 100 and the one of the source and the drain of the transistor 200. FIG. 1C illustrates an example in which the capacitance Cp is formed between the electrode functioning as the gate of the transistor 200 and the electrode functioning as the gate of the transistor 100 and the one of the source and the drain of the transistor 200.

FIG. 1D is a plan view illustrating a structure example of the transistor 100. FIG. 1E is a plan view illustrating a structure example of the transistor 200. The plan views in FIG. 1D and FIG. 1E can each be regarded as illustrating the structure example of the XY plane. Note that for simplification, some components are not illustrated in the plan views in FIG. 1D and FIG. 1E. The same applies to the other plan views.

FIG. 1F is a cross-sectional view along the dashed-dotted line A1-A2 in FIG. 1D and FIG. 1E. FIG. 1G is a cross-sectional view along the dashed-dotted line A3-A4 in FIG. 1D and FIG. 1E. FIG. 1F can be regarded as illustrating a structure example of the XZ plane. FIG. 1G can be regarded as illustrating a structure example of the YZ plane.

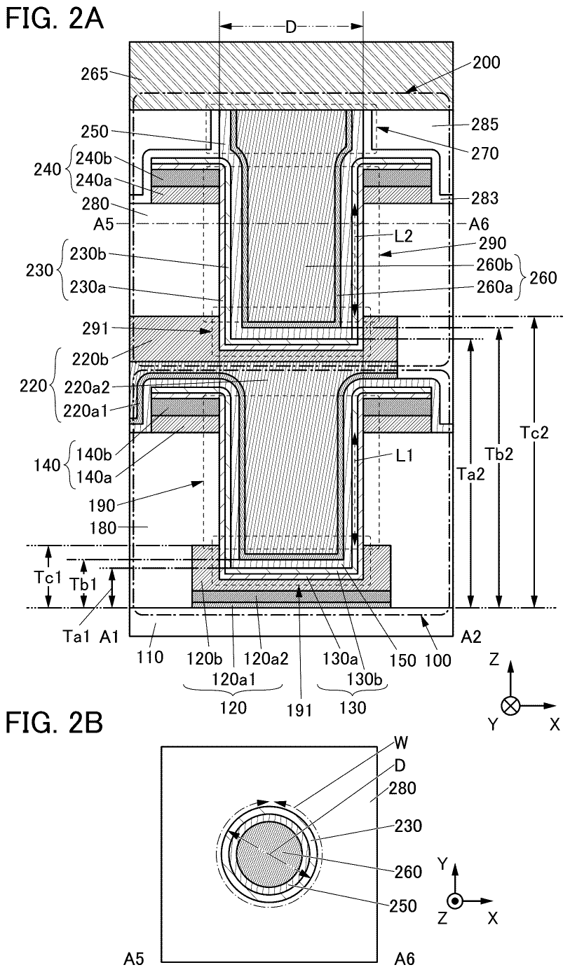

FIG. 2A is a cross-sectional view along the dashed-dotted line A1-A2 in FIG. 1D and FIG. 1E and is an enlarged view of FIG. 1F. FIG. 2B is a plan view illustrating a structure example of a cross section along the dashed-dotted line A5-A6 in FIG. 2A.

The semiconductor device illustrated in FIG. 1D to FIG. 1G, FIG. 2A, and FIG. 2B includes an insulating layer 110 over a substrate (not illustrated), the transistor 100 and an insulating layer 180 over the insulating layer 110, the transistor 200 and an insulating layer 280 over the transistor 100 and the insulating layer 180, an insulating layer 283 over the transistor 200 and the insulating layer 280, an insulating layer 285 over the insulating layer 283, and a conductive layer 265 over the transistor 200 and the insulating layer 285. The insulating layer 110, the insulating layer 180, the insulating layer 280, the insulating layer 283, and the insulating layer 285 each function as an interlayer film.

The transistor 100 includes a conductive layer 120, a conductive layer 140 over the insulating layer 180, a semiconductor layer 130, an insulating layer 150 over the semiconductor layer 130, and a conductive layer 220 over the insulating layer 150. The conductive layer 120 includes a conductive layer 120a and a conductive layer 120b over the conductive layer 120a. The conductive layer 140 includes a conductive layer 140a and a conductive layer 140b over the conductive layer 140a. The conductive layer 220 includes a conductive layer 220a and a conductive layer 220b over the conductive layer 220a.

The transistor 200 includes the conductive layer 220, a conductive layer 240 over the insulating layer 280, a semiconductor layer 230, an insulating layer 250 over the semiconductor layer 230, and a conductive layer 260 over the insulating layer 250. The conductive layer 240 includes a conductive layer 240a and a conductive layer 240b over the conductive layer 240a. Note that the conductive layer 120, the conductive layer 140, the conductive layer 220, and the conductive layer 240 may each have a single-layer structure or a stacked-layer structure of three or more layers.

The conductive layer 120 functions as one of the source electrode and the drain electrode of the transistor 100. The conductive layer 140 functions as the other of the source electrode and the drain electrode of the transistor 100. The conductive layer 220 functions as the gate electrode of the transistor 100 and one of the source electrode and the drain electrode of the transistor 200. The conductive layer 240 functions as the other of the source electrode and the drain electrode of the transistor 200. The conductive layer 260 functions as the gate electrode of the transistor 200. The insulating layer 150 functions as the gate insulating layer of the transistor 100. The insulating layer 250 functions as the gate insulating layer of the transistor 200. The conductive layer 265 functions as a gate wiring.

At least part of the conductive layer 120 can function as the wiring 13 illustrated in FIG. 1A. At least part of the conductive layer 140 can function as the wiring 15 illustrated in FIG. 1A. At least part of the conductive layer 240 can function as the wiring 23 illustrated in FIG. 1A. At least part of the conductive layer 265 can function as the wiring 21 illustrated in FIG. 1A. Note that at least part of the conductive layer 120 may function as the wiring 15, and at least part of the conductive layer 140 may function as the wiring 13.

At least part of a region of the semiconductor layer 130 that is in contact with the insulating layer 180 functions as the channel formation region of the transistor 100. At least part of a region of the semiconductor layer 230 that is in contact with the insulating layer 280 functions as the channel formation region of the transistor 200. One of a region of the semiconductor layer 130 that is in contact with the conductive layer 120 and a region of the semiconductor layer 130 that is in contact with the conductive layer 140 functions as a source region, and the other thereof functions as a drain region. One of a region of the semiconductor layer 230 that is in contact with the conductive layer 220 and a region of the semiconductor layer 230 that is in contact with the conductive layer 240 functions as a source region, and the other thereof functions as a drain region. Accordingly, each of the channel formation region of the transistor 100 and the channel formation region of the transistor 200 is interposed between the source region and the drain region.

As illustrated in FIG. 1F and FIG. 1G, an opening portion 190 reaching the conductive layer 120 is provided in the conductive layer 140 and the insulating layer 180. Here, a depressed portion 191 is provided in the conductive layer 120 in a position overlapping with the opening portion 190. Specifically, the depressed portion 191 is provided in the conductive layer 120b. The bottom portion of the depressed portion 191 corresponds to the top surface of the conductive layer 120, specifically, the top surface of the conductive layer 120b. A sidewall of the depressed portion 191 corresponds to the side surface of the conductive layer 120, specifically, the side surface of the conductive layer 120b.

The opening portion 190 includes an opening portion of the insulating layer 180 and an opening portion of the conductive layer 140. In other words, the opening portion of the insulating layer 180 in a region overlapping with the conductive layer 120 is part of the opening portion 190, and the opening portion of the conductive layer 140 in a region overlapping with the conductive layer 120 is another part of the opening portion 190. Note that the depressed portion 191 is not necessarily included in the opening portion 190.

An opening portion 290 reaching the conductive layer 220 is provided in the conductive layer 240 and the insulating layer 280. Here, a depressed portion 291 is provided in the conductive layer 220 in a position overlapping with the opening portion 290. Specifically, the depressed portion 291 is provided in the conductive layer 220b. The bottom portion of the depressed portion 291 corresponds to the top surface of the conductive layer 220, specifically, the top surface of the conductive layer 220b. A sidewall of the depressed portion 291 corresponds to the side surface of the conductive layer 220, specifically, the side surface of the conductive layer 220b.

The opening portion 290 is provided such that at least part of the opening portion 290 overlaps with the opening portion 190. As described above, the depressed portion 191 is provided in a position overlapping with the opening portion 190. Accordingly, at least part of the depressed portion 191, the opening portion 190, the depressed portion 291, and the opening portion 290 overlap with one another. Thus, the area occupied by the memory cell 10 can be smaller than in the case where the opening portion 190 and the opening portion 290 do not overlap with each other, for example. Thus, the semiconductor device of one embodiment of the present invention can be a semiconductor device that can be miniaturized or highly integrated. Furthermore, the storage capacity per unit area can be increased.

The opening portion 290 includes an opening portion of the insulating layer 280 and an opening portion of the conductive layer 240. In other words, the opening portion of the insulating layer 280 in a region overlapping with the conductive layer 220 is part of the opening portion 290, and the opening portion of the conductive layer 240 in a region overlapping with the conductive layer 220 is another part of the opening portion 290. Note that the depressed portion 291 is not necessarily included in the opening portion 290.

The shapes and sizes of the opening portion 190 and the opening portion 290 in the plan view may differ from layer to layer. When the shape of the whole opening portion 190 in the plan view is circular, the opening portions included in the layers may be, but not necessarily concentrically arranged. Similarly, when the shape of the whole opening portion 290 in the plan view is circular, the opening portions included in the layers may be, but not necessarily concentrically arranged.

At least part of the components of the transistor 100 are placed in the opening portion 190. Specifically, at least part of each of the semiconductor layer 130, the insulating layer 150, and the conductive layer 220 is placed in the opening portion 190. The semiconductor layer 130 is in contact with the top surface of the conductive layer 140. The semiconductor layer 130 is in contact with the bottom portion and the sidewall of the depressed portion 191. Furthermore, the semiconductor layer 130 is in contact with the side surface of the conductive layer 140 and the side surface of the insulating layer 180 in the opening portion 190. The insulating layer 150 includes a region located over the conductive layer 140 and a region located over the semiconductor layer 130 in the opening portion 190. The insulating layer 150 can be provided to cover the semiconductor layer 130 and the conductive layer 140. The conductive layer 220 includes a region facing the semiconductor layer 130 with the insulating layer 150 therebetween in the opening portion 190.

Regions of the semiconductor layer 130 and the insulating layer 150, which are placed in the opening portion 190, are provided to reflect the shapes of the depressed portion 191 and the opening portion 190. Specifically, the semiconductor layer 130 is provided to cover the bottom portion and the sidewall of the depressed portion 191 and the sidewall of the opening portion 190, and the insulating layer 150 is provided to cover the semiconductor layer 130. Then, the conductive layer 220 is provided to fill at least part of a depressed portion of the insulating layer 150.

At least part of the components of the transistor 200 are placed in the opening portion 290. Specifically, at least part of each of the semiconductor layer 230, the insulating layer 250, and the conductive layer 260 is placed in the opening portion 290. The semiconductor layer 230 is in contact with the top surface of the conductive layer 240. The semiconductor layer 230 is in contact with the bottom portion and the sidewall of the depressed portion 291. Furthermore, the semiconductor layer 230 is in contact with the side surface of the conductive layer 240 and the side surface of the insulating layer 280 in the opening portion 290. The insulating layer 250 is located over the semiconductor layer 230 in the opening portion 290. The conductive layer 260 includes a region facing the semiconductor layer 230 with the insulating layer 250 therebetween in the opening portion 290.

Regions of the semiconductor layer 230 and the insulating layer 250, which are placed in the opening portion 290, are provided to reflect the shapes of the depressed portion 291 and the opening portion 290. Specifically, the semiconductor layer 230 is provided to cover the bottom portion and the sidewall of the depressed portion 291 and the sidewall of the opening portion 290, and the insulating layer 250 is provided to cover the semiconductor layer 230. Then, the conductive layer 260 is provided to fill at least part of a depressed portion of the insulating layer 250.

When the conductive layer 120 includes the depressed portion 191, the levels of the bottom surfaces of the insulating layer 150 and the conductive layer 220 in the opening portion 190 can be lower than the level of at least part of the top surface of the conductive layer 120 that is in contact with the insulating layer 180, unlike in the case where the depressed portion 191 is not provided. When the conductive layer 220 includes the depressed portion 291, the levels of the bottom surfaces of the insulating layer 250 and the conductive layer 260 in the opening portion 290 can be lower than the level of at least part of the top surface of the conductive layer 220 that is in contact with the insulating layer 280, unlike in the case where the depressed portion 291 is not provided.

The levels of the surfaces can be determined using the formation surface of the transistor as a reference. Here, the top surface of the insulating layer 110 can be used as the reference. The surface used as the reference is not limited to the formation surface of the transistor. For example, the top surface of the substrate where the transistor or the semiconductor device is provided may be used as the reference.

FIG. 2A illustrates a distance Ta1, a distance Tb1, a distance Tc1, a distance Ta2, a distance Tb2, and a distance Tc2. The distance Ta1 is the shortest distance from the top surface of the insulating layer 110 to the bottom surface of the insulating layer 150 in a region overlapping with the depressed portion 191. The distance Tb1 is the shortest distance from the top surface of the insulating layer 110 to the bottom surface of the conductive layer 220 in a region overlapping with the depressed portion 191. The distance Tc1 is the shortest distance from the top surface of the insulating layer 110 to the top surface of the conductive layer 120 that is in contact with the insulating layer 180. The distance Ta2 is the shortest distance from the top surface of the insulating layer 110 to the bottom surface of the insulating layer 250 in a region overlapping with the depressed portion 291. The distance Tb2 is the shortest distance from the top surface of the insulating layer 110 to the bottom surface of the conductive layer 260 in a region overlapping with the depressed portion 291. The distance Tc2 is the shortest distance from the top surface of the insulating layer 110 to the top surface of the conductive layer 220 that is in contact with the insulating layer 280 and overlaps with the conductive layer 140.

The distance Tc1 is preferably longer than the distance Ta1. Accordingly, the contact area between the side surface of the conductive layer 120 and the semiconductor layer 130 can be increased, so that the contact resistance between the conductive layer 120 and the semiconductor layer 130 can be reduced. This can inhibit a decrease in the on-state current of the transistor 100 due to the contact resistance between the conductive layer 120 and the semiconductor layer 130.

The distance Tc2 is preferably longer than the distance Ta2. Accordingly, the contact area between the side surface of the conductive layer 220 and the semiconductor layer 230 can be increased, so that the contact resistance between the conductive layer 220 and the semiconductor layer 230 can be reduced. This can inhibit a decrease in the on-state current of the transistor 200 due to the contact resistance between the conductive layer 220 and the semiconductor layer 230.

The distance Tc1 is preferably longer than or equal to the distance Tb1, further preferably longer than the distance Tb1. Accordingly, a gate electric field is easily applied to the channel formation region of the semiconductor layer 130, so that the electrical characteristics of the transistor 100 can be improved. Furthermore, a gate electric field is easily applied also to a region of the semiconductor layer 130 that is in contact with the conductive layer 120, whereby the on-state current of the transistor 100 can be increased. The electrical characteristics of the transistor 100 can be improved when either the conductive layer 120 or the conductive layer 140 is used as the drain electrode.

Furthermore, the distance Tc2 is preferably longer than or equal to the distance Tb2, further preferably longer than the distance Tb2. Accordingly, a gate electric field is easily applied to the channel formation region of the semiconductor layer 230, so that the electrical characteristics of the transistor 200 can be improved. Furthermore, a gate electric field is easily applied also to a region of the semiconductor layer 230 that is in contact with the conductive layer 220, whereby the on-state current of the transistor 200 can be increased. The electrical characteristics of the transistor 200 can be improved when either the conductive layer 220 or the conductive layer 240 is used as the drain electrode.

A conductive material containing oxygen is preferably used for the conductive layer 120b. Thus, even when a metal oxide is used for the semiconductor layer 130, it is possible to inhibit formation of a region having high electric resistance in a region of the conductive layer 120b that is in contact with the semiconductor layer 130 and a region in the vicinity thereof due to oxygen contained in the metal oxide. Accordingly, the contact resistance between the semiconductor layer 130 and the conductive layer 120b can be reduced. Similarly, a conductive material containing oxygen is preferably used for the conductive layer 140a. Thus, when a metal oxide is used for the semiconductor layer 130, the contact resistance between the semiconductor layer 130 and the conductive layer 140a can be reduced. A conductive material containing oxygen is preferably used for the conductive layer 220b. Thus, when a metal oxide is used for the semiconductor layer 230, the contact resistance between the semiconductor layer 230 and the conductive layer 220b can be reduced. Similarly, a conductive material containing oxygen is preferably used for the conductive layer 240a. Thus, when a metal oxide is used for the semiconductor layer 230, the contact resistance between the semiconductor layer 230 and the conductive layer 240a can be reduced.

In the case where the conductive layer 120, the conductive layer 220, and the conductive layer 240 each have a stacked-layer structure, the use of a conductive material containing oxygen for the layer closest to the channel formation region in the stacked-layer structure can reduce the contact resistance with the semiconductor layer 130 or the semiconductor layer 230, which allows a short current path between the source and the drain. Accordingly, the on-state current of the transistor can be increased. As a conductive material containing oxygen, a metal oxide having conductivity (also referred to as an oxide conductor) is preferably used.

When the semiconductor layer 130 is in contact with the top surface and the side surface of the conductive layer 140, the contact area with the conductive layer 140 is larger than that in the case where the semiconductor layer 130 is in contact with only the side surface of the conductive layer 140. Accordingly, the contact resistance between the semiconductor layer 130 and the conductive layer 140 can be further reduced. Thus, a decrease in the on-state current of the transistor 100 due to the contact resistance can be inhibited. When the semiconductor layer 230 is in contact with the top surface and the side surface of the conductive layer 240, the contact area with the conductive layer 240 is larger than that in the case where the semiconductor layer 230 is in contact with only the side surface of the conductive layer 240. Accordingly, the contact resistance between the semiconductor layer 230 and the conductive layer 240 can be further reduced. Thus, a decrease in the on-state current of the transistor 200 due to the contact resistance can be inhibited.

As illustrated in FIG. 1F and FIG. 1G, the insulating layer 150 is provided to cover the semiconductor layer 130 and the conductive layer 140. The conductive layer 220 is provided to include a region overlapping with the conductive layer 140 with the insulating layer 150 therebetween. Thus, the capacitance Cp illustrated in FIG. 1A or FIG. 1B is formed in the memory cell 10. In the example illustrated in FIG. 1A and FIG. 1B, the capacitance Cp can be capacitance in which the insulating layer 150 serves as a dielectric layer and the conductive layer 140 and the conductive layer 220 serve as a pair of electrodes. Note that in the capacitance Cp illustrated in FIG. 1C, the insulating layer 250 serves as a dielectric layer and the conductive layer 220 and the conductive layer 260 serve as a pair of electrodes.

In this manner, in the semiconductor device of one embodiment of the present invention, data can be retained with the capacitance Cp even when a capacitor is not formed in the memory cell 10. Thus, the number of manufacturing processes in the semiconductor device of one embodiment of the present invention can be smaller than that in the case where a capacitor is formed in the memory cell 10. Accordingly, the semiconductor device of one embodiment of the present invention can be a low-cost semiconductor device. By not forming a capacitor in the memory cell 10, the area occupied by the memory cell 10 can be reduced in some cases. In that case, the semiconductor device of one embodiment of the present invention can be a semiconductor device that can be miniaturized or highly integrated. Furthermore, the storage capacity per unit area can be increased. Note that a capacitance value of capacitance for retaining data can be the total of the capacitance value of the capacitance Cp illustrated in FIG. 1A or FIG. 1B and the capacitance value of the capacitance Cp illustrated in FIG. 1C, for example.

In the semiconductor device of one embodiment of the present invention, a capacitor may be formed in the memory cell 10. Specifically, a capacitor connected to the node ND1 of the memory cell 10 can be provided. This enables the memory cell 10 to retain data for a long time.

Here, the larger the region where the conductive layer 140 and the conductive layer 220 overlap with each other with the insulating layer 150 therebetween is, the larger the capacitance value of the capacitance Cp can be. This enables the memory cell 10 to retain data for a long time. Meanwhile, an excessively large capacitance value of the capacitance Cp may decrease the operation speed of the semiconductor device of one embodiment of the present invention, specifically, the operation speed of the memory cell 10. Accordingly, the above-described area is preferably adjusted in manufacturing the semiconductor device of one embodiment of the present invention so that the capacitance Cp has a desired value. FIG. 1F and FIG. 2A illustrate an example in which part of the side surface of the conductive layer 140 is covered with the conductive layer 220 with the insulating layer 150 therebetween. In this case, the capacitance value of the capacitance Cp can be larger than that in the case where the side surface of the conductive layer 140 is not covered with the conductive layer 220.

As illustrated in FIG. 1F and FIG. 1G, an opening portion 270 reaching the semiconductor layer 230 is provided in the insulating layer 285 in a position overlapping with the opening portion 290. At least part of the components of the transistor 200 are placed in the opening portion 270. Specifically, at least part of each of the insulating layer 250 and the conductive layer 260 is placed in the opening portion 270. At least part of the insulating layer 283 is located in the opening portion 270. The insulating layer 283 covers the top surface and the side surface of the semiconductor layer 230 and the side surface of the conductive layer 240. The insulating layer 250 is in contact with the insulating layer 283 in the opening portion 270. Note that the opening portion 270 may be provided in the insulating layer 283.

A region of the insulating layer 250 that is placed in the opening portion 270 reflects the shape of the opening portion 270. Specifically, the insulating layer 283 is provided to cover a sidewall of the opening portion 270 (the side surface of the insulating layer 285), and the insulating layer 250 is provided inside the insulating layer 283. Then, the conductive layer 260 is provided to fill at least part of a depressed portion of the insulating layer 250 reflecting the shape of the opening portion 270.

Since the conductive layer 260 does not overlap with the top surface of the conductive layer 240 in the transistor 200, parasitic capacitance between the conductive layer 240 and the conductive layer 260 can be reduced. As illustrated in FIG. 2A, the maximum width of the conductive layer 260 is smaller than a width D of the opening portion 290 in a cross-sectional view. As described above, the maximum width of the conductive layer 260 is preferably smaller than the width D of the opening portion 290, in which case the parasitic capacitance between the conductive layer 260 and the conductive layer 240 can be reduced. Note that for example, as illustrated in FIG. 2A, the relation between the two widths in the semiconductor device of one embodiment of the present invention can be found in one cross section parallel to the Z direction.

Note that in this specification and the like, a simple expression “in a cross-sectional view” is replaced with a specific expression “in a cross-sectional view from the same direction” in some cases. For example, in the case where the relation between a plurality of components is described, a relation in a cross-sectional view from the same direction is described. In that case, the relation between the plurality of components can be described using one cross-sectional view.

Note that the width D of the opening portion 290 changes in the depth direction in some cases. Here, the shortest distance between two side surfaces of the conductive layer 240 on the opening portion 290 side in a cross-sectional view is particularly used as the width D. In other words, the minimum width of the opening portion 290 in the conductive layer 240 is used as the width D of the opening portion 290.

It is preferable that the top surface of the conductive layer 260 be level with or substantially level with the top surface of the insulating layer 285. The conductive layer 265 is provided over the insulating layer 285, the insulating layer 283, the insulating layer 250, and the conductive layer 260, and is in contact with the top surface of the conductive layer 260. The conductive layer 265 can be in contact with the top surface of the insulating layer 285, the top surface of the insulating layer 283, and the top surface of the insulating layer 250. The conductive layer 260 and the conductive layer 265 can be regarded as being electrically connected to each other. The insulating layer 283 and the insulating layer 285 are located between the conductive layer 265 and the conductive layer 240. Here, the total thickness of the insulating layer 283 and the insulating layer 285, for example, the total thickness of the insulating layer 283 and the insulating layer 285 in a region overlapping with the conductive layer 240 and the semiconductor layer 230 is larger than the thickness of the insulating layer 150. Thus, the parasitic capacitance between the conductive layer 240 and the conductive layer 265 can be smaller than the capacitance Cp between the conductive layer 140 and the conductive layer 220.

That is, the transistor 200 has a structure where the parasitic capacitance between the other of the source electrode and the drain electrode and the gate electrode and the parasitic capacitance between the other of the source electrode and the drain electrode and the gate wiring are reduced. Accordingly, the transistor 200 can operate at high speed and the frequency characteristics of the memory cell 10 can be improved. Furthermore, the transistor 200 can be a transistor with favorable electrical characteristics. Thus, the semiconductor device of one embodiment of the present invention can be a semiconductor device including a transistor with favorable electrical characteristics.

In the example illustrated in FIG. 1F, an end portion of the conductive layer 140a, an end portion of the conductive layer 140b, and an end portion of the semiconductor layer 130 are aligned with one another outside the opening portion 190. Furthermore, in the example illustrated in FIG. 1F, an end portion of the conductive layer 240a, an end portion of the conductive layer 240b, and an end portion of the semiconductor layer 230 are aligned one another outside the opening portion 290. As in a manufacturing method example described later, the conductive layer 140a, the conductive layer 140b, and the semiconductor layer 130 can be formed by processing with the use of the same mask. The conductive layer 240a, the conductive layer 240b, and the semiconductor layer 230 can be formed by processing with the use of the same mask. These are preferable because the number of masks required for manufacturing the semiconductor device can be reduced.

The conductive layer 140 includes the opening portion 190 in a region overlapping with the conductive layer 120. It is preferable that the conductive layer 140 not be provided in the opening portion 190 included in the insulating layer 180. That is, it is preferable that the conductive layer 140 not be in contact with the side surface of the insulating layer 180 in the opening portion 190. With such a structure, the opening portion 190 can be formed in the conductive layer 140 and the insulating layer 180 at once. When the side surface of the conductive layer 140 in the opening portion 190 and the side surface of the insulating layer 180 in the opening portion 190 are aligned with each other, the thickness distribution of the semiconductor layer 130 provided in the opening portion 190 can be uniform. In addition, the semiconductor layer 130 can be inhibited from being divided by a step between the conductive layer 140 and the insulating layer 180.

Similarly, the conductive layer 240 includes the opening portion 290 in a region overlapping with the conductive layer 220. It is preferable that the conductive layer 240 not be provided in the opening portion 290 included in the insulating layer 280. That is, it is preferable that the conductive layer 240 not be in contact with the side surface of the insulating layer 280 in the opening portion 290.

Note that FIG. 1F and FIG. 1G illustrate an example where the slope of the side surface of the conductive layer 140 in the opening portion 190 is equal to the slope of the side surface of the insulating layer 180 in the opening portion 190; however, the slopes of these side surfaces may be different from each other. In that case, for example, the taper angle of the side surface of the conductive layer 140 in the opening portion 190 is preferably smaller than the taper angle of the side surface of the insulating layer 180 in the opening portion 190. Such a structure can improve the coverage of the side surface of the conductive layer 140 with the semiconductor layer 130 in the opening portion 190, thereby reducing defects such as voids. In the case where the insulating layer 180 has a stacked-layer structure, the slopes of the side surfaces of the layers in the opening portion 190 may be different from each other. Similarly, in the case where the conductive layer 140 has a stacked-layer structure, the slopes of the side surfaces of the layers in the opening portion 190 may be different from each other.

In a manner similar to that described above, FIG. 1F and FIG. 1G illustrate an example where the slope of the side surface of the conductive layer 240 in the opening portion 290 is equal to the slope of the side surface of the insulating layer 280 in the opening portion 290; however, the slopes of these side surfaces may be different from each other.

In the transistor 100, the semiconductor layer 130 including the channel formation region includes a metal oxide functioning as a semiconductor (also referred to as an oxide semiconductor). In the transistor 200, the semiconductor layer 230 including the channel formation region includes a metal oxide functioning as a semiconductor (also referred to as an oxide semiconductor). Accordingly, the transistor 100 and the transistor 200 can be regarded as OS transistors.

When oxygen vacancies (Vo) and impurities are in a channel formation region of an oxide semiconductor in an OS transistor, electrical characteristics of the OS transistor easily vary and the reliability thereof might worsen. In some cases, hydrogen in the vicinity of an oxygen vacancy forms a defect that is an oxygen vacancy into which hydrogen enters (hereinafter sometimes referred to as VoH), which generates an electron serving as a carrier. Thus, if the channel formation region of the oxide semiconductor includes oxygen vacancies, the OS transistor is likely to be normally-on. Therefore, the oxygen vacancies and the impurities are preferably reduced as much as possible in the channel formation region in the oxide semiconductor. In other words, the oxide semiconductor preferably includes an i-type (intrinsic) or substantially i-type channel formation region with a low carrier concentration.

Meanwhile, preferably, the source region and the drain region of the OS transistor include more oxygen vacancies, include more VoH, or have a higher concentration of an impurity such as hydrogen, nitrogen, or a metal element than the channel formation region, and thus are low-resistance regions with high carrier concentrations. In other words, the source region and the drain region of the OS transistor are preferably n-type regions having higher carrier concentrations and lower resistances than the channel formation region.

An OS transistor has a low off-state current. Thus, in particular, the use of an OS transistor as the transistor 100 enables the memory cell 10 to retain data for a long time. Thus, no refresh operation is necessary. Alternatively, the frequency of refresh operation can be extremely low. Therefore, the semiconductor device of one embodiment of the present invention can be a low-power-consumption semiconductor device. Here, the transistor 200 can be an OS transistor, like the transistor 100.

As described above, the semiconductor layer 130 is provided in the opening portion 190 included in the insulating layer 180. The transistor 100 has a structure in which a current flows in the vertical direction since one of the source electrode and the drain electrode (here, the conductive layer 120) is located in the lower portion and the other of the source electrode and the drain electrode (here, the conductive layer 140) is located in the upper portion. That is, a channel is formed along the side surface of the opening portion 190 included in the insulating layer 180. Similarly, the channel of the transistor 200 is formed along the side surface of the opening portion 290 included in the insulating layer 280.

As illustrated in FIG. 2B, the insulating layer 280 is in contact with all the perimeter of the semiconductor layer 230. Thus, the channel formation region of the transistor 200 can be formed in all the perimeter of the semiconductor layer 230 in the opening portion 290 (the entire region in contact with the insulating layer 280). Similarly, the insulating layer 180 is in contact with all the perimeter of the semiconductor layer 130. Thus, the channel formation region of the transistor 100 can be formed in all the perimeter of the semiconductor layer 130 in the opening portion 190 (the entire region in contact with the insulating layer 180). Note that FIG. 2B can be regarded as a cross-sectional view along the XY plane including the channel formation region of the semiconductor layer 230.

Each channel length of the transistor 100 and the transistor 200 is the distance between the source region and the drain region. The channel length of the transistor 100 can correspond to the length of the side surface of the insulating layer 180 on the opening portion 190 side. The channel length of the transistor 200 can correspond to the length of the side surface of the insulating layer 280 on the opening portion 290 side. In FIG. 2A, a channel length L1 of the transistor 100 and a channel length L2 of the transistor 200 are indicated by dashed double-headed arrows. Here, an example where the channel length LI corresponds to the length of the side surface of the insulating layer 180 on the opening portion 190 side is shown. Furthermore, an example where the channel length L2 corresponds to the length of the side surface of the insulating layer 280 on the opening portion 290 side is shown.

In a conventional transistor, the channel length is determined by the light exposure limit of photolithography, whereas in one embodiment of the present invention, the channel length can be determined by the thickness of the insulating layer 180 or the insulating layer 280. Thus, the transistor 100 and the transistor 200 can each have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 0.1 nm, greater than or equal to 1 nm, or greater than or equal to 5 nm). Accordingly, the transistor 100 and the transistor 200 can have higher on-state currents and higher frequency characteristics.

In addition, as described above, the channel formation region, the source region, and the drain region can be formed in each of the opening portion 190 and the opening portion 290. Thus, the areas occupied by the transistor 100 and the transistor 200 can be reduced as compared with a lateral transistor in which the channel formation region, the source region, and the drain region are provided separately on the XY plane. Thus, the semiconductor device can be highly integrated. In the case where the semiconductor device of one embodiment of the present invention is used in a memory device, the storage capacity per unit area can be increased.

As illustrated in FIG. 2B, the semiconductor layer 230, the insulating layer 250, and the conductive layer 260 are provided concentrically. Therefore, the side surface of the conductive layer 260 provided at the center faces the side surface of the semiconductor layer 230 with the insulating layer 250 therebetween. That is, in the plan view, all the perimeter of the semiconductor layer 230 serves as the channel formation region. In that case, for example, the channel width of the transistor 200 is determined by the length of the perimeter of the semiconductor layer 230. In other words, the channel width of the transistor 200 is determined by the width of the opening portion 290 (the diameter in the case where the opening portion 290 is circular in the plan view). In FIG. 2A and FIG. 2B, the width D of the opening portion 290 is indicated by a dashed double-dotted double-headed arrow. In FIG. 2B, a channel width W of the transistor 200 is indicated by a dashed-dotted double-headed arrow. An increase in the width D of the opening portion 290 can increase the channel width per unit area and the on-state current. Similarly, in the plan view, all the perimeter of the semiconductor layer 130 serves as the channel formation region. In that case, for example, the channel width of the transistor 100 is determined by the length of the perimeter of the semiconductor layer 130. In other words, the channel width of the transistor 100 is determined by the width of the opening portion 190 (the diameter in the case where the opening portion 190 is circular in the plan view).

In the case where the opening portion 290 is formed by a photolithography method, the width D of the opening portion 290 is determined by the light exposure limit of photolithography. In addition, the width D of the opening portion 290 is determined by the thicknesses of the semiconductor layer 230, the insulating layer 250, and the conductive layer 260 provided in the opening portion 290. The width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 290 is circular in the plan view, the width D of the opening portion 290 corresponds to the diameter of the opening portion 290, and the channel width W can be calculated to be “D×π”. The same applies to the width of the opening portion 190 when the opening portion 290, the semiconductor layer 230, the insulating layer 250, and the conductive layer 260 are replaced with the opening portion 190, the semiconductor layer 130, the insulating layer 150, and the conductive layer 220, respectively.

The channel length L2 of the transistor 200 is preferably shorter than at least the channel width W of the transistor 200. The channel length L2 of the transistor 200 is preferably greater than or equal to 0.1 times and less than or equal to 0.99 times, further preferably greater than or equal to 0.5 times and less than or equal to 0.8 times the channel width W of the transistor 200. Similarly, the channel length L1 of the transistor 100 is preferably shorter than at least the channel width of the transistor 100. The channel length L1 of the transistor 100 is preferably greater than or equal to 0.1 times and less than or equal to 0.99 times, further preferably greater than or equal to 0.5 times and less than or equal to 0.8 times the channel width W of the transistor 100. This structure enables the transistor 100 and the transistor 200 to have with favorable electrical characteristics and high reliability.

In the case where the opening portion 190 is formed to be circular in a plan view, the semiconductor layer 130, the insulating layer 150, and the conductive layer 220 are provided concentrically. This makes the distance between the conductive layer 220 and the semiconductor layer 130 substantially uniform, so that a gate electric field can be substantially uniformly applied to the semiconductor layer 130. Similarly, in the case where the opening portion 290 is formed to be circular in a plan view, a gate electric field can be substantially uniformly applied to the semiconductor layer 230.

Although this embodiment describes the example where the opening portion 190, the opening portion 290, and the opening portion 270 have circular shapes in the plan view, the present invention is not limited thereto. The opening portion 190, the opening portion 290, and the opening portion 270 in the plan view can have circular shapes, substantially circular shapes such as elliptical shapes, polygonal shapes such as triangular shapes, tetragonal shapes (including rectangular shapes, rhombus shapes, and square shapes), pentagonal shapes, star polygonal shapes, or any of these polygonal shapes with rounded corners, for example. Note that the polygonal shape may be a concave polygonal shape (a polygonal shape at least one of the interior angles of which is greater than 180°) or a convex polygonal shape (a polygonal shape all the interior angles of which are less than or equal to 180°). As illustrated in FIG. 1D, FIG. 1E, and the like, the opening portion 190, the opening portion 290, and the opening portion 270 in the plan view preferably have a circular shape. When the opening portions have a circular shape, processing accuracy in forming the opening portions can be high, whereby the opening portions can be formed to have minute sizes. In this specification and the like, a circular shape is not necessarily a perfect circular shape.

### Materials for Semiconductor Device

Materials that can be used for the semiconductor device of this embodiment are described below. Note that the layers included in the semiconductor device of this embodiment may each have a single-layer structure or a stacked-layer structure. FIG. 1F and FIG. 1G illustrate an example where the conductive layer 120a, the conductive layer 220a, the semiconductor layer 130, the semiconductor layer 230, and the conductive layer 260 each have a single-layer structure. FIG. 2A illustrates an example where the conductive layer 120a, the conductive layer 220a, the semiconductor layer 130, the semiconductor layer 230, and the conductive layer 260 each have a stacked-layer structure.

### Semiconductor layer 130 and Semiconductor Layer 230

As described above, the semiconductor layer 130 and the semiconductor layer 230 each include a channel formation region. The channel formation region can be regarded as an i-type (intrinsic) or substantially i-type region. In addition, the semiconductor layer 130 and the semiconductor layer 230 each include a source region and a drain region. The source region and the drain region are n-type regions (low-resistance regions) having a higher carrier concentration than the channel formation region.

There is no particular limitation on the crystallinity of the semiconductor material used for the semiconductor layer 130 and the semiconductor layer 230, and any of an amorphous semiconductor, a single crystal semiconductor, and a semiconductor having other crystallinity than single crystal (a microcrystalline semiconductor, a polycrystalline semiconductor, or a semiconductor partly including crystal regions) may be used. It is preferable to use a single crystal semiconductor or a semiconductor having crystallinity, in which case deterioration of the transistor characteristics can be inhibited.

A metal oxide can be used for the semiconductor layer 130 and the semiconductor layer 230. In that case, the semiconductor layer 130 and the semiconductor layer 230 can be referred to as oxide semiconductor layers.

The band gap of the metal oxide functioning as a semiconductor is preferably greater than or equal to 2.0 eV, further preferably greater than or equal to 2.5 eV. The use of such a metal oxide having a wide band gap can reduce the off-state current of the transistor. The off-state current of the OS transistor is small, so that power consumption of the semiconductor device can be sufficiently reduced. The OS transistor has high frequency characteristics, which enables the semiconductor device to operate at high speed.

Examples of the metal oxide that can be used for the semiconductor layer 130 and the semiconductor layer 230 include indium oxide, gallium oxide, and zinc oxide. The metal oxide preferably contains at least indium (In) or zinc (Zn). The metal oxide preferably contains two or three selected from indium, an element M, and zinc. The element M is a metal element or metalloid element that has a high bonding energy with oxygen, such as a metal element or metalloid element whose bonding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more kinds of the above elements, further preferably one or more kinds selected from aluminum, gallium, tin, and yttrium, and still further preferably gallium. In this specification and the like, a metal element and a metalloid element may be collectively referred to as a “metal element”, and a “metal element” in this specification and the like may refer to a metalloid element.

For example, the semiconductor layer 130 and the semiconductor layer 230 can be formed using indium oxide (In oxide), indium zinc oxide (also referred to as In—Zn oxide or IZO (registered trademark)), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (also referred to as In—Ga—Sn oxide, IGTO), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (also referred to as In—Sn—Zn oxide or ITZO (registered trademark)), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, IGZAO, or IAGZO). Alternatively, indium tin oxide containing silicon, gallium tin oxide (Ga—Sn oxide), aluminum tin oxide (Al—Sn oxide), or the like can be used.

By increasing the proportion of the number of indium atoms in the total number of atoms of all the metal elements contained in the metal oxide, the field-effect mobility of the transistor can be increased. In addition, the transistor can have a high on-state current.

Instead of indium or in addition to indium, the metal oxide may contain one or more kinds of metal elements whose period number in the periodic table is large. The larger the overlap between orbits of metal elements is, the more likely it is that the metal oxide will have high carrier conductivity. Thus, when a metal element with a large period number in the periodic table is contained in the metal oxide, the field-effect mobility of the transistor can be increased in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of non-metallic elements. By containing a non-metallic element, the metal oxide sometimes has an increased carrier concentration, a reduced band gap, or the like, in which case the transistor can have increased field-effect mobility. Examples of the non-metallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor is suppressed and the transistor can have high reliability.

By increasing the proportion of the number of element M atoms in the total number of atoms of all the metal elements contained in the metal oxide, the metal oxide can have a large band gap. That is, formation of oxygen vacancies in the metal oxide can be inhibited. Accordingly, generation of carriers due to oxygen vacancies is inhibited, which makes the off-state current of the transistor low. Furthermore, a shift in the threshold voltage of the transistor can be inhibited. Furthermore, changes in the electrical characteristics of the transistor can be reduced to improve the reliability of the transistor.

The composition of the metal oxide used for the semiconductor layer 130 and the semiconductor layer 230 affects the electrical characteristics and reliability of the transistor. Therefore, by determining the composition of the metal oxide in accordance with the electrical characteristics and reliability required for the transistor, the semiconductor device can have both excellent electrical characteristics and high reliability.

When the metal oxide is an In—M—Zn oxide, the atomic ratio of In is preferably higher than or equal to the atomic ratio of M in the In—M—Zn oxide. Examples of the atomic ratio of the metal elements of such an In-M-Zn oxide include In:M:Zn=1:1:0.5, In:M:Zn=1:1:1, In:M:Zn=1:1:1.2, In:M:Zn=1:1:2, In:M:Zn=2:1:3, In:M:Zn=3:1:1, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, and In:M:Zn=5:2:5 and a composition in the neighborhood thereof. Note that the neighborhood of the atomic ratio includes ±30 % of an intended atomic ratio. By increasing the atomic ratio of indium in the metal oxide, the on-state current, field-effect mobility, or the like of the transistor can be improved.

The atomic ratio of In may be less than the atomic ratio of M in the In—M—Zn oxide. Examples of the atomic ratio of the metal elements of such an In—M—Zn oxide include In:M:Zn=1:3:2, In:M:Zn=1:3:3, and In:M:Zn=1:3:4 and a composition in the neighborhood thereof. By increasing the proportion of the number of M atoms in the metal oxide, generation of oxygen vacancies can be suppressed.

In the case where a plurality of metal elements are contained as the element M, the sum of the proportions of the numbers of atoms of these metal elements can be used as the proportion of the number of element M atoms.

In this specification and the like, the proportion of the number of indium atoms in the total number of atoms of all the metal elements contained is sometimes referred to as indium content percentage. The same applies to other metal elements.

In the case where the metal oxide is an In-Zn oxide, examples of the atomic ratio of metal elements in the In-Zn oxide include In:Zn=1:1, In:Zn=2:1, In:Zn=4:1, and a composition in the neighborhood thereof. In addition, the In-Zn oxide may contain a slight amount of the element M. For example, in the case where Sn is contained as the element M, examples of the atomic ratio of metal elements in the metal oxide include In:Sn:Zn=2:0.1:1, In:Sn:Zn=4:0.1:1, and a composition in the neighborhood thereof.

Analysis of the composition of the metal oxide used for the semiconductor layer 130 and the semiconductor layer 230 can be performed by energy dispersive X-ray spectrometry (EDX), X-ray photoelectron spectrometry (XPS), inductively coupled plasma-mass spectrometry (ICP-MS), or inductively coupled plasma-atomic emission spectrometry (ICP-AES), for example. Alternatively, any of these methods may be combined with each other for the analysis. As for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage. In some cases, the element M is difficult to quantify or the element M is not detected.

A sputtering method or an ALD method can be suitably used for forming the metal oxide. Note that in the case where the metal oxide is formed by a sputtering method, the composition of the formed metal oxide may be different from the composition of a target. In particular, the zinc content percentage of the formed metal oxide may be reduced to approximately 50% of that of the target. The metal oxide may be formed by a chemical vapor deposition (CVD) method, a molecular beam epitaxy (MBE) method, a pulsed laser deposition (PLD) method, or the like.

The semiconductor layer 130 and the semiconductor layer 230 may each have a stacked-layer structure of two or more metal oxide layers. The two or more metal oxide layers included in each of the semiconductor layer 130 and the semiconductor layer 230 may have the same composition or substantially the same compositions. Employing a stacked-layer structure of metal oxide layers having the same composition can reduce the manufacturing cost because the metal oxide layers can be formed using the same sputtering target.

The two or more metal oxide layers included in each of the semiconductor layer 130 and the semiconductor layer 230 may have different compositions.

FIG. 2A illustrates an example where the semiconductor layer 130 has a two-layer structure of an oxide layer 130a and an oxide layer 130b over the oxide layer 130a. FIG. 2A also illustrates an example where the semiconductor layer 230 has a two-layer structure of an oxide layer 230a and an oxide layer 230b over the oxide layer 230a.

Materials having higher conductivity than the oxide layer 130b and the oxide layer 230b are preferably used for the oxide layer 130a and the oxide layer 230a, for example. When a material with high conductivity is used for the oxide layer 130a in contact with the source electrode and the drain electrode (the conductive layer 120 and the conductive layer 140) of the transistor 100, the contact resistance between the semiconductor layer 130 and the conductive layer 120 and the contact resistance between the semiconductor layer 130 and the conductive layer 140 can be reduced. Therefore, the transistor 100 can be a transistor with a high on-state current. Similarly, when a material with high conductivity is used for the oxide layer 230a in contact with the source electrode and the drain electrode (the conductive layer 220 and the conductive layer 240) of the transistor 200, the contact resistance between the semiconductor layer 230 and the conductive layer 220 and the contact resistance between the semiconductor layer 230 and the conductive layer 240 can be reduced. Therefore, the transistor 200 can be a transistor with a high on-state current.

Here, when a material with high conductivity is used for the oxide layer 130b provided on the conductive layer 220 side, the threshold voltage of the transistor 100 is shifted in some cases. Thus, a drain current flowing at the time when the gate voltage is 0 V (hereinafter also referred to as a cut-off current) becomes large in some cases. Specifically, the threshold voltage might be low when the transistor 100 is an n-channel transistor. Similarly, when a material with high conductivity is used for the oxide layer 230b provided on the conductive layer 260 side, the threshold voltage of the transistor 200 is shifted in some cases. Thus, the cut-off current in the transistor 200 becomes large in some cases. Specifically, the threshold voltage might be low when the transistor 200 is an n-channel transistor. Accordingly, a material with lower conductivity than the oxide layer 130a and the oxide layer 230a is preferably used for the oxide layer 130b and the oxide layer 230b. Therefore, in the case where the transistor 100 and the transistor 200 are n-channel transistors, the transistors can have a high threshold voltage and a low cut-off current. Note that characteristics with low cut-off current are sometimes referred to as normally-off.

When the semiconductor layer 130 and the semiconductor layer 230 each have a stacked-layer structure and a material with higher conductivity than the oxide layer 130b and the oxide layer 230b is used for the oxide layer 130a and the oxide layer 230a as described above, the transistors can be normally-off and have a high on-state current. Consequently, the semiconductor device can have both low power consumption and high performance.

The carrier concentrations of the oxide layer 130a and the oxide layer 230a are preferably higher than those of the oxide layer 130b and the oxide layer 230b. When the carrier concentrations of the oxide layer 130a and the oxide layer 230a are high, their conductivities are high. Thus, the contact resistance between the semiconductor layer 130 and the conductive layer 120, the contact resistance between the semiconductor layer 130 and the conductive layer 140, the contact resistance between the semiconductor layer 230 and the conductive layer 220, and the contact resistance between the semiconductor layer 230 and the conductive layer 240 can be reduced. Accordingly, the transistor 100 and the transistor 200 can be transistors with high on-state currents. When the carrier concentrations of the oxide layer 130b and the oxide layer 230b are low, their conductivities are low, whereby the transistor 100 and the transistor 200 can be normally-off transistors.

Note that the compositions of the semiconductor layer 130 and the semiconductor layer 230 are not limited to those described above, and a material with lower conductivity than the oxide layer 130b and the oxide layer 230b may be used for the oxide layer 130a and the oxide layer 230a. The carrier concentrations of the oxide layer 130a and the oxide layer 230a may be lower than the carrier concentrations of the oxide layer 130b and the oxide layer 230b.

The band gap of a first metal oxide used for the oxide layer 130a and the oxide layer 230a is preferably different from the band gap of a second metal oxide used for the oxide layer 130b and the oxide layer 230b. For example, a difference between the band gap of the first metal oxide and the band gap of the second metal oxide is preferably greater than or equal to 0.1 eV, further preferably greater than or equal to 0.2 eV, still further preferably greater than or equal to 0.3 eV.

The band gap of the first metal oxide used for the oxide layer 130a and the oxide layer 230a is preferably smaller than the band gap of the second metal oxide used for the oxide layer 130b and the oxide layer 230b. Accordingly, the contact resistance between the semiconductor layer 130 and the conductive layer 120, the contact resistance between the semiconductor layer 130 and the conductive layer 140, the contact resistance between the semiconductor layer 230 and the conductive layer 220, and the contact resistance between the semiconductor layer 230 and the conductive layer 240 can be reduced. Accordingly, the transistor 100 and the transistor 200 can be transistors with high on-state currents. In the case where the transistor 100 and the transistor 200 are n-channel transistors, the transistors can have a high threshold voltage and be normally-off. Furthermore, when the second metal oxide has a large band gap, carriers can be inhibited from being generated and induced in the oxide layer 130b and the oxide layer 230b, at the interface between the oxide layer 130b and the insulating layer 150, and at the interface between the oxide layer 230b and the insulating layer 250. This can improve the reliability of the transistors.

For example, the content percentage of the element M in the first metal oxide is preferably lower than that of the element M in the second metal oxide. Specifically, for example, a metal oxide with a composition of In:M:Zn=1:1:1 [atomic ratio] or the neighborhood thereof is preferably used for the oxide layer 130a and the oxide layer 230a, and a metal oxide with a composition of In:M:Zn=1:3:2 [atomic ratio] or the neighborhood thereof is preferably used for the oxide layer 130b and the oxide layer 230b. In that case, it is particularly preferable to use one or more of gallium, aluminum, and tin as the element M.

Note that the semiconductor layer 130 and the semiconductor layer 230 are not limited to having the above composition, and the band gap of the first metal oxide may be larger than the band gap of the second metal oxide.

The content percentage of the element M in the first metal oxide is preferably lower than that of the element M in the second metal oxide. The first metal oxide may contain no or a slight amount of element M. For example, the first metal oxide used for the oxide layer 130a and the oxide layer 230a is preferably an In—Zn oxide, and the second metal oxide used for the oxide layer 130b and the oxide layer 230b is preferably an In—M—Zn oxide. Specifically, the first metal oxide can be an In—Zn oxide, and the second metal oxide can be an In—Ga—Zn oxide.

For example, for the oxide layer 130a and the oxide layer 230a, it is preferable to use a metal oxide with a composition of In:Zn=1:1 [atomic ratio] or the neighborhood thereof, a metal oxide with a composition of In:Zn=2:1 [atomic ratio] or the neighborhood thereof, a metal oxide with a composition of In:Sn:Zn=2:0.1:1 [atomic ratio] or the neighborhood thereof, a metal oxide with a composition of In:Zn=4:1 [atomic ratio] or the neighborhood thereof, a metal oxide with a composition of In:Sn:Zn=4:0.1:1 [atomic ratio] or the neighborhood thereof, or an indium oxide. For the oxide layer 130b and the oxide layer 230b, it is preferable to use a metal oxide with a composition of In:Ga:Zn=1:1:1 [atomic ratio] or the neighborhood thereof, a metal oxide with a composition of In:Ga:Zn=1:3:2 [atomic ratio] or the neighborhood thereof, or a metal oxide with a composition of In:Ga:Zn=1:3:4 [atomic ratio] or the neighborhood thereof. With this structure, the transistor 200 can have a high on-state current and high reliability with small variations.

For example, in the case where a metal oxide is used for the conductive layer 120 or the conductive layer 140 (the layer closest to the channel formation region of the semiconductor layer 130 in the case of a stacked-layer structure), an In—Zn oxide or an In—Sn—Zn oxide is preferably used for the semiconductor layer 130 (or the oxide layer 130a) because the contact resistance can be reduced as compared with the case where an In-Ga-Zn oxide is used for the semiconductor layer 130 (or the oxide layer 130a). Specifically, in FIG. 2A, an indium tin oxide (also referred to as ITO) or an indium tin oxide to which silicon is added (also referred to as ITSO) is preferably used for the conductive layer 120b and the conductive layer 140a, an In-Zn oxide or an In—Sn—Zn oxide is preferably used for the oxide layer 130a, and an In—Ga—Zn oxide is preferably used for the oxide layer 130b.

Similarly, in the case where a metal oxide is used for the conductive layer 220 or the conductive layer 240 (the layer closest to the channel formation region of the semiconductor layer 230 in the case of a stacked-layer structure), an In—Zn oxide or an In—Sn—Zn oxide is preferably used for the semiconductor layer 230 (or the oxide layer 230a) because the contact resistance can be reduced as compared with the case where an In—Ga—Zn oxide is used for the semiconductor layer 230 (or the oxide layer 230a). Specifically, in FIG. 2A, ITO or ITSO is preferably used for the conductive layer 220b and the conductive layer 240a, an In—Zn oxide or an In—Sn—Zn oxide is preferably used for the oxide layer 230a, and an In—Ga—Zn oxide is preferably used for the oxide layer 230b.

Note that the semiconductor layer 130 and the semiconductor layer 230 are not limited to having the above composition, and the content percentage of the element Min the first metal oxide may be higher than that of the element M in the second metal oxide.

There is no particular limitation on the crystallinity of the semiconductor material used for the semiconductor layer 130 and the semiconductor layer 230, and any of an amorphous semiconductor (a semiconductor having an amorphous structure), a single crystal semiconductor (a semiconductor having a single crystal structure), and a semiconductor having other crystallinity than single crystal (a microcrystalline semiconductor, a polycrystalline semiconductor, or a semiconductor partly including crystal regions) may be used. It is preferable to use a single crystal semiconductor or a semiconductor having crystallinity, in which case deterioration of the transistor characteristics can be inhibited.

It is preferable that the semiconductor layer 130 and the semiconductor layer 230 each include a metal oxide layer having crystallinity. Examples of the structure of a metal oxide having crystallinity include a c-axis aligned crystalline (CAAC) structure, a polycrystalline structure, and a nano-crystal (nc) structure. By using a metal oxide layer having crystallinity as each of the semiconductor layer 130 and the semiconductor layer 230, the density of defect states in the semiconductor layer 130 and the semiconductor layer 230 can be reduced, which enables the semiconductor device to have high reliability. Note that the CAAC structure is a crystal structure in which a plurality of nanocrystals (typically, a plurality of IGZO nanocrystals) have c-axis alignment and are connected on the a-b plane without alignment. According to a high-resolution cross-sectional TEM image of an OS film having the CAAC structure, metal atoms are arranged in a layered manner in the crystal parts. Thus, the CAAC structure of the OS film can also be referred to as a structure including the layered crystal parts.

A polycrystalline structure includes a crystal grain boundary. When an oxide semiconductor layer having a polycrystalline structure is formed and then subjected to heat treatment, a minute gap (also referred to as a nano crack or a micro crack) or a minute space (also referred to as a nano space or a micro space) can be formed between crystal parts. When a minute gap or a minute space is formed in the oxide semiconductor layer, the electric resistance of the oxide semiconductor layer is increased. This is because the electric resistance of the minute gap or the minute space is extremely high, for example, infinite. In the case where an oxide semiconductor layer including a minute gap or a minute space is used for a channel formation region of a transistor, the contact resistance between the oxide semiconductor layer and one or both of a source electrode and a drain electrode becomes high. This adversely affects initial characteristics or reliability of the transistor. A CAAC structure has a fewer crystal grain boundaries in the a-b plane than the polycrystalline structure; thus, a highly reliable semiconductor device can be achieved.

As the crystallinity of the metal oxide layer used as each of the semiconductor layer 130 and the semiconductor layer 230 becomes higher, the density of defect states in the semiconductor layer 130 and the semiconductor layer 230 can be reduced. In contrast, with the use of a metal oxide layer having low crystallinity, a large amount of current can flow through the transistor.

The higher the substrate temperature (the stage temperature) in the formation of the metal oxide layer is, the higher the crystallinity of the metal oxide layer can be. The crystallinity of the metal oxide layer can be increased as the proportion of the flow rate of an oxygen gas to the flow rate of the whole film formation gas (also referred to as oxygen flow rate ratio) used in formation is higher.

The crystallinity of the semiconductor layer 130 and the semiconductor layer 230 can be analyzed with X-ray diffraction (XRD), a transmission electron microscope (TEM), or electron diffraction (ED), for example. Alternatively, any of these methods may be combined with each other for the analysis.

The semiconductor layer 130 and the semiconductor layer 230 can each have a stacked-layer structure of two or more metal oxide layers having different crystallinities. In that case, the compositions of the two or more metal oxide layers may be different from, the same as, or substantially the same as each other. For example, in a stacked-layer structure of a first metal oxide layer and a second metal oxide layer provided thereover, the second metal oxide layer can include a region having higher crystallinity than the first metal oxide layer. Alternatively, the second metal oxide layer can include a region having lower crystallinity than the first metal oxide layer. Note that in the case where the second metal oxide layer includes a region having lower crystallinity than the first metal oxide layer, heat treatment (also referred to as crystallization treatment) is performed after formation of the second metal oxide layer, whereby the crystallinity of the second metal oxide layer can be increased.

For example, a metal oxide with a composition of In:M:Zn=1:3:2 [atomic ratio] or the neighborhood thereof or a metal oxide with a composition of In:M:Zn=1:3:4 [atomic ratio] or the neighborhood thereof is preferably used for the oxide layer 130a, and a metal oxide with a composition of In:M:Zn=1:1:1 [atomic ratio] or the neighborhood thereof is preferably used for the oxide layer 130b. When a metal oxide with a high proportion of Zn to In is used for the oxide layer 130a, the crystallinity of the oxide layer 130a can be increased. Furthermore, when the oxide layer 130b is formed over the oxide layer 130a with high crystallinity, the crystallinity of the oxide layer 130b can be easily increased. Note that the same applies to the oxide layer 230a and the oxide layer 230b. Such a structure is preferable because the crystallinity of the whole semiconductor layer 130 and the whole semiconductor layer 230 can be increased. In this case, it is particularly preferable to use gallium, aluminum, or tin as the element M. For example, two IGZO layers having different compositions may be stacked. Alternatively, a stacked-layer structure of one selected from an indium oxide, an indium gallium oxide, and IGZO, and one selected from IAZO, IAGZO, and ITZO (registered trademark) may be employed, for example.

The semiconductor layer 130 and the semiconductor layer 230 may each have a stacked-layer structure of three or more layers. The semiconductor layer 130 can have a three-layer structure of an oxide layer, the oxide layer 130a over the oxide layer, and the oxide layer 130b over the oxide layer 130a, for example. Although the case where the semiconductor layer 130 has a three-layer structure is described below as an example, the same structure can be applied to the semiconductor layer 230.

The oxide layer 130a and the oxide layer 130b can have the above-described composition. The oxide layer located below the oxide layer 130a can have a composition similar to that of the oxide layer 130b. Hereinafter, the oxide layer and the oxide layer 130b are collectively described as a pair of oxide layers between which the oxide layer 130a is interposed.

For example, as the oxide layer 130a, it is preferable to use a metal oxide with a composition of In:Zn=1:1 [atomic ratio] or the neighborhood thereof, a metal oxide with a composition of In:Zn=2:1 [atomic ratio] or the neighborhood thereof, a metal oxide with a composition of In:Sn:Zn=2:0.1:1 [atomic ratio] or the neighborhood thereof, a metal oxide with a composition of In:Zn=4:1 [atomic ratio] or the neighborhood thereof, a metal oxide with a composition of In:Sn:Zn=4:0.1:1 [atomic ratio] or the neighborhood thereof, or an indium oxide. For the pair of oxide layers between which the oxide layer 130a is interposed, it is preferable to use a metal oxide with a composition of In:Ga:Zn=1:1:1 [atomic ratio] or the neighborhood thereof, a metal oxide with a composition of In:Ga:Zn=1:3:2 [atomic ratio] or the neighborhood thereof, or a metal oxide with a composition of In:Ga:Zn =1:3:4 [atomic ratio] or the neighborhood thereof.

The pair of oxide layers between which the oxide layer 130a is interposed preferably has a larger band gap than the oxide layer 130a. Accordingly, the oxide layer 130a is interposed between the pair of oxide layers with a large band gap, and functions as a main current path (channel). When the oxide layer 130a is interposed between the pair of oxide layers, the trap states at and near the interface with the oxide layer 130a can be reduced. Accordingly, a buried-channel transistor where a channel is away from the interface with an insulating layer can be achieved, whereby the field-effect mobility can be increased. Furthermore, the influence of interface states that might be formed on the back channel side is reduced, so that light deterioration (e.g., light negative bias deterioration) of the transistor can be inhibited and the reliability of the transistor can be increased.

The thicknesses of the semiconductor layer 130 and the semiconductor layer 230 are each preferably greater than or equal to 3 nm and less than or equal to 200 nm, further preferably greater than or equal to 3 nm and less than or equal to 100 nm, still further preferably greater than or equal to 5 nm and less than or equal to 100 nm, yet still further preferably greater than or equal to 10 nm and less than or equal to 100 nm, yet still further preferably greater than or equal to 10 nm and less than or equal to 70 nm, yet still further preferably greater than or equal to 15 nm and less than or equal to 70 nm, yet still further preferably greater than or equal to 15 nm and less than or equal to 50 nm, yet still further preferably greater than or equal to 20 nm and less than or equal to 50 nm. In a transistor used for a miniaturized semiconductor device, the thicknesses of the semiconductor layer 130 and the semiconductor layer 230 are each preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm.

In formation of the oxide semiconductor layer, two kinds of film formation methods, that is, a sputtering method and an ALD method, are preferably used. For example, after a first oxide semiconductor layer having a CAAC structure is formed by a sputtering method, a second oxide semiconductor layer having lower crystallinity than the CAAC structure is formed by an ALD method, in which case an atomic layer of the second oxide semiconductor layer is expected to fill or repair a gap between crystal parts in the atomic level in the CAAC structure of the first oxide semiconductor layer. After the second oxide semiconductor layer is formed by an ALD method, heat treatment (e.g., at a temperature higher than or equal to 100 ° C and lower than or equal to 500 ° C, preferably higher than or equal to 200 ° C and lower than or equal to 450 ° C, further preferably higher than or equal to 300 ° C and lower than or equal to 400 ° C) is preferably performed. By the heat treatment, the gap between crystal parts in the atomic level in the CAAC structure of the first oxide semiconductor layer is expected to be repaired by the second oxide semiconductor layer (i.e., crystal molecules formed by the ALD method). The oxide semiconductor layer formed by the two kinds of film formation methods may be referred to as a hybrid OS.

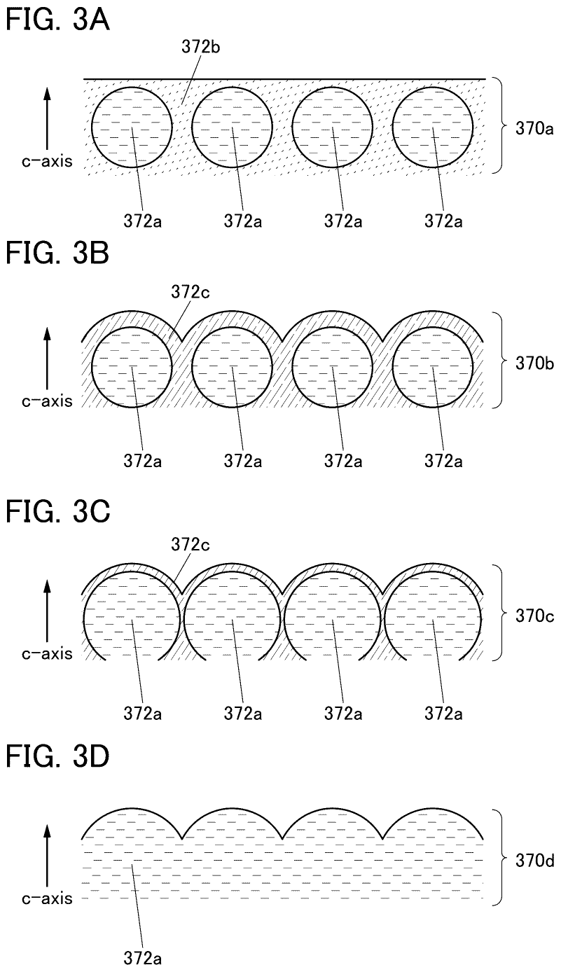

Here, a concept of the heat treatment that increases the crystallinity of an oxide semiconductor layer is described with reference to FIG. 3A, FIG. 3B, FIG. 3C, and FIG. 3D. Note that FIG. 3A, FIG. 3B, FIG. 3C, and FIG. 3D are conceptual diagrams each illustrating a cross section of an oxide semiconductor layer having a CAAC structure. In each of the diagrams, the c-axis is indicated by an arrow.

An oxide semiconductor layer 370a illustrated in FIG. 3A includes regions 372a and a region 372b located between the regions 372a. The regions 372a each correspond to a region having a CAAC structure (i.e., a structure including a layered crystal part), and the region 372b corresponds to a region between the CAAC structures. The CAAC structure has fewer crystal grain boundaries in the a-b plane than a polycrystalline structure. As described above, even in the oxide semiconductor layer 370a having the CAAC structure, a minute gap or a minute space (the region 372b in FIG. 3A) can exist between crystal parts, in some cases.

In view of the above, in order to increase the crystallinity of an oxide semiconductor layer, in other words, in order to reduce the region 372b illustrated in FIG. 3A, after an oxide semiconductor layer having a CAAC structure is formed by a sputtering method as the first oxide semiconductor layer, an oxide semiconductor layer having a microcrystalline structure or an amorphous structure with lower crystallinity than the CAAC structure is formed by an ALD method as the second oxide semiconductor layer.

Specifically, as illustrated in FIG. 3B, after an oxide semiconductor layer including the regions 372a is formed by a sputtering method as the first oxide semiconductor layer, an oxide semiconductor layer including a region 372c having lower crystallinity than the CAAC structure is formed by an ALD method as the second oxide semiconductor layer. In FIG. 3B, an oxide semiconductor layer 370b includes the regions 372a and the region 372c. Since atomic layers can be deposited one by one by an ALD method, the second oxide semiconductor layer can be formed so as to fill the region 372b.

Then, heat treatment is performed, whereby the regions 372a included in the first oxide semiconductor layer serve as seeds and the crystallinity of the region 372c included in the second oxide semiconductor layer is increased. In other words, the regions 372a included in the first oxide semiconductor layer serve as seeds, whereby crystal growth of the region 372c included in the second oxide semiconductor layer can be achieved. Alternatively, the regions 372a of the first oxide semiconductor layer having the CAAC structure serve as nuclei, whereby crystal growth of the region 372c included in the second oxide semiconductor layer having the amorphous structure can be achieved. The model of this crystal growth can be regarded as a concept equivalent to hetero epitaxy. In FIG. 3C, an oxide semiconductor layer 370c includes the regions 372a and the region 372c. The regions 372a illustrated in FIG. 3C are each a region with higher crystallinity or higher density of crystal parts than the regions 372a illustrated in FIG. 3B. By the heat treatment, the crystallinity of one or both of the regions 372a and the region 372c can be increased. The region 372c includes a crystal part having the same crystal structure as the crystal part included in the regions 372a, for example. Alternatively, the region 372c includes a crystal part that is connected with the crystal part included in the regions 372a, for example.

In FIG. 3D, an oxide semiconductor layer 370d includes the region 372a. The region 372a is a region having higher crystallinity than the regions 372a illustrated in FIG. 3B and FIG. 3C, where there is no boundary between the region 372a and the region 372c or a boundary is not observed between the region 372a and the region 372c. Thus, the entire oxide semiconductor layer 370d has a CAAC structure. When the entire oxide semiconductor layer 370d has a CAAC structure as illustrated in FIG. 3D, a highly reliable semiconductor device can be achieved. Whether there is a boundary between the region 372a and the region 372c can be checked with a cross-sectional TEM, a cross-sectional STEM, or the like, for example.

Even in the case where a minute gap or a minute space is included in the first oxide semiconductor layer, forming the second oxide semiconductor layer over the first oxide semiconductor layer or forming the second oxide semiconductor layer and performing heat treatment can fill the minute gap or the minute space in the first oxide semiconductor layer. When an oxide semiconductor layer having a CAAC structure is used as the first oxide semiconductor layer and an oxide semiconductor layer having a microcrystalline structure or an amorphous structure is used as the second oxide semiconductor layer in this manner, a dense oxide semiconductor layer with increased crystallinity density can be provided. When the dense oxide semiconductor layer with increased crystallinity density is used in a channel formation region of a transistor, an increase in electric resistance of the oxide semiconductor layer can be inhibited or initial characteristics (particularly on-state current) of the transistor can be improved; thus, the transistor suitable for high-speed operation can be expected.

In the case where oxide semiconductor layers are formed by a sputtering method and an ALD method and the oxide semiconductor layer formed by an ALD method is thin, the obtained oxide semiconductor layers can be regarded as not a stacked-layer structure of the oxide semiconductor layer formed by a sputtering method and the oxide semiconductor layer formed by an ALD method, but an oxide semiconductor layer having a single-layer structure. For example, when the thickness of the oxide semiconductor layer formed by an ALD method is greater than 0 nm and less than or equal to 3 nm, preferably greater than 0 nm and less than or equal to 2 nm, further preferably greater than 0 nm and less than or equal to 1 nm, the oxide semiconductor layers formed by two kinds of film formation methods, which are a sputtering method and an ALD method, can be regarded as an oxide semiconductor layer having a single-layer structure. In such a case, for example, a boundary between the oxide semiconductor layer formed by a sputtering method and the oxide semiconductor layer formed by an ALD method is not observed in a cross-sectional TEM image, a cross-sectional STEM image, or the like. In contrast, when the thickness of the oxide semiconductor layer formed by an ALD method exceeds 3 nm, the oxide semiconductor layers can be regarded as a stacked-layer structure, a multilayer structure, or a multi-structure of the oxide semiconductor layer formed by a sputtering method and the oxide semiconductor layer formed by an ALD method in some cases.

In the case where the oxide semiconductor layer is formed by both a sputtering method and an ALD method, the oxide semiconductor formed by a sputtering method and the oxide semiconductor formed by an ALD method preferably have different compositions from each other. Typically, a metal oxide with a composition of In:Ga:Zn=1:1:1 [atomic ratio] or the neighborhood thereof can be formed by a sputtering method, and then a metal oxide with a composition of In:Ga:Zn=4:0.1:1 [atomic ratio] or the neighborhood thereof can be formed by an ALD method. The oxide semiconductor layer having the above composition can have high reliability owing to the metal oxide layer with a composition of In:Ga:Zn=1:1:1 [atomic ratio] and have a high on-state current or high field-effect mobility owing to the metal oxide with a composition of In:Ga:Zn=4:0.1:1 [atomic ratio] or the neighborhood thereof. Instead of the metal oxide with a composition of In:Ga:Zn=4:0.1:1 [atomic ratio] or the neighborhood thereof, a metal oxide with a composition of In:Ga:Zn=1:0:0 [atomic ratio], that is, indium oxide or a metal oxide with a high In proportion can be used.

The oxide semiconductor layer formed by the two kinds of film formation methods can be regarded as having a structure where a space between crystal parts of the CAAC structure is filled with an atomic layer formed by an ALD method. Note that this structure can be analyzed by analysis methods such as a cross-sectional SEM, a cross-sectional STEM, a cross-sectional TEM, SIMS, and EDX.

The oxide semiconductor layer having the CAAC structure formed by the two kinds of film formation methods sometimes has one or more of a higher dielectric constant, higher film density, and higher film hardness than an oxide semiconductor layer having the CAAC structure formed by one kind of film formation method. With the use of the oxide semiconductor layer having the CAAC structure formed by two kinds of film formation methods for a channel formation region of a transistor as described above, the transistor can have excellent characteristics (e.g., high on-state current, high field-effect mobility, a low S value, high frequency characteristics (also referred to as f characteristics), or high reliability).

Hydrogen contained in the oxide semiconductor reacts with oxygen bonded to a metal atom to be water, and thus sometimes forms an oxygen vacancy (Vo) in the oxide semiconductor. A defect where hydrogen enters an oxygen vacancy (hereinafter, referred to as VoH) serves as a donor and generates an electron serving as a carrier in some cases. In other cases, bonding of part of hydrogen to oxygen bonded to a metal atom generates an electron serving as a carrier. Thus, a transistor including an oxide semiconductor that contains a large amount of hydrogen is likely to be normally-on (that is, the threshold voltage is likely to be a negative value). Moreover, hydrogen in an oxide semiconductor easily moves by stress such as heat and an electric field; thus, the reliability of a transistor may be low when the oxide semiconductor contains a plenty of hydrogen.

It is preferable that VoH in the semiconductor layer 130 and the semiconductor layer 230 be reduced as much as possible to make the semiconductor layer 130 and the semiconductor layer 230 highly purified intrinsic or substantially highly purified intrinsic. It is important to remove impurities such as water and hydrogen in an oxide semiconductor (sometimes described as dehydration or dehydrogenation treatment) and to repair oxygen vacancies by supplying oxygen to the oxide semiconductor to obtain an oxide semiconductor whose VoH is reduced enough. When an oxide semiconductor in which impurities such as VoH are sufficiently reduced is used for a channel formation region in a transistor, the transistor can have stable electrical characteristics. Note that repairing oxygen vacancies by supplying oxygen to an oxide semiconductor is sometimes referred to as oxygen adding treatment.

The carrier concentration of the oxide semiconductor in a region functioning as the channel formation region is preferably lower than or equal to 1×10¹⁸cm⁻³ , further preferably lower than 1×10¹⁷cm⁻³, still further preferably lower than 1×10¹⁶cm⁻³, yet further preferably lower than 1×10¹³cm⁻³, and yet still further preferably lower than 1×10¹²cm⁻3. The minimum carrier concentration of an oxide semiconductor in the region functioning as the channel formation region is not limited and can be 1×10⁻⁹ cm⁻3, for example.

The influence of impurities in the metal oxide (oxide semiconductor) will be described here.

When silicon or carbon, which is a Group 14 element, is contained in the oxide semiconductor, defect states are formed in the oxide semiconductor. Thus, the carbon concentration in the channel formation region of the oxide semiconductor, which is measured by SIMS, is lower than or equal to 1×10²⁰atoms/cm³, preferably lower than or equal to 5×10¹⁹ atoms/cm³, further preferably lower than or equal to 3×10¹⁹atoms/cm³, further preferably lower than or equal to 1×10¹⁹atoms/cm³, still further preferably lower than or equal to 3×10¹⁸ atoms/cm³, yet still further preferably lower than or equal to 1×10¹⁸atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³.

When containing nitrogen, the oxide semiconductor easily becomes n-type by generation of electrons serving as carriers and an increase in carrier concentration. Thus, a transistor using an oxide semiconductor that contains nitrogen as a semiconductor is likely to be normally-on. When nitrogen is contained in the oxide semiconductor, a trap state is sometimes formed. This might make the electrical characteristics of the transistor unstable. Thus, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, still further preferably lower than or equal to 1×10¹⁸ atoms/cm³, yet still further preferably lower than or equal to 5×10¹⁷ atoms/cm³.

Hydrogen contained in an oxide semiconductor reacts with oxygen bonded to a metal atom to be water, and thus sometimes causes oxygen vacancies. Entry of hydrogen into the oxygen vacancy generates an electron serving as a carrier in some cases. Furthermore, bonding of part of hydrogen to oxygen bonded to a metal atom generates an electron serving as a carrier. Thus, a transistor including an oxide semiconductor that contains hydrogen is likely to be normally-on. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³.

When the oxide semiconductor contains an alkali metal or an alkaline earth metal, defect states are formed and carriers are generated, in some cases. Thus, a transistor including an oxide semiconductor that contains alkali metal or alkaline earth metal is likely to be normally-on. Thus, the concentration of alkali metal or alkaline earth metal in the channel formation region of the oxide semiconductor measured by SIMS is set lower than or equal to 1×10¹⁸ atoms/cm³, preferably lower than or equal to 2×10¹⁶ atoms/cm³.

When an oxide semiconductor with sufficiently reduced impurity concentration is used for a channel formation region in a transistor, the transistor can have stable electrical characteristics.

Note that for the semiconductor device of this embodiment, a transistor containing another semiconductor material in a channel formation region may be used. Examples of another semiconductor material include a single-element semiconductor and a compound semiconductor. Examples of the single-element semiconductor include silicon and germanium. Examples of the compound semiconductor include gallium arsenide and silicon germanium. Other examples of the compound semiconductor include an organic semiconductor and a nitride semiconductor. Note that the above-described oxide semiconductor is also one kind of the compound semiconductor. These semiconductor materials may contain an impurity as a dopant.

Examples of silicon that can be used as a semiconductor material of a transistor include single crystal silicon, polycrystalline silicon, microcrystalline silicon, and amorphous silicon. An example of polycrystalline silicon is low-temperature polysilicon (LTPS).

Alternatively, a semiconductor layer of a transistor may include a layered material functioning as a semiconductor. The layered material generally refers to a group of materials having a layered crystal structure. In the layered crystal structure, layers formed by covalent bonding or ionic bonding are stacked with bonding such as the Van der Waals bonding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, the transistor can have a high on-state current.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### Insulating Layers

An inorganic insulating film is preferably used for each of the insulating layers (the insulating layer 110, the insulating layer 150, the insulating layer 180, the insulating layer 250, the insulating layer 280, the insulating layer 283, and the insulating layer 285, and the like) included in the semiconductor device. Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film may be used for the insulating layer included in the semiconductor device.

With further miniaturization and higher integration of a transistor, for example, a problem such as generation of a leakage current may arise because of a thinned gate insulating layer. When a high-k material is used for the gate insulating layer, the voltage at the time of operation of the transistor can be reduced while the physical thickness is maintained. In addition, the equivalent oxide thickness (EOT) of the gate insulating layer can be reduced. By contrast, when a material with a low dielectric constant is used for an insulating layer functioning as an interlayer film, parasitic capacitance generated between wirings can be reduced. Thus, a material is preferably selected depending on the function of an insulating layer. Note that a material with a low dielectric constant is a material with high dielectric strength.

Examples of a material with a high dielectric constant (a high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with a low dielectric constant include inorganic insulating materials such as silicon oxide, silicon oxynitride, and silicon nitride oxide, and resins such as polyester, polyolefin, polyamide (e.g., nylon and aramid), polyimide, polycarbonate, and an acrylic resin. Other examples of an inorganic insulating material with a low dielectric constant include silicon oxide to which fluorine is added, silicon oxide to which carbon is added, and silicon oxide to which carbon and nitrogen are added. Another example is porous silicon oxide. Note that these silicon oxides may contain nitrogen.

A material that can show ferroelectricity may be used for an insulating layer included in the semiconductor device. Examples of the material that can show ferroelectricity include metal oxides such as hafnium oxide, zirconium oxide, and HfZrO_{X} (X is a real number greater than 0). Examples of the material that can show ferroelectricity also include a material in which an element J1 (the element J1 here is one or more selected from zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 is, for example, 1:1 or the neighborhood thereof. Examples of the material that can show ferroelectricity also include a material in which an element J2 (the element J2 here is one or more selected from hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 is, for example, 1:1 or the neighborhood thereof. As the material that can show ferroelectricity, a piezoelectric ceramic having a perovskite structure, such as lead titanate (PbTiOx), barium strontium titanate (BST), strontium titanate, lead zirconate titanate (PZT), strontium bismuth tantalate (SBT), bismuth ferrite (BFO), or barium titanate, may be used.

Examples of the material that can show ferroelectricity also include a metal nitride containing an element M1, an element M2, and nitrogen. Here, the element M1 is one or more selected from aluminum, gallium, indium, and the like. The element M2 is one or more selected from boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen shows ferroelectricity in some cases even though the metal oxide does not contain the element M2. Examples of the material that can show ferroelectricity also include the above metal nitride to which an element M3 is added. Note that the element M3 is one or more selected from magnesium, calcium, strontium, zinc, cadmium, and the like. Here, the atomic ratio between the element M1, the element M2, and the element M3 can be set as appropriate.

Examples of the material that can show ferroelectricity also include perovskite-type oxynitrides such as SrTaO₂N and BaTaO₂N, and GaFeO₃ with a k-alumina-type structure.

Although metal oxides and metal nitrides are described above as examples, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can show ferroelectricity, a mixture or compound containing a plurality of materials selected from the above-listed materials can be used, for example. Alternatively, the insulating layer included in the semiconductor device can have a stacked-layer structure of a plurality of materials selected from the above-listed materials. Since the above-listed materials may change their crystal structures (characteristics) according to, for example, a variety of processes and the like as well as film formation conditions, a material that exhibits ferroelectricity is referred to not only as a ferroelectric but also as a material that can show ferroelectricity in this specification and the like.

A metal oxide containing one or both of hafnium and zirconium can have ferroelectricity even when being processed into a thin film of several nanometers. A metal oxide containing one or both of hafnium and zirconium can have ferroelectricity even with a minute area. Accordingly, the use of a metal oxide containing one or both of hafnium and zirconium enables miniaturization of the semiconductor device.

Note that in this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

Note that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulating layer can exhibit ferroelectricity, the insulating layer needs to include a crystal. It is particularly preferable that the insulating layer include a crystal having an orthorhombic crystal structure, in which case ferroelectricity is exhibited. A crystal included in the insulating layer may have one or more of crystal structures selected from cubic, tetragonal, orthorhombic, monoclinic, and hexagonal crystal structures. Alternatively, the insulating layer may have an amorphous structure. In that case, the insulating layer may have a composite structure including an amorphous structure and a crystal structure.

Addition of a Group 3 element (also referred to as IIIa element) in the periodic table to an oxide containing one or both of hafnium and zirconium increases the oxygen vacancy concentration in the oxide and facilitates formation of a crystal having an orthorhombic crystal structure. This is preferable because the proportion of the crystal having an orthorhombic crystal structure is increased and the amount of remanent polarization can be increased. On the other hand, too much addition of the Group 3 element might decrease the crystallinity of the oxide and hinder the exhibition of ferroelectricity. Thus, the content percentage of the Group 3 element in the oxide containing one or both of hafnium and zirconium is preferably higher than or equal to 0.1 atomic % and lower than or equal to 10 atomic %, further preferably higher than or equal to 0.1 atomic% and lower than or equal to 5 atomic %, still further preferably higher than or equal to 0.1 atomic% and lower than or equal to 3 atomic %. Here, the content percentage of the Group 3 element refers to the proportion of the number of the Group 3 element atoms in the total number of atoms of all the metal elements contained in the layer. The Group 3 element is preferably one or more selected from scandium, lanthanum, and yttrium, further preferably one or both of lanthanum and yttrium.

A transistor including a metal oxide can have stable electrical characteristics when surrounded by an insulating layer having a function of inhibiting passage of impurities and oxygen. The insulating layer having a function of inhibiting passage of impurities and oxygen can have, for example, a single-layer structure or a stacked-layer structure of an insulating layer containing one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, as a material for the insulating layer having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, silicon nitride oxide, or silicon nitride can be used.

Specifically, as the insulating layer having a function of inhibiting passage of oxygen and impurities such as water and hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide can be used. Other examples of the insulating layer having a function of inhibiting passage of oxygen and impurities such as water and hydrogen include oxides containing aluminum and hafnium (hafnium aluminate). Other examples of the insulating layer having a function of inhibiting passage of oxygen and impurities such as water and hydrogen include metal nitrides such as aluminum nitride, aluminum titanium nitride, titanium nitride, silicon nitride oxide, and silicon nitride.

In addition, an insulating layer in contact with an oxide semiconductor layer, such as a gate insulating layer, or an insulating layer provided in the vicinity of the oxide semiconductor layer preferably includes a region containing oxygen (hereinafter, sometimes referred to as excess oxygen) that is released by heating. For example, when an insulating layer including a region containing excess oxygen is in contact with an oxide semiconductor layer or located in the vicinity of the oxide semiconductor layer, oxygen vacancies in the oxide semiconductor layer can be reduced. Examples of an insulating layer in which a region containing excess oxygen is easily formed include silicon oxide, silicon oxynitride, and porous silicon oxide.

The insulating layer 110 functions as an interlayer film and preferably has a low dielectric constant. In the case where a material with a low dielectric constant is used for an interlayer film, the parasitic capacitance generated between wirings can be reduced. Silicon oxide and silicon oxynitride are thermally stable, and thus are suitable for the insulating layer 110.

The concentration of impurities such as water and hydrogen in the insulating layer 110 is preferably reduced. This can inhibit entry of impurities such as water and hydrogen into the channel formation region of the semiconductor layer 130, for example.

As the insulating layer 110, a barrier insulating layer against hydrogen is preferably used. When the insulating layer 110 provided outside the semiconductor layer 130 has a barrier property against hydrogen, diffusion of hydrogen into the semiconductor layer 130 can be inhibited for example.

Examples of a material for a barrier insulating layer against hydrogen include aluminum oxide, magnesium oxide, hafnium oxide, gallium oxide, indium gallium zinc oxide, silicon nitride, and silicon nitride oxide.

Note that in this specification and the like, a barrier insulating layer refers to an insulating layer having a barrier property. A barrier property refers to a property of hardly diffusing a particular substance (also referred to as a property of hardly transmitting a particular substance, a low permeability of a particular substance, or a function of inhibiting diffusion of a particular substance). Note that hydrogen described as a target substance refers to at least one of a hydrogen atom, a hydrogen molecule, a substance bonded to hydrogen, such as a water molecule and OH⁻, and the like. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), a copper atom, and the like. Oxygen described as a target substance refers to, for example, at least one of an oxygen atom, an oxygen molecule, and the like.

For example, a silicon nitride film is preferably used as the insulating layer 110.

Each of the insulating layer 180 and the insulating layer 280 preferably includes the above-described barrier insulating layer against hydrogen. The insulating layer 180 is provided to surround the semiconductor layer 130. The insulating layer 280 is provided to surround the semiconductor layer 230. When the insulating layer 180 provided outside the semiconductor layer 130 has a barrier property against hydrogen, diffusion of hydrogen into the semiconductor layer 130 can be inhibited. Similarly, when the insulating layer 280 provided outside the semiconductor layer 230 has a barrier property against hydrogen, diffusion of hydrogen into the semiconductor layer 230 can be inhibited. For example, each of the insulating layer 180 and the insulating layer 280 preferably includes one or both of an aluminum oxide film and a silicon nitride film.

Note that silicon nitride also has a barrier property against oxygen. Thus, using silicon nitride for the insulating layer 180 can inhibit extraction of oxygen from the semiconductor layer 130. This can inhibit formation of an excess amount of oxygen vacancies in the semiconductor layer 130. Similarly, using silicon nitride for the insulating layer 280 can inhibit extraction of oxygen from the semiconductor layer 230. This can inhibit formation of an excess amount of oxygen vacancies in the semiconductor layer 230.

Furthermore, when silicon nitride is used for the insulating layer 180, excess oxygen can be prevented from being supplied to the semiconductor layer 130. Thus, the channel formation region of the semiconductor layer 130 can be prevented from containing excess oxygen, whereby the reliability of the transistor 100 can be improved. Similarly, when silicon nitride is used for the insulating layer 280, the reliability of the transistor 200 can be improved.

Each of the insulating layer 180 and the insulating layer 280 preferably includes any of an oxide insulating film, an oxynitride insulating film, and an insulating layer including a region containing excess oxygen, which are described above.

For example, the insulating layer including a region containing excess oxygen can be formed by a sputtering method in an atmosphere containing oxygen. Here, a sputtering method does not need to use a molecule containing hydrogen as a film formation gas. Thus, using a sputtering method for forming the insulating layer 180 and the insulating layer 280 can reduce the hydrogen concentrations in the insulating layer 180 and the insulating layer 280. When at least one layer in the insulating layer 180 is formed by a sputtering method in this manner, oxygen can be supplied from the insulating layer 180 to the channel formation region of the semiconductor layer 130, so that oxygen vacancies and VoH therein can be reduced. Furthermore, when at least one layer in the insulating layer 280 is formed by a sputtering method in this manner, oxygen can be supplied from the insulating layer 280 to the channel formation region of the semiconductor layer 230, so that oxygen vacancies and VoH therein can be reduced.

The concentrations of impurities such as water or hydrogen in the insulating layer 180 and the insulating layer 280 are preferably reduced. In that case, impurities such as water or hydrogen can be inhibited from entering the channel formation region of the semiconductor layer 130 and the channel formation region of the semiconductor layer 230.

Note that since the thickness of the insulating layer 180 over the conductive layer 120 corresponds to the channel length of the transistor 100. Thus, the thickness of the insulating layer 180 is set as appropriate depending on the design value of the channel length of the transistor 100. Similarly, since the thickness of the insulating layer 280 over the conductive layer 220 corresponds to the channel length of the transistor 200. Thus, the thickness of the insulating layer 280 is set as appropriate depending on the design value of the channel length of the transistor 200.

For example, a single-layer structure of a silicon nitride film, a silicon nitride oxide film, or an aluminum oxide film is preferably used for each of the insulating layer 180 and the insulating layer 280. Alternatively, for example, a three-layer structure where a silicon nitride film, a silicon oxide film, and a silicon nitride film are stacked in this order is preferably used for each of the insulating layer 180 and the insulating layer 280. For example, a three-layer structure where an aluminum oxide film, a silicon oxide film, and an aluminum oxide film are stacked in this order is preferably used for each of the insulating layer 180 and the insulating layer 280.

The insulating layer 150 and the insulating layer 250 preferably have a function of trapping and fixing hydrogen. In that case, the hydrogen concentrations in the semiconductor layer 130 and the semiconductor layer 230 (in particular, the hydrogen concentrations in the channel formation regions of the transistors) can be reduced. Accordingly, VoH in the channel formation regions can be reduced, so that the channel formation regions can be i-type or substantially i-type regions.

Examples of a material for an insulating layer having a function of capturing or fixing hydrogen include metal oxides such as an oxide containing hafnium, an oxide containing magnesium, an oxide containing aluminum, and an oxide containing aluminum and hafnium (hafnium aluminate). Furthermore, these metal oxides may further contain zirconium, and an example of such a metal oxide is an oxide containing hafnium and zirconium. Note that in a metal oxide having an amorphous structure, some oxygen atoms have a dangling bond, which allows the metal oxide to have a high property of capturing or fixing hydrogen. Thus, these metal oxides preferably have an amorphous structure. For example, these oxides may have an amorphous structure by containing silicon. For example, an oxide containing hafnium and silicon (hafnium silicate) is preferably used. Note that the metal oxide may partly include one or both of a crystal region and a crystal grain boundary.

Note that a function of capturing or fixing a target substance can also be referred to as a property that does not easily allow diffusion of a target substance. Thus, a function of capturing or fixing a target substance can be rephrased as a barrier property.

In the case where the gate insulating layers have a stacked-layer structure, a layer in contact with the semiconductor layer 130 and a layer in contact with the semiconductor layer 230 preferably have a function of capturing or fixing hydrogen. In that case, hydrogen contained in the semiconductor layer 130 and hydrogen contained in the semiconductor layer 230 can be captured or fixed more effectively. Thus, the hydrogen concentrations in the semiconductor layer 130 and the semiconductor layer 230 can be reduced. For example, hafnium silicate is preferably used for the layer of the insulating layer 150 that is in contact with the semiconductor layer 130 and the layer of the insulating layer 250 that is in contact with the semiconductor layer 230. The layers preferably have an amorphous structure.

When the layers have an amorphous structure, formation of a crystal grain boundary can be inhibited. Inhibiting formation of a crystal grain boundary can increase the planarity of the layers. Accordingly, the thickness distributions of the insulating layer 150 and the insulating layer 250 can be uniform, so that a region with an extremely small thickness can be reduced. Thus, the withstand voltages of the insulating layer 150 and the insulating layer 250 can be improved. Furthermore, the thickness distributions of the films provided over the insulating layer 150 and the insulating layer 250 can be uniform.

Furthermore, inhibiting formation of a crystal grain boundary in the layers can reduce a leakage current due to the defect states in the crystal grain boundary. Thus, the insulating layer 150 and the insulating layer 250 can function as insulating films with a small leakage current.

Since hafnium oxide is a high dielectric constant (high-k) material, hafnium silicate becomes a high dielectric constant (high-k) material depending on the content of silicon. Thus, in the case where hafnium oxide or hafnium silicate is used for the gate insulating layer, a gate potential applied at the time of operation of the transistor can be reduced while the physical thickness of the gate insulating layer is maintained. In addition, the equivalent oxide thickness (EOT) of the gate insulating layer can be reduced.

As described above, for each of the insulating layer 150 and the insulating layer 250, an oxide containing one or both of aluminum and hafnium is preferably used, more preferably, an oxide containing one or both of aluminum and hafnium and having an amorphous structure is used, and further preferably, aluminum oxide having an amorphous structure is used.

As each of the insulating layer 150 and the insulating layer 250, the above-described barrier insulating layer against hydrogen is preferably used. When a barrier insulating layer against hydrogen is used as the insulating layer 150, diffusion of impurities contained in the conductive layer 220 into the semiconductor layer 130 can be inhibited. Similarly, when a barrier insulating layer against hydrogen is used as the insulating layer 250, diffusion of impurities contained in the conductive layer 220 into the semiconductor layer 230 can be inhibited. For example, silicon nitride is suitable for the insulating layer 150 and the insulating layer 250 because of its high barrier property against hydrogen.

With such a structure, a semiconductor device having favorable electrical characteristics can be provided. A highly reliable semiconductor device can be provided. A semiconductor device with a small variation in transistor's electrical characteristics can be provided. A semiconductor device that has a high on-state current can be provided.

Furthermore, each of the insulating layer 150 and the insulating layer 250 may include a thermally stable insulating layer such as silicon oxide or silicon oxynitride.

Each of the insulating layer 150 and the insulating layer 250 may include, between a pair of insulating layers having a function of capturing and fixing hydrogen, a thermally stable insulating layer.

Each of the insulating layer 150 and the insulating layer 250 preferably includes a barrier insulating layer against oxygen. Thus, oxidation of the conductive layer 140, the conductive layer 220, the conductive layer 240, the conductive layer 260, and the like can be inhibited. In the case where the insulating layer 150 and the insulating layer 250 each have a stacked-layer structure, a layer in contact with the conductive layer 140 or the conductive layer 240 is preferably a barrier insulating layer against oxygen. In particular, a layer in contact with the conductive layer 140, a layer in contact with the conductive layer 220, a layer in contact with the conductive layer 240, and a layer in contact with the conductive layer 260, which are included in the insulating layer 150 and the insulating layer 250, are preferably barrier insulating layers against oxygen.

When a barrier insulating layer against hydrogen and oxygen is used as the layer of the insulating layer 150 which is in contact with the conductive layer 220, oxidation of the conductive layer 220 can be inhibited. Furthermore, diffusion of oxygen contained in the semiconductor layer 130 into the conductive layer 220 can be inhibited, and accordingly formation of oxygen vacancies in the semiconductor layer 130 can be inhibited. Similarly, when a barrier insulating layer against hydrogen and oxygen is used as the layer of the insulating layer 250 which is in contact with the conductive layer 260, oxidation of the conductive layer 260 can be inhibited. Furthermore, diffusion of oxygen contained in the semiconductor layer 230 into the conductive layer 260 can be inhibited, and accordingly formation of oxygen vacancies in the semiconductor layer 230 can be inhibited.

Examples of the barrier insulating layer against oxygen include an oxide containing one or both of aluminum and hafnium, magnesium oxide, gallium oxide, gallium zinc oxide, indium gallium zinc oxide, silicon nitride, and silicon nitride oxide. Examples of the oxide containing aluminum and/or hafnium include aluminum oxide, hafnium oxide, an oxide containing aluminum and hafnium (hafnium aluminate), and an oxide containing hafnium and silicon (hafnium silicate).

The layer of the insulating layer 150 which is in contact with the conductive layer 140 is preferably less likely to transmit oxygen than at least the insulating layer 180. When the layer has a barrier property against oxygen, oxidation of the side surface of the conductive layer 140 can be inhibited, and accordingly formation of an oxide film on the side surface can be inhibited. It is thus possible to inhibit a reduction in the on-state current or field-effect mobility of the transistor 100.

Similarly, the layer of the insulating layer 250 which is in contact with the conductive layer 240 is preferably less likely to transmit oxygen than at least the insulating layer 280. When the layer has a barrier property against oxygen, oxidation of the side surface of the conductive layer 240 can be inhibited, and accordingly formation of an oxide film on the side surface can be inhibited. It is thus possible to inhibit a reduction in the on-state current or field-effect mobility of the transistor 200.

Each layer included in the insulating layer 150 and the insulating layer 250 is preferably a thin film. For example, when the insulating layer 150 and the insulating layer 250 each have a thickness greater than or equal to 1 nm and less than or equal to 20 nm, preferably greater than or equal to 3 nm and less than or equal to 10 nm, the subthreshold swing value (also referred to as S value), which is one of transistor characteristics, can be reduced. Note that the S value means the amount of change in gate voltage in the subthreshold region when the drain voltage is constant and the drain current is changed by one order of magnitude.

The thickness of each layer included in the insulating layer 150 and the insulating layer 250 is preferably greater than or equal to 0.1 nm and less than or equal to 10 nm, further preferably greater than or equal to 0.1 nm and less than or equal to 5 nm, further preferably greater than or equal to 0.5 nm and less than or equal to 5 nm, further preferably greater than or equal to 1 nm and less than or equal to 5 nm, further preferably greater than or equal to 1 nm and less than or equal to 3 nm.

The insulating layer 150 and the insulating layer 250 preferably have a three-layer structure where a first insulating layer containing a material with a low dielectric constant, a second insulating layer having a function of capturing or fixing hydrogen, and a third insulating layer having a barrier property against hydrogen and oxygen are stacked in this order from the semiconductor layer 130 side and the semiconductor layer 230 side, respectively. As the material with a low dielectric constant contained in the first insulating layer, silicon oxide or silicon oxynitride is preferably used. The first insulating layer is in contact with the semiconductor layer 130 or the semiconductor layer 230. When an oxide is used for the first insulating layer, oxygen can be supplied to the semiconductor layer 130 and the semiconductor layer 230. Providing the third insulating layer can inhibit diffusion of oxygen contained in the first insulating layer into the conductive layer 220 and the conductive layer 260 and inhibit oxidation of the conductive layer 220 and the conductive layer 260. Furthermore, a reduction in the amount of oxygen supplied from the first insulating layer to the semiconductor layer 130 and the semiconductor layer 230 can be inhibited.

The insulating layer 150 and the insulating layer 250 preferably have a four-layer structure where a fourth insulating layer having a barrier property against oxygen, a first insulating layer containing a material with a low dielectric constant, a second insulating layer having a function of capturing or fixing hydrogen, and a third insulating layer having a barrier property against hydrogen and oxygen are stacked in this order from the semiconductor layer 130 side and the semiconductor layer 230 side, respectively. The first insulating layer to the third insulating layer can have a structure similar to that of the layers used in the above three-layer structure. The fourth insulating layer is in contact with the semiconductor layer 130 or the semiconductor layer 230. When the fourth insulating layer has a barrier property against oxygen, release of oxygen from the semiconductor layer 130 and the semiconductor layer 230 can be inhibited. For the fourth insulating layer, aluminum oxide is preferably used, for example. Aluminum oxide has a function of capturing or fixing hydrogen, and thus is suitably used for the fourth insulating layer in contact with the semiconductor layer 130 or the semiconductor layer 230.

Typically, the thicknesses of the fourth insulating layer, the first insulating layer, the second insulating layer, and the third insulating layer are 1 nm, 2 nm, 2 nm, and 1 nm, respectively. Such a structure enables the transistor to have favorable electrical characteristics even when the transistor is miniaturized or highly integrated.

As the insulating layer 283, a barrier insulating layer against hydrogen is preferably used. In that case, diffusion of hydrogen from above the insulating layer 283 into the semiconductor layer 230 can be inhibited, for example. A silicon nitride film and a silicon nitride oxide film can be suitably used for the insulating layer 283 because they release few impurities (e.g., water and hydrogen) and are less likely to transmit oxygen and hydrogen.

It is particularly preferable to use silicon nitride formed by a sputtering method for the insulating layer 283. A film formation gas in a sputtering method need not include molecules containing hydrogen; thus, the hydrogen concentration in the insulating layer 283 can be reduced. When the insulating layer 283 is formed by a sputtering method, a high-density silicon nitride film can be obtained.

As the insulating layer 283, an insulating layer having a function of capturing or fixing hydrogen may be used. With such a structure, for example, diffusion of hydrogen from above the insulating layer 283 into the semiconductor layer 230 can be inhibited, and hydrogen contained in the semiconductor layer 230 can be captured or fixed. Thus, for example, the hydrogen concentration in the semiconductor layer 230 can be reduced. For the insulating layer 283, aluminum oxide, hafnium oxide, hafnium silicate, or the like can be used.

The insulating layer 283 may have a stacked-layer structure of an insulating layer having a function of capturing or fixing hydrogen and a barrier insulating layer against hydrogen. For example, a stacked-layer film of aluminum oxide and silicon nitride over the aluminum oxide may be used for the insulating layer 283.

The insulating layer 285 functions as an interlayer film and thus is preferably formed using the above-described material with a low dielectric constant. For example, the insulating layer 285 preferably includes a silicon oxide film.

### Conductive Layers

For each of the conductive layers (the conductive layer 120, the conductive layer 140, the conductive layer 220, the conductive layer 240, the conductive layer 260, and the conductive layer 265, and the like) included in the semiconductor device, it is preferable to use a metal element selected from aluminum, chromium, copper, silver, gold, platinum, zinc, tantalum, nickel, titanium, iron, cobalt, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As an alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. A semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. As examples of the conductive material containing oxygen, indium oxide containing tungsten oxide, indium oxide containing titanium oxide, indium tin oxide, indium tin oxide containing titanium oxide, indium tin oxide to which silicon is added, indium zinc oxide (also referred to as IZO (registered trademark)), indium zinc oxide containing tungsten oxide, and the like can be given. In this specification and the like, a conductive film formed using the conductive material containing oxygen may be referred to as an oxide conductive film.

In addition, a conductive material containing tungsten, copper, or aluminum as its main component is preferable because it has high conductivity.

Conductive layers formed using any of the above materials may be stacked. For example, a stacked-layer structure combining a material containing any of the above metal elements and a conductive material containing oxygen may be employed. Alternatively, a stacked-layer structure combining a material containing any of the above metal elements and a conductive material containing nitrogen may be employed. Further alternatively, a stacked-layer structure combining a material containing any of the above metal elements, a conductive material containing oxygen, and a conductive material containing nitrogen may be employed.

In the case where a metal oxide is used for the channel formation region of the transistor, the conductive layer functioning as the gate electrode preferably employs a stacked-layer structure combining a material containing any of the above metal elements and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

Each of the conductive layer 120, the conductive layer 140, the conductive layer 220, and the conductive layer 240 is in contact with the semiconductor layer 130 or the semiconductor layer 230. Thus, each of these conductive layers is preferably formed using a conductive material that is not easily oxidized, a conductive material that maintains its low electric resistance even after being oxidized, a metal oxide having conductivity (also referred to as an oxide conductor), or a conductive material having a function of inhibiting oxygen diffusion. Examples of the conductive material include a conductive material containing nitrogen and a conductive material containing oxygen. Thus, a decrease in conductivity of the conductive layer 120, the conductive layer 140, the conductive layer 220, and the conductive layer 240 can be inhibited.

When a conductive material containing oxygen is used for the conductive layer 120, the conductive layer 140, the conductive layer 220, or the conductive layer 240, the conductivity can be maintained even when the conductive layer 120, the conductive layer 140, the conductive layer 220, or the conductive layer 240 absorbs oxygen. It is also preferable that an insulating layer containing oxygen, such as hafnium oxide, be used as the insulating layer 110 in order that the conductive layer 120 can maintain its conductivity. For each of the conductive layer 120, the conductive layer 140, the conductive layer 220, and the conductive layer 240, ITO, ITSO, IZO (registered trademark), or the like is preferably used, for example.

FIG. 2A illustrates an example where the conductive layer 120 has a three-layer structure of a conductive layer 120a1, a conductive layer 120a2 over the conductive layer 120a1, and the conductive layer 120b over the conductive layer 120a2. FIG. 2A illustrates an example where the conductive layer 220 has a three-layer structure of a conductive layer 220a1, a conductive layer 220a2 over the conductive layer 220a1, and the conductive layer 220b over the conductive layer 220a2.

For example, a conductive material that is not easily oxidized or a conductive material having a function of inhibiting oxygen diffusion is preferably used for the conductive layer 120a1 and the conductive layer 220a1, a material with high conductivity is preferably used for the conductive layer 120a2 and the conductive layer 220a2, and a conductive material containing oxygen (preferably an oxide conductor) is preferably used for the conductive layer 120b and the conductive layer 220b. For example, titanium nitride is preferably used for the conductive layer 120a1 and the conductive layer 220a1, tungsten is preferably used for the conductive layer 120a2 and the conductive layer 220a2, and an oxide conductor (e.g., ITO, ITSO, or IZO (registered trademark)) is preferably used for the conductive layer 120b and the conductive layer 220b. In this case, titanium nitride is in contact with the insulating layer 110 and the oxide conductor is in contact with the semiconductor layer 130 in the conductive layer 120. The oxide conductor is in contact with the semiconductor layer 230 in the conductive layer 220. In addition, an oxide conductor is used for layers closest to the channel formation regions of the semiconductor layer 130 and the semiconductor layer 230. The oxide conductor has lower contact resistance with the semiconductor layer 130 and the semiconductor layer 230 than tungsten. Thus, the current path between the source and the drain of each of the transistor 100 and the transistor 200 can be shortened. Accordingly, the on-state currents of the transistor 100 and the transistor 200 can be increased. Such a structure can maintain conductivity even when the conductive layer 120 is in contact with the semiconductor layer 130. Furthermore, conductivity can be maintained even when the conductive layer 220 is in contact with the semiconductor layer 230. In the case of using an oxide insulating layer as the insulating layer 110, the conductive layer 120 can be inhibited from being excessively oxidized by the insulating layer 110. When a metal material (here, tungsten) having higher conductivity than an oxide conductor and titanium nitride is used for the conductive layer 120a2 and the conductive layer 220a2, the conductivity of the conductive layer 120 and the conductive layer 220 can be increased.

FIG. 2A illustrates the example where the conductive layer 140 has a two-layer structure of the conductive layer 140a and the conductive layer 140b over the conductive layer 140a. Furthermore, FIG. 2A illustrates the example where the conductive layer 240 has a two-layer structure of the conductive layer 240a and the conductive layer 240b over the conductive layer 240a. In that case, a conductive material containing oxygen is preferably used for the conductive layer 140a and the conductive layer 240a, for example. A material with higher conductivity than the conductive layer 140a and the conductive layer 240a is preferably used for the conductive layer 140b and the conductive layer 240b, for example. An oxide conductor (e.g., ITO, ITSO, or IZO (registered trademark)) is preferably used for the conductive layer 140a and the conductive layer 240a, for example. Ruthenium, tungsten, titanium nitride, or tantalum nitride is preferably used for the conductive layer 140b and the conductive layer 240b, for example.

A material with high conductivity, such as tungsten, is preferably used for the conductive layer 260. A conductive material that is not easily oxidized, a conductive material having a function of inhibiting oxygen diffusion, or the like is preferably used for the conductive layer 260. As described above, examples of the conductive material include a conductive material containing nitrogen (e.g., titanium nitride or tantalum nitride) and a conductive material containing oxygen (e.g., ruthenium oxide). Thus, a decrease in conductivity of the conductive layer 260 can be inhibited.

It is particularly preferable to use, for the conductive layer 260, a conductive material containing oxygen and a metal element contained in the metal oxide where a channel is formed. Alternatively, a conductive material containing the above metal element and nitrogen (e.g., titanium nitride or tantalum nitride) may be used. One or more of an indium tin oxide, an indium oxide containing tungsten oxide, an indium zinc oxide containing tungsten oxide, an indium oxide containing titanium oxide, an indium tin oxide containing titanium oxide, an indium zinc oxide, and an indium tin oxide to which silicon is added may be used. An indium gallium zinc oxide containing nitrogen may be used. With the use of such a material, hydrogen contained in the metal oxide where a channel is formed can be captured in some cases. Alternatively, hydrogen entering from a surrounding insulating layer or the like can be captured in some cases.

FIG. 2A illustrates an example where the conductive layer 260 has a two-layer structure of a conductive layer 260a and a conductive layer 260b over the conductive layer 260a. In this case, for example, it is preferable to use titanium nitride for the conductive layer 260a and tungsten for the conductive layer 260b. Alternatively, it is preferable to use tantalum nitride for the conductive layer 260a and copper for the conductive layer 260b. Such a structure can increase the conductivity of the conductive layer 260.

Alternatively, the conductive layer 260 may have a stacked-layer structure of three or more layers. The conductive layer 260 may have a three-layer structure of tantalum nitride, titanium nitride over the tantalum nitride, and tungsten over the titanium nitride, for example.

The conductive layer 265 functions as the gate wiring and thus preferably has high conductivity. The conductive layer 265 is preferably formed using tungsten. The conductive layer 265 may have a structure similar to that of the conductive layer 260. For example, a two-layer structure of titanium nitride and tungsten may be employed.

### Substrate

As a substrate where a transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Another example includes a semiconductor substrate in which an insulator region is provided in the above semiconductor substrate, e.g., a silicon on insulator (SOI) substrate. Examples of the conductor substrate include a graphite substrate, a metal substrate, an alloy substrate, and a conductive resin substrate. Other examples include a substrate containing a nitride of a metal, and a substrate containing an oxide of a metal. Other examples include an insulator substrate provided with a conductor or a semiconductor, a semiconductor substrate provided with a conductor or an insulator, and a conductor substrate provided with a semiconductor or an insulator. Alternatively, any of these substrates provided with an element may be used. As the element provided over the substrate, a capacitor, a resistor, a switching element, a light-emitting element, a memory element, or the like is used.

### Structure Example 2 of Semiconductor Device

A structure of a semiconductor device of another embodiment of the present invention will be described below. Specifically, modification examples of the transistor 100 and the transistor 200 are described. Unless otherwise specified, FIG. 1D can be referred to for the planar structure of the transistor 100, and FIG. 1E can be referred to for the planar structure of the transistor 200.

### Transistor 100A and transistor 200A

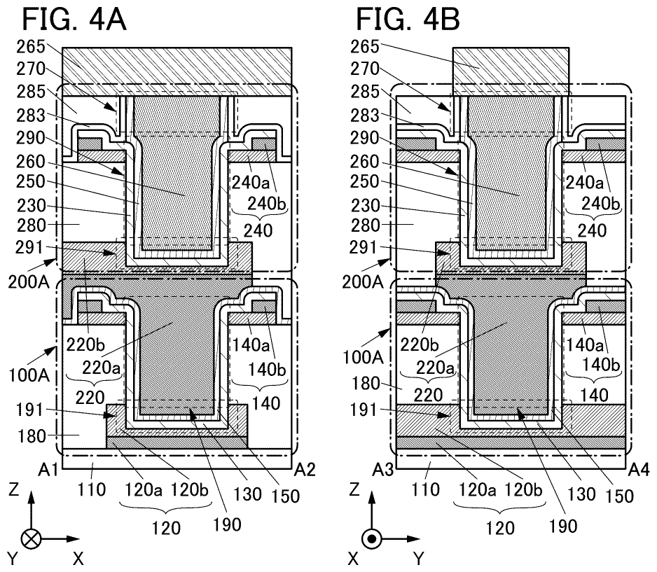

FIG. 4A is a cross-sectional view along the dashed-dotted line A1-A2 in FIG. 1D and FIG. 1E. FIG. 4B is a cross-sectional view along the dashed-dotted line A3-A4 in FIG. 1D and FIG. 1E. FIG. 4A illustrates a transistor 100A as a modification example of the transistor 100. FIG. 4B illustrates a transistor 200A as a modification example of the transistor 200.

The side surface of the conductive layer 140b which is included in the transistor 100A in the opening portion 190 is located outward from the side surface of the conductive layer 140a in the opening portion 190. The side surface of the conductive layer 240b which is included in the transistor 200A in the opening portion 290 is located outward from the side surface of the conductive layer 240a in the opening portion 290. The conductive layer 140 and the conductive layer 240 illustrated in FIG. 4A and FIG. 4B are formed due to the formation processes of the opening portion 190 and the opening portion 290 in some cases. For example, after the opening portion 190 is formed by etching, part of the conductive layer 140b is removed, whereby the conductive layer 140 included in the transistor 100A is formed in some cases. Similarly, after the opening portion 290 is formed by etching, part of the conductive layer 240b is removed, whereby the conductive layer 240 included in the transistor 200A is formed in some cases.

In the transistor 100A, the semiconductor layer 130 is in contact with the top surface of the conductive layer 140a as well as the side surface of the conductive layer 140a. Thus, in the transistor 100A, the contact area between the semiconductor layer 130 and the conductive layer 140a can be larger than that in the transistor 100 illustrated in FIG. 1F, FIG. 1G, or the like. As described above, a conductive material containing oxygen can be used for the conductive layer 140a. Accordingly, when a metal oxide is used for the semiconductor layer 130, the contact resistance per unit area between the semiconductor layer 130 and the conductive layer 140a can be lower than the contact resistance per unit area between the semiconductor layer 130 and the conductive layer 140b. Therefore, in the transistor 100A, the contact resistance between the semiconductor layer 130 and the conductive layer 140 can be lower than that in the transistor 100 illustrated in FIG. 1F, FIG. 1G, or the like. Similarly, in the transistor 200A, the contact resistance between the semiconductor layer 230 and the conductive layer 240 can be lower than that in the transistor 200 illustrated in FIG. 1F, FIG. 1G, or the like. Meanwhile, the transistor 100 and the transistor 200 illustrated in FIG. 1F, FIG. 1G, or the like can be manufactured in processes simpler than those of the transistor 100A and the transistor 200A.

### Transistor 100b and Transistor 200b

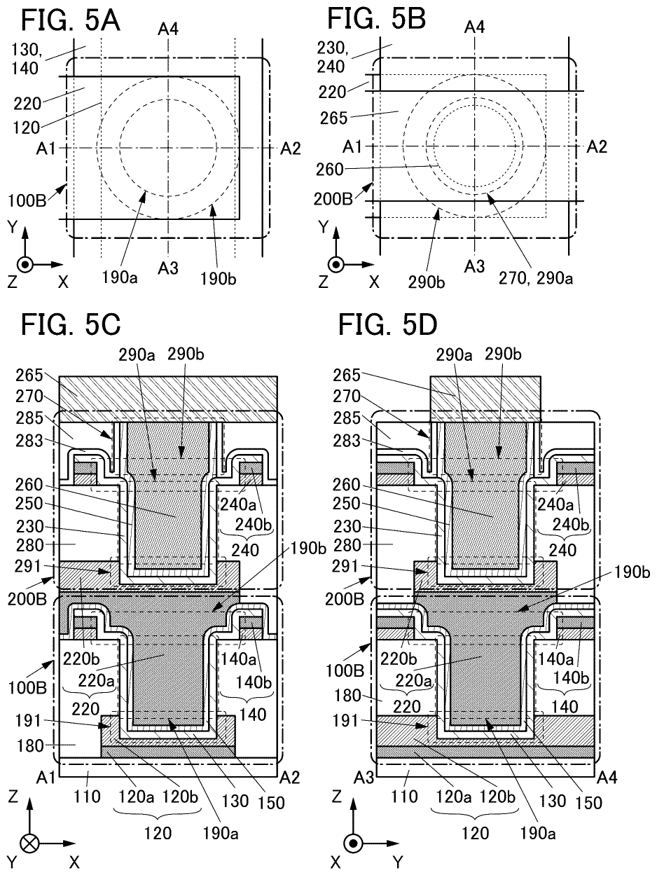

FIG. 5A is a plan view illustrating a structure example of a transistor 100B which is a modification example of the transistor 100. FIG. 5B is a plan view illustrating a structure example of a transistor 200B which is a modification example of the transistor 200. FIG. 5C is a cross-sectional view along the dashed-dotted line A1-A2 in FIG. 5A and FIG. 5B. FIG. 5D is a cross-sectional view along the dashed-dotted line A3-A4 in FIG. 5A and FIG. 5B.

The side surface of each of the conductive layer 140a and the conductive layer 140b which are included in the transistor 100B in the opening portion 190 is located outward from the side surface of the insulating layer 180 in the opening portion 190. The side surface of each of the conductive layer 240a and the conductive layer 240b which are included in the transistor 200B in the opening portion 290 is located outward from the side surface of the insulating layer 280 in the opening portion 290. In FIG. 5A to FIG. 5D, the opening portion 190 provided in the insulating layer 180 is referred to as an opening portion 190a and the opening portion 190 provided in the conductive layer 140a and the conductive layer 140b is referred to as an opening portion 190b. The opening portion 290 provided in the insulating layer 280 is referred to as an opening portion 290a and the opening portion 290 provided in the conductive layer 240a and the conductive layer 240b is referred to as an opening portion 290b. The conductive layer 140 and the conductive layer 240 illustrated in FIG. 5A to FIG. 5D are formed due to the formation processes of the opening portion 190 and the opening portion 290 in some cases.

### Transistor 100C and Transistor 200C

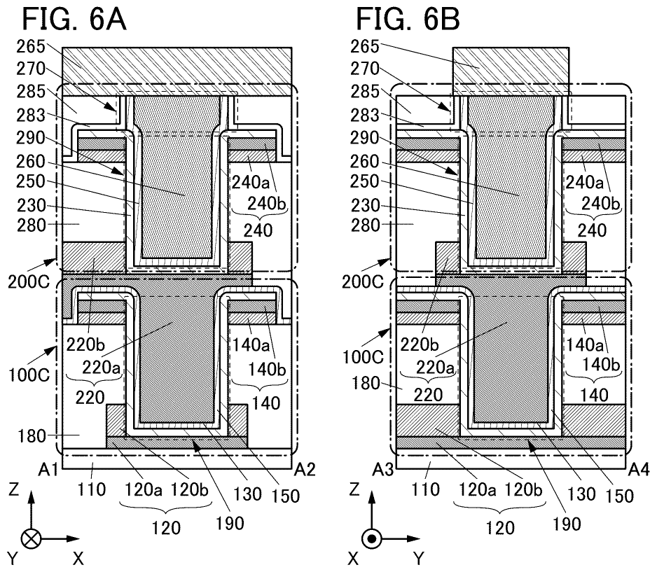

FIG. 6A is a cross-sectional view along the dashed-dotted line A1-A2 in FIG. 1D and FIG. 1E. FIG. 6B is a cross-sectional view along the dashed-dotted line A3-A4 in FIG. 1D and FIG. 1E. FIG. 6A illustrates a transistor 100C as a modification example of the transistor 100. FIG. 6B illustrates a transistor 200C as a modification example of the transistor 200.

In the semiconductor device including the transistor 100C and the transistor 200C, the opening portion 190 reaches the conductive layer 120a. The semiconductor layer 130 is in contact with the top surface of the conductive layer 120a in the opening portion 190. The opening portion 290 reaches the conductive layer 220a. The semiconductor layer 230 is in contact with the top surface of the conductive layer 220a in the opening portion 290. Although FIG. 6A and FIG. 6B illustrate an example where the conductive layer 120a and the conductive layer 220a are not provided with a depressed portion, the conductive layer 120a and the conductive layer 220a may be provided with a depressed portion.

In the transistor 100C, the conductive layer 120b includes the opening portion 190. Thus, the difference between the distance Tc1 and the distance Tb1 is larger in the transistor 100C than, for example, in the transistor 100 illustrated in FIG. 2A. As the difference between the distance Tc1 and the distance Tb1 becomes larger, the area of a region where the side surface of the conductive layer 220 and the conductive layer 120 face each other becomes larger in the opening portion 190 of the conductive layer 120b or in the depressed portion 191. Thus, a gate electric field is easily applied to the channel formation region of the semiconductor layer 130. Similarly, a gate electric field is applied to the channel formation region of the semiconductor layer 230 more easily in the transistor 200C than in the transistor 200 illustrated in FIG. 2A, for example.

Meanwhile, for example, the transistor 100 illustrated in FIG. 2A is in contact with the top surface of the conductive layer 120b in a region overlapping with the opening portion 190. Thus, for example, the area where the semiconductor layer 130 and the conductive layer 120b are in contact with each other is larger in the transistor 100 illustrated in FIG. 2A than in the transistor 100C. As described above, a conductive material containing oxygen can be used for the conductive layer 120b. Accordingly, when a metal oxide is used for the semiconductor layer 130, the contact resistance per unit area between the semiconductor layer 130 and the conductive layer 120b can be lower than the contact resistance per unit area between the semiconductor layer 130 and the conductive layer 120a. Therefore, the contact resistance between the semiconductor layer 130 and the conductive layer 120 in the transistor 100C can be lower than that in the transistor 100 illustrated in FIG. 2A, for example. Similarly, the contact resistance between the semiconductor layer 230 and the conductive layer 220 in the transistor 200C can be lower than that in the transistor 200 illustrated in FIG. 2A, for example.

### Transistor 100D and Transistor 200D

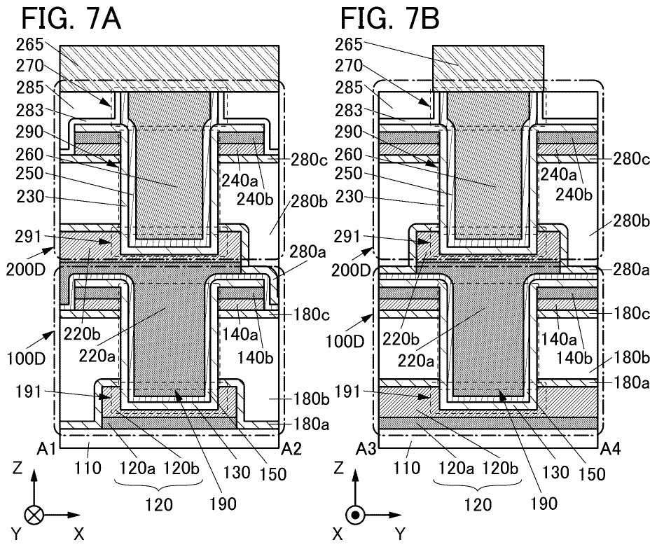

FIG. 7A is a cross-sectional view along the dashed-dotted line A1-A2 in FIG. 1D and FIG. 1E. FIG. 7B is a cross-sectional view along the dashed-dotted line A3-A4 in FIG. 1D and FIG. 1E. FIG. 7A illustrates a transistor 100D as a modification example of the transistor 100. FIG. 7B illustrates a transistor 200D as a modification example of the transistor 200.

In the semiconductor device illustrated in FIG. 7A and FIG. 7B, the insulating layer 180 has a three-layer stacked structure of an insulating layer 180a, an insulating layer 180b over the insulating layer 180a, and an insulating layer 180c over the insulating layer 180b. In the semiconductor device illustrated in FIG. 7A and FIG. 7B, the insulating layer 280 has a three-layer stacked structure of an insulating layer 280a, an insulating layer 280b over the insulating layer 280a, and an insulating layer 280c over the insulating layer 280b. Note that the insulating layer 180 and the insulating layer 280 may each have a single-layer structure, a two-layer structure, or a stacked-layer structure of four or more layers.

The insulating layer 180a includes a region in contact with the top surface of the insulating layer 110, a region in contact with the side surface of the conductive layer 120, and a region in contact with the top surface of the conductive layer 120. The insulating layer 180c includes a region in contact with the bottom surface of the conductive layer 140a.

The insulating layer 280a includes a region in contact with the insulating layer 150, a region in contact with the side surface of the conductive layer 220, and a region in contact with the top surface of the conductive layer 220. The insulating layer 280c includes a region in contact with the bottom surface of the conductive layer 240a.

The insulating layer 180b is a layer in contact with the channel formation region of the semiconductor layer 130. When an insulating layer containing oxygen is used as the insulating layer 180b, oxygen can be supplied to the semiconductor layer 130. Similarly, the insulating layer 280b is a layer in contact with the channel formation region of the semiconductor layer 230. When an insulating layer containing oxygen is used as the insulating layer 280b, oxygen can be supplied to the semiconductor layer 230.

The insulating layer 180b preferably includes a region having a higher oxygen content than one or both of the insulating layer 180a and the insulating layer 180c. In particular, the insulating layer 180b preferably includes a region having a higher oxygen content than each of the insulating layer 180a and the insulating layer 180c. When the insulating layer 180b has a high oxygen content, an i-type region can be easily formed in the semiconductor layer 130 in the vicinity of the insulating layer 180b.

Similarly, the insulating layer 280b preferably includes a region having a higher oxygen content than one or both of the insulating layer 280a and the insulating layer 280c. In particular, the insulating layer 280b preferably includes a region having a higher oxygen content than each of the insulating layer 280a and the insulating layer 280c. When the insulating layer 280b has a high oxygen content, an i-type region can be easily formed in the semiconductor layer 230 in the vicinity of the insulating layer 280b.

It is further preferable that a film from which oxygen is released by heating be used for the insulating layer 180b and the insulating layer 280b. For example, when the insulating layer 180b releases oxygen by being heated during the manufacturing process of the transistor 100D, the oxygen can be supplied to the semiconductor layer 130. Supplying oxygen from the insulating layer 180b to the semiconductor layer 130, particularly to the channel formation region of the semiconductor layer 130, can reduce oxygen vacancies and VoH in the semiconductor layer 130. Therefore, the transistor 100D can have favorable electrical characteristics and high reliability. Similarly, the transistor 200D can have favorable electrical characteristics and high reliability.

In order to improve the electrical characteristics and reliability of an OS transistor, it is important that the amount of oxygen supplied to the oxide semiconductor be optimized after the hydrogen concentration in the oxide semiconductor is sufficiently reduced.

In particular, when the channel lengths of the transistor 100D and the transistor 200D are short, the influence of oxygen vacancies and VoH in the channel formation regions on the electrical characteristics and reliability is especially large. Accordingly, the amount of oxygen supplied to the semiconductor layer 130 and the semiconductor layer 230 is preferably optimized after the hydrogen concentration in the semiconductor layer 130 and the hydrogen concentration in the semiconductor layer 230 are sufficiently reduced. Accordingly, transistors with a short channel length, favorable electrical characteristics, and high reliability can be provided.

The insulating layer 180b and the insulating layer 280b are preferably formed by a film formation method such as a sputtering method or a plasma-enhanced chemical vapor deposition (PECVD) method. It is particularly preferable to employ a sputtering method, in which a hydrogen gas does not need to be used as a film formation gas, to form a film having an extremely low hydrogen content. Therefore, supply of hydrogen to the semiconductor layer 130 and the semiconductor layer 230 is inhibited and the electrical characteristics of the transistor 100D and the transistor 200D can be stabilized.

In the case where a large amount of oxygen is supplied to the semiconductor layer 130, heat treatment in an oxygen-containing atmosphere or plasma treatment in an oxygen-containing atmosphere is preferably performed after the formation of the insulating layer 180b, for example. Alternatively, an oxide film may be formed over the top surface of the insulating layer 180b by a sputtering method in an oxygen atmosphere to supply oxygen. After that, the oxide film may be removed. Such treatment can supply oxygen to the insulating layer 180b and increase the amount of oxygen supplied to the semiconductor layer 130. In addition, the same treatment is performed after the formation of the insulating layer 280b, whereby oxygen can be supplied to the insulating layer 280b to increase the amount of oxygen supplied to the semiconductor layer 230.

A region of the semiconductor layer 130 that is in contact with the insulating layer 180a and a region of the semiconductor layer 130 that is in contact with the insulating layer 180c are supplied with a smaller amount of oxygen than a region of the semiconductor layer 130 that is in contact with the insulating layer 180b. Thus, the region of the semiconductor layer 130 that is in contact with the insulating layer 180a and the region of the semiconductor layer 130 that is in contact with the insulating layer 180c each have a low resistance in some cases. That is, by adjusting the thicknesses of the insulating layer 180a and the insulating layer 180c, the range of a region functioning as one of the source region and the drain region of the transistor 100D can be controlled.

Similarly, a region of the semiconductor layer 230 that is in contact with the insulating layer 280a and a region of the semiconductor layer 230 that is in contact with the insulating layer 280c are supplied with a smaller amount of oxygen than a region of the semiconductor layer 230 that is in contact with the insulating layer 280b. Thus, by adjusting the thicknesses of the insulating layer 280a and the insulating layer 280c, the range of a region functioning as one of the source region and the drain region of the transistor 200D can be controlled. As described above, the thicknesses of the insulating layer 180a, the insulating layer 180c, the insulating layer 280a, and the insulating layer 280c can be set as appropriate in accordance with the characteristics required for the transistor.

A material with a low dielectric constant is preferably used for the insulating layer 180b and the insulating layer 280b. In that case, parasitic capacitance generated between wirings can be reduced. For example, silicon oxide or silicon oxynitride can be used for the insulating layer 180b and the insulating layer 280b.

A barrier insulating layer against oxygen is preferably used for each of the insulating layer 180a, the insulating layer 180c, the insulating layer 280a, and the insulating layer 280c. Providing the insulating layer 180a between the insulating layer 180b and the conductive layer 120 can inhibit the conductive layer 120 from being oxidized and having high electric resistance. Moreover, providing the insulating layer 180c between the insulating layer 180b and the conductive layer 140 can inhibit the conductive layer 140 from being oxidized and having high electric resistance. Furthermore, providing the insulating layer 280a between the insulating layer 280b and the conductive layer 220 can inhibit the conductive layer 220 from being oxidized and having high electric resistance. Moreover, providing the insulating layer 280c between the insulating layer 280b and the conductive layer 240 can inhibit the conductive layer 240 from being oxidized and having high electric resistance.

An insulating layer having a function of capturing or fixing hydrogen may be used as the insulating layer 180a. With such a structure, diffusion of hydrogen from below the insulating layer 180a into the semiconductor layer 130 can be inhibited, and hydrogen contained in the semiconductor layer 130 can be captured or fixed. Thus, the hydrogen concentration in the semiconductor layer 130 can be reduced. Magnesium oxide, aluminum oxide, hafnium oxide, an oxide containing hafnium and silicon, or the like can be used for the insulating layer 180a. Alternatively, for example, a stacked-layer film of aluminum oxide and silicon nitride over the aluminum oxide may be used for the insulating layer 180a. Similarly, an insulating layer having a function of capturing or fixing hydrogen may be used as each of the insulating layer 180c, the insulating layer 280a, and the insulating layer 280c.

For example, silicon nitride can be used for the insulating layer 180a, the insulating layer 180c, the insulating layer 280a, and the insulating layer 280c, and silicon oxide can be used for the insulating layer 180b and the insulating layer 280b.

### Transistor 100E and Transistor 200E

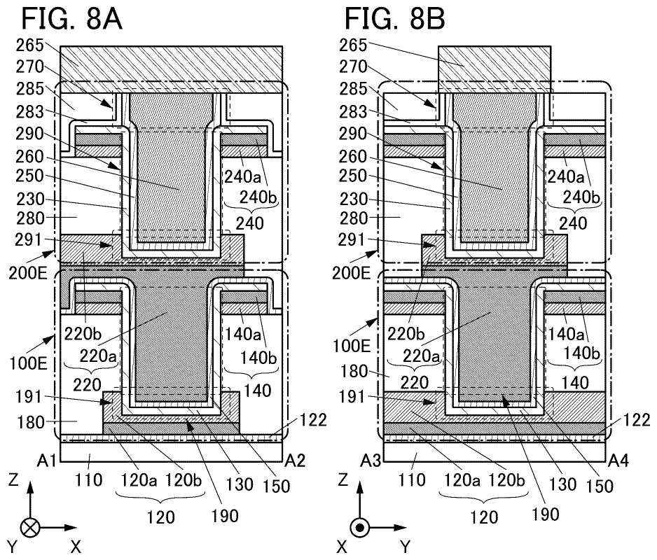

FIG. 8A is a cross-sectional view along the dashed-dotted line A1-A2 in FIG. 1D and FIG. 1E. FIG. 8B is a cross-sectional view along the dashed-dotted line A3-A4 in FIG. 1D and FIG. 1E. FIG. 8A illustrates a transistor 100E as a modification example of the transistor 100. FIG. 8B illustrates a transistor 200E as a modification example of the transistor 200.

The semiconductor device illustrated in FIG. 8A and FIG. 8B is different from the semiconductor device illustrated in FIG. 1F and FIG. 1G in including an insulating layer 122.

In the semiconductor device illustrated in FIG. 8A and FIG. 8B, the insulating layer 122 is provided over the insulating layer 110, and the conductive layer 120a, and the insulating layer 180 are provided over the insulating layer 122.

An insulating layer having a function of capturing or fixing hydrogen is preferably used as the insulating layer 122. Accordingly, hydrogen in the semiconductor layer 130 diffusing into the insulating layer 122 through the conductive layer 120a and the conductive layer 120b can be captured or fixed. Thus, the hydrogen concentration in the semiconductor layer 130 can be reduced.

For example, a silicon nitride film is preferably used for the insulating layer 110 and an oxide film containing hafnium and silicon (hafnium silicate film) is preferably used for the insulating layer 122.

### Transistor 200f and Transistor 200f

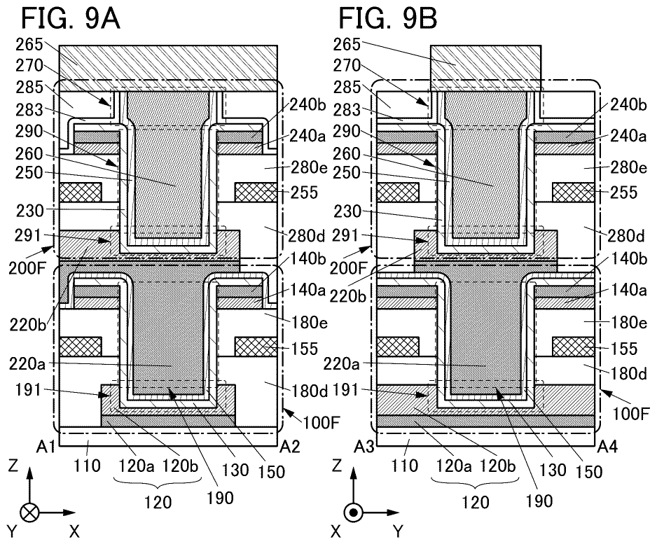

FIG. 9A is a cross-sectional view along the dashed-dotted line A1-A2 in FIG. 1D and FIG. 1E. FIG. 9B is a cross-sectional view along the dashed-dotted line A3-A4 in FIG. 1D and FIG. 1E. FIG. 9A illustrates a transistor 100F as a modification example of the transistor 100. FIG. 9B illustrates a transistor 200F as a modification example of the transistor 200.

The transistor 100F includes a conductive layer 155. The transistor 200F includes a conductive layer 255. In the semiconductor device illustrated in FIG. 9A and FIG. 9B, the insulating layer 180 has a two-layer stacked structure of an insulating layer 180d and an insulating layer 180e over the insulating layer 180d. In the semiconductor device illustrated in FIG. 9A and FIG. 9B, the insulating layer 280 has a two-layer stacked structure of an insulating layer 280d and an insulating layer 280e over the insulating layer 280d.

In the transistor 100F, the conductive layer 155 is located over the insulating layer 180d, and the insulating layer 180e covers the top surface and the side surface of the conductive layer 155. In a cross-sectional view, the semiconductor layer 130 includes a region facing the conductive layer 155 with the insulating layer 180e therebetween and facing the conductive layer 220 with the insulating layer 150 therebetween.

In the transistor 200F, the conductive layer 255 is located over the insulating layer 280d, and the insulating layer 280e covers the top surface and the side surface of the conductive layer 255. In a cross-sectional view, the semiconductor layer 230 includes a region facing the conductive layer 255 with the insulating layer 280e therebetween and facing the conductive layer 260 with the insulating layer 250 therebetween.

The conductive layer 155 functions as the back gate electrode of the transistor 100F. The conductive layer 255 functions as the back gate electrode of the transistor 200F. Since the transistor 100F and the transistor 200F each include a back gate electrode, the threshold voltage can be easily controlled and a change in the threshold voltage can be inhibited. Thus, the transistor 100F and the transistor 200F can be transistors with high electrical characteristics and high reliability.

For example, the material that can be used for the conductive layer 260 can be used for the conductive layer 155 and the conductive layer 255.

### Transistor 100g and Transistor 200g

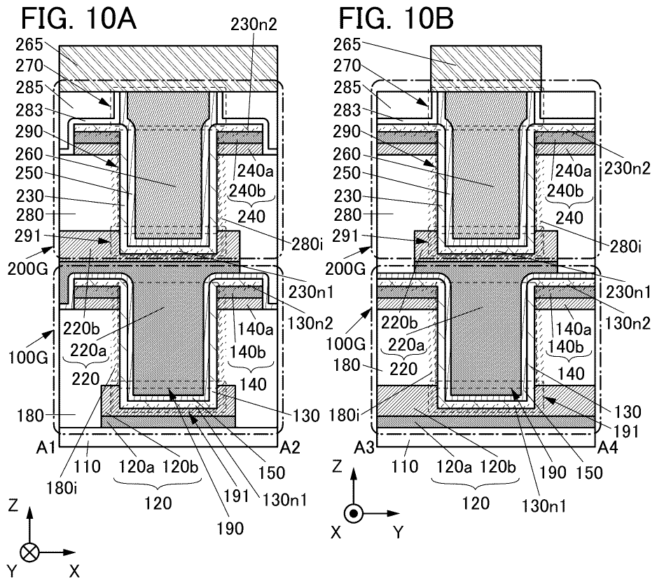

FIG. 10A is a cross-sectional view along the dashed-dotted line A1-A2 in FIG. 1D and FIG. 1E. FIG. 10B is a cross-sectional view along the dashed-dotted line A3-A4 in FIG. 1D and FIG. 1E. FIG. 10A illustrates a transistor 100G as a modification example of the transistor 100. FIG. 10B illustrates a transistor 200G as a modification example of the transistor 200.

In the semiconductor device illustrated in FIG. 10A and FIG. 10B, the insulating layer 180 includes a region 180i, and the insulating layer 280 includes a region 280i. The region 180i and the region 280i contain a halogen element. At least part of the region 180i is in contact with the semiconductor layer 130, and at least part of the region 280i is in contact with the semiconductor layer 230.

The halogen element is preferably one or more kinds selected from chlorine, fluorine, bromine, and iodine, and further preferably chlorine or fluorine. In terms of substitution for oxygen, fluorine having higher electronegativity than oxygen is preferably used.

Since the region 180i contains the halogen element, the halogen element can be supplied from the region 180i to the semiconductor layer 130. Since the region 280i contains the halogen element, the halogen element can be supplied from the region 280i to the semiconductor layer 230. The halogen element (X) has a function of generating an electron serving as a carrier by entering oxygen vacancies (Vo) in the semiconductor layer 130 and the semiconductor layer 230 to form defects (VoX). For example, in the case where chlorine (Cl ) is used as the halogen element, chlorine exists stably in the state of VoCl in the semiconductor layer 130 (particularly at and near the interface between the insulating layer 180 and the semiconductor layer 130) and in the semiconductor layer 230 (particularly at and near the interface between the insulating layer 280 and the semiconductor layer 230). At that time, Cl can be in the state of VoCl by not only entering an existing Vo but also substituting for oxygen.

In contrast, oxygen substituted by Cl (also referred to as excess oxygen) has a function of trapping electrons. Furthermore, carrier trap by oxygen takes precedence over carrier generation by VoCl. Thus, a negative charge (also referred to as negative fixed charge) is formed at and near the interface between the insulating layer 180 and the semiconductor layer 130. The region 180i is in contact with the channel formation region of the semiconductor layer 130. When a negative charge exists in the channel formation region, the threshold voltage of the transistor 100G can be shifted positively. Thus, even when the transistor 100G has a minute structure or an extremely short channel length, the transistor 100G can be normally-off. Similarly, for example, the insulating layer 280 includes the region 280i, whereby the transistor 200G can be normally-off even when the transistor 200G has a minute structure or an extremely short channel length.

For example, it is preferable to use aluminum oxide layers as the insulating layer 180 and the insulating layer 280 and use fluorine as the halogen element. Note that the insulating layer 180 and the insulating layer 280 may each have a single layer structure or a stacked-layer structure. In the case where the insulating layer 180 and the insulating layer 280 each have a stacked-layer structure, one or both of a silicon oxide layer and a silicon nitride layer are preferably included in addition to an aluminum oxide layer, for example. In this case, it is possible that oxygen bonded to aluminum is substituted by fluorine and the released oxygen is bonded to hydrogen to form an OH group (Al—O+F→Al—F+O+H→AlF+OH). When AlF exists on the back channel side in this manner, a negative charge is formed in the channel formation region, and not only can the threshold voltages of the transistor 100G and the transistor 200G be shifted positively, but also a function of capturing or fixing (also referred to as gettering) hydrogen can be provided. In that case, the hydrogen concentrations in the semiconductor layer 130 and the semiconductor layer 230 can be reduced. In particular, the hydrogen concentration in the channel formation region of the transistor 100G and the hydrogen concentration in the channel formation region of the transistor 200G can be reduced. Accordingly, VoH in the channel formation regions can be reduced, so that the channel formation regions can be i-type or substantially i-type regions.

Note that the conductive layer 120, the conductive layer 140, the conductive layer 220, and the conductive layer 240 may also contain a halogen element. A halogen element may be supplied from the conductive layer 120 or the conductive layer 140 to the semiconductor layer 130. A halogen element may be supplied from the conductive layer 220 or the conductive layer 240 to the semiconductor layer 230. In FIG. 10A and FIG. 10B, side surfaces of the conductive layer 120 and the conductive layer 140 on the opening portion 190 side are shown with a hatching pattern similar to that of the region 180i. In FIG. 10A and FIG. 10B, side surfaces of the conductive layer 220 and the conductive layer 240 on the opening portion 290 side are shown with a hatching pattern similar to that of the region 280i.

The semiconductor layer 130 may include a region that is in contact with the insulating layer 180 and contains a halogen element. The semiconductor layer 230 may include a region that is in contact with the insulating layer 280 and contains a halogen element.

The source region and the drain region of the semiconductor layer 130 and the source region and the drain region of the semiconductor layer 230 preferably contain an impurity element. A first element is preferably used as the impurity element. Alternatively, both the first element and hydrogen are preferably used as the impurity element.

In FIG. 10A and FIG. 10B, a region of the semiconductor layer 130 that is in contact with the top surface of the conductive layer 120 in the depressed portion 191 is referred to as a region 130n1. A region of the semiconductor layer 130 that is in contact with the top surface of the conductive layer 140 is referred to as a region 130n2. A region of the semiconductor layer 230 that is in contact with the top surface of the conductive layer 220 in the depressed portion 291 is referred to as a region 230n1. A region of the semiconductor layer 230 that is in contact with the top surface of the conductive layer 240 is referred to as a region 230n2. Here, the region 130n1 and the region 130n2 are collectively referred to as a region 130n, and the region 230n1 and the region 230n2 are collectively referred to as a region 230n. The region 130n and the region 230n preferably contain an impurity element.

Note that the conductive layer 120, the conductive layer 140, the conductive layer 220, and the conductive layer 240 also contain the impurity element in some cases. In FIG. 10A and FIG. 10B, regions of the conductive layer 120 and the conductive layer 140 that are in contact with the semiconductor layer 130 are shown with a hatching pattern similar to that of the region 130n. Regions of the conductive layer 220 and the conductive layer 240 that are in contact with the semiconductor layer 230 are shown with a hatching pattern similar to that of the region 230n.

As the first element, it is preferable to use one or more kinds selected from boron, aluminum, indium, carbon, silicon, germanium, tin, phosphorus, arsenic, antimony, magnesium, calcium, titanium, copper, zinc, tungsten, molybdenum, tantalum, hafnium, cerium, and a noble gas (helium, neon, argon, krypton, xenon, and the like).

The first element is not limited to the above elements, and one or more kinds selected from first transition elements (3d transition elements or 3d transition metals), second transition elements (4d transition elements or 4d transition metals), third transition elements (5d transition elements or 5d transition metals), alkaline earth metal elements, and rare earth elements can be used.

When the first element is supplied to the source region and the drain region, the first element deprives these regions of oxygen, for example, and accordingly generates an oxygen vacancy therein. Then, the oxygen vacancy is bonded to hydrogen in the film, so that a carrier is generated and the resistances of the source region and the drain region can be reduced. Accordingly, the sheet resistance of the semiconductor layer 130, the sheet resistance of the semiconductor layer 230, the contact resistance between the semiconductor layer 130 and the conductive layer 120, the contact resistance between the semiconductor layer 130 and the conductive layer 140, the contact resistance between the semiconductor layer 230 and the conductive layer 220, and the contact resistance between the semiconductor layer 230 and the conductive layer 240 can each be reduced. Therefore, the transistor 100G and the transistor 200G can be transistors with high on-state currents. The increased on-state current can reduce the operation voltage of the transistor. This can reduce the power consumption of the semiconductor device.

In the case where an element that is easily bonded to oxygen is used as the first element, the first element exists in a state of being bonded to oxygen in the semiconductor layer. Furthermore, when an element that is stabilized by being bonded to oxygen is used as the first element, the first element in the semiconductor layer exists stably in an oxidized state and thus is not easily released, for example, by heat or the like applied during the manufacturing process of the semiconductor device, thereby enabling a low-resistance region that is stable in a low-electric-resistance state. Therefore, as the first element, it is preferable to use an element an oxide of which can exist as a solid at 25 ° C and 1 atmospheric pressure. Specifically, a typical non-metallic element other than hydrogen, a typical metal element, and a transition element (transition metal) are preferable as the first element, and boron, phosphorus, magnesium, aluminum, and silicon are particularly preferable as the first element.

Thus, boron, phosphorus, magnesium, aluminum, or silicon is preferably used as the first element. In particular, boron or phosphorus is preferably used as the first element.

Furthermore, hydrogen has a function of being bonded to an oxygen vacancy in addition to the function of generating an oxygen vacancy, and thus is suitable as the impurity element.

When both the first element and hydrogen are used as impurity elements, the electric resistances of the source regions and the drain regions of the semiconductor layer 130 and the semiconductor layer 230 are easily reduced and a low-electric-resistance state can be kept stably.

Both the first element and hydrogen are preferably supplied because ions generated from the source gases can be added without mass separation and thus the productivity can be increased. For example, when a B₂H₆ gas is used, boron and hydrogen can be supplied as the impurity element. As another example, when a PH₃ gas is used, phosphorus and hydrogen can be supplied as the impurity element. Note that the method for supplying the impurity element is not limited thereto. For example, a specific element may be added after a source gas is ionized and then the ion is subjected to mass separation. For example, after mass separation of an ionized B₂H₆ gas, boron may be added to the region 130n and the region 230n.

The region 130n and the region 230n each preferably include a region having an impurity element concentration higher than or equal to 1×10¹⁹ atoms/cm³ and lower than or equal to 1×10²³ atoms/cm³, preferably higher than or equal to 5×10¹⁹ atoms/cm³ and lower than or equal to 5×10²²atoms/cm³, further preferably higher than or equal to 1×10²⁰ atoms/cm³ and lower than or equal to 1×10²² atoms/cm³. Note that in the case where a plurality of impurity elements are contained, the concentration of each impurity element is preferably within the above range.

Note that the impurity element is also supplied to the channel formation region of the semiconductor layer 130 and the channel formation region of the semiconductor layer 230 in some cases. Alternatively, the impurity element contained in the region 130n and the impurity element contained in the region 230n sometimes partly diffuse into the channel formation regions due to the influence of heat applied during the manufacturing process, for example. The impurity element concentrations of the channel formation regions are each preferably lower than or equal to one tenth, further preferably lower than or equal to one hundredth of those of the region 130n and the region 230n.

The impurity element concentrations in the semiconductor layer 130 (including the region 130n) and the semiconductor layer 230 (including the region 230n) can be analyzed by an analysis method such as SIMS or XPS, for example. In the case of using XPS analysis, ion sputtering from the front surface side or the back surface side is combined with XPS analysis, whereby the concentration distribution in the depth direction can be found.

In manufacturing the semiconductor device of one embodiment of the present invention, an impurity element is preferably added to the source region and the drain region of the semiconductor layer 130 and the source region and the drain region of the semiconductor layer 230 more easily than to the channel formation regions. Thus, the impurity element is preferably added from a direction perpendicular or substantially perpendicular to the top surface of the substrate. At that time, in each of the semiconductor layer 130 and the semiconductor layer 230, the addition amount of the impurity element is smaller in a surface inclined to the top surface of the substrate than in a surface parallel or substantially parallel to the top surface of the substrate. That is, in each of the semiconductor layer 130 and the semiconductor layer 230, the addition amount of the impurity element is larger in the source region and the drain region than in the channel formation region. Thus, the resistances of the source region and the drain region can be reduced preferentially.

### Transistor 100H and Transistor 200H

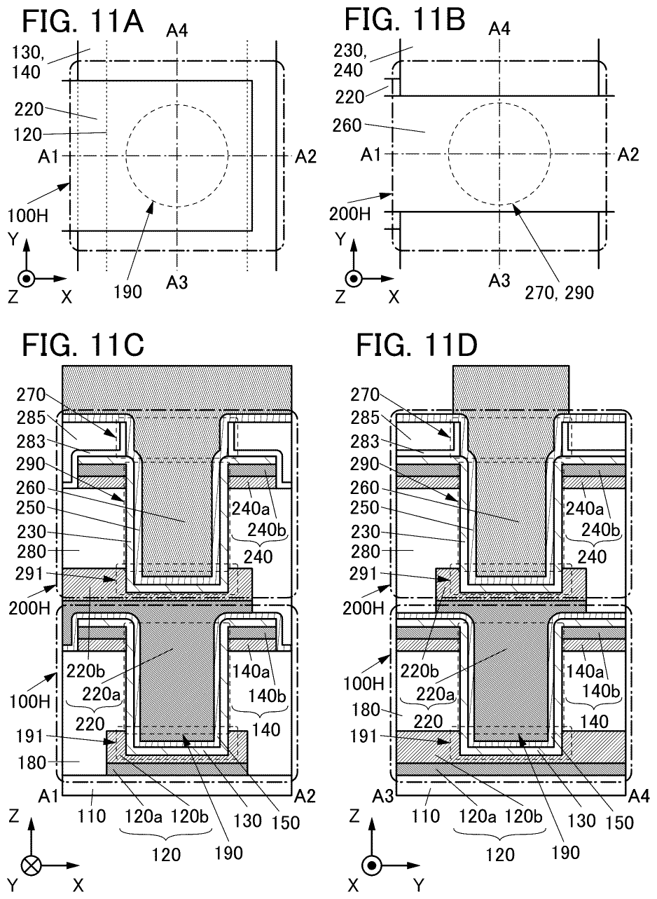

FIG. 11A is a plan view illustrating a structure example of a transistor 100H which is a modification example of the transistor 100. FIG. 11B is a plan view illustrating a structure example of a transistor 200H which is a modification example of the transistor 200. FIG. 11C is a cross-sectional view along the dashed-dotted line A1-A2 in FIG. 11A and FIG. 11B. FIG. 11D is a cross-sectional view along the dashed-dotted line A3-A4 in FIG. 11A and FIG. 11B.

Unlike the semiconductor device illustrated in FIG. 1D to FIG. 1G, the semiconductor device illustrated in FIG. 11A to FIG. 11D does not include the conductive layer 265. In the semiconductor device, as illustrated in FIG. 11C and FIG. 11D, the insulating layer 250 includes a region located over the insulating layer 283 and a region located over the insulating layer 285 in addition to a region located in the opening portion 270. The conductive layer 260 includes a region located over the insulating layer 283 and a region located over the insulating layer 285 in addition to a region located in the opening portion 270. In the semiconductor device illustrated in FIG. 11A to FIG. 11D, the conductive layer 260 has a function of a gate wiring.

The conductive layer 260 includes a region overlapping with the top surface of the conductive layer 240; between the region of the conductive layer 260 and the conductive layer 240, the insulating layer 250, the insulating layer 283, and the insulating layer 285 are provided. Thus, the parasitic capacitance between the conductive layer 240 and the conductive layer 260 can be smaller than the capacitance Cp between the conductive layer 140 and the conductive layer 220.

### Manufacturing Method Example of Semiconductor Device

Next, a method for manufacturing the semiconductor device of one embodiment of the present invention will be described with reference to drawings. Note that as for a material and a formation method of each component, portions similar to those described above are not described in some cases.

Thin films included in the semiconductor device (e.g., insulating films, semiconductor films, and conductive films) can be formed by a sputtering method, a CVD method, a vacuum evaporation method, a PLD method, an ALD method, or the like.

Examples of the sputtering method include an RF sputtering method in which a high-frequency power source is used for a sputtering power source, a DC sputtering method in which a DC power source is used, and a pulsed DC sputtering method in which a voltage is applied to an electrode while being changed in a pulsed manner. The RF sputtering method is mainly used in the case where an insulating film is formed, and the DC sputtering method is mainly used in the case where a metal conductive film is formed. The pulsed DC sputtering method is mainly used in the case where a compound such as an oxide, a nitride, or a carbide is formed by a reactive sputtering method.

CVD methods can be classified into a plasma enhanced CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature through a PECVD method. A thermal CVD method does not use plasma and thus causes less plasma damage to an object. A wiring, an electrode, an element (e.g., a transistor or a capacitor), or the like included in a semiconductor device might be charged up by receiving charges from plasma, for example. In that case, accumulated charges might break the wiring, electrode, element, or the like included in the semiconductor device. By contrast, such plasma damage is not caused and the yield of semiconductor devices can be increased with the thermal CVD method which does not use plasma. A thermal CVD method yields a film with few defects because of no plasma damage during film formation.

As the ALD method, a thermal ALD method, in which a precursor and a reactant react with each other only by a thermal energy, a PEALD method, in which a reactant excited by plasma is used, and the like can be used.

A CVD method and an ALD method differ from a sputtering method by which particles ejected from a target or the like are deposited. Thus, a CVD method and an ALD method can provide good step coverage, almost regardless of the shape of an object. In particular, an ALD method can provide excellent step coverage and excellent thickness uniformity and thus can be favorably used for covering a surface of an opening portion with a high aspect ratio, for example. On the other hand, an ALD method has a relatively low film formation speed; thus, it is sometimes preferable to combine an ALD method with another film formation method with a high film formation speed such as a CVD method.

By a CVD method, a film with a certain composition can be formed by adjusting the flow rate ratio of the source gases. For example, a CVD method enables a film with a gradually-changed composition to be formed by changing the flow rate ratio of the source gases during film formation. In the case where a film is formed while the flow rate ratio of the source gases is changed, as compared to the case where a film is formed using a plurality of film formation chambers, the time taken for the film formation can be shortened because the time taken for transfer or pressure adjustment is omitted. Hence, the productivity of the semiconductor device can be improved in some cases.

By an ALD method, a film with a certain composition can be formed by concurrently introducing different kinds of precursors. In the case where different kinds of precursors are introduced, a film with a certain composition can be formed by controlling the number of cycles for each of the precursors.

Thin films included in the semiconductor device (e.g., insulating films, semiconductor films, and conductive films) can be formed by a wet film formation method such as spin coating, dipping, spray coating, ink-jetting, dispensing, screen printing, offset printing, doctor blade coating, slit coating, roll coating, curtain coating, or knife coating.

In processing a thin film included in the semiconductor device, a photolithography method can be employed, for example. Alternatively, a nanoimprinting method, a sandblasting method, a lift-off method, or the like may be used to process thin films. Alternatively, island-shaped thin films may be directly formed by a film formation method using a shielding mask such as a metal mask.

In this specification and the like, the term “island shape” refers to a state where two or more layers formed using the same material in the same step are physically separated from each other.

There are two typical examples of photolithography methods. In one of the methods, a resist mask is formed over a thin film that is to be processed, the thin film is processed by an etching method, for example, and then the resist mask is removed. In the other method, a photosensitive thin film is formed and then processed into a desired shape by light exposure and development.

As light used for exposure in the photolithography method, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure may be performed by liquid immersion exposure technique. As the light for exposure, extreme ultraviolet (EUV) light or X-rays may also be used. Furthermore, instead of the light used for exposure, an electron beam can be used. It is preferable to use EUV light, X-rays, or an electron beam to perform extremely minute processing. Note that when exposure is performed by scanning of a beam such as an electron beam, a photomask is not needed.

For etching of thin films, a dry etching method, a wet etching method, a sandblasting method, or the like can be used.

A manufacturing method example of the semiconductor device illustrated in FIG. 1F is described below.

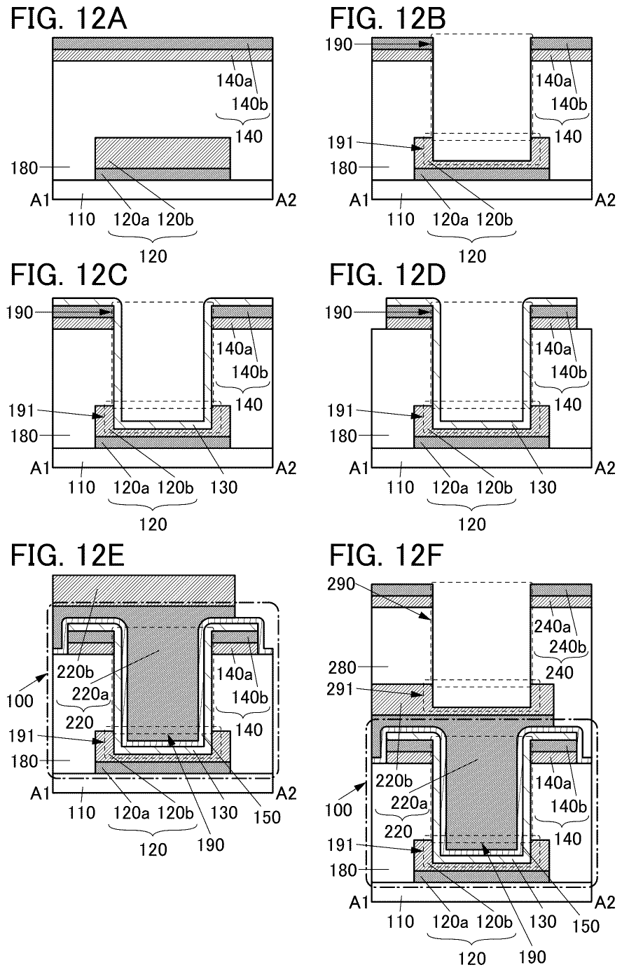

First, as illustrated in FIG. 12A, the insulating layer 110 is formed over a substrate (not illustrated), the conductive layer 120a is formed over the insulating layer 110, the conductive layer 120b is formed over the conductive layer 120a, the insulating layer 180 is formed over the conductive layer 120b, the conductive layer 140a is formed over the insulating layer 180, and the conductive layer 140b is formed over the conductive layer 140a.

Note that planarization treatment is preferably performed after formation of the insulating layer 180 to planarize the top surface of the insulating layer 180. As the planarization treatment, planarization treatment using a chemical mechanical polishing (CMP) method (also referred to as CMP treatment) is suitable. Alternatively, planarization treatment using etching (also referred to as etch back treatment) may be performed. The planarization treatment on the insulating layer 180 can flatten the formation surfaces of the conductive layer 140a and the conductive layer 240b, thereby inhibiting disconnection of the conductive layer 140a and the conductive layer 140b. Note that the planarization treatment is not necessarily performed, in which case the manufacturing cost can be reduced.

In this specification and the like, disconnection refers to a phenomenon in which a layer, a film, or an electrode is split because of the shape of the formation surface (e.g., a level difference).

Next, as illustrated in FIG. 12B, the opening portion 190 is formed in the conductive layer 140b, the conductive layer 140a, and the insulating layer 180 in a position overlapping with the conductive layer 120b. At that time, the depressed portion 191 is formed in the conductive layer 120b such that the depressed portion 191 and the opening portion 190 overlap with each other. Since the depressed portion 191 is formed in the conductive layer 120b, a contact area with the semiconductor layer 130 to be formed later can be increased. Thus, a decrease in the on-state current of the transistor 100 due to the contact resistance between the conductive layer 120b and the semiconductor layer 130 can be inhibited. Furthermore, a gate electric field is easily applied to the channel formation region of the semiconductor layer 130, so that the electrical characteristics of the transistor 100 can be improved.

At the time of forming the opening portion 190, part of the conductive layer 120b, part of the conductive layer 140a, part of the conductive layer 140b, and part of the insulating layer 180 are preferably processed by anisotropic etching for microfabrication and a small transistor size. It is particularly preferable to use a dry etching method because it is suitable for microfabrication. The opening portion 190 may be formed under processing conditions different between layers. Note that the slope of the side surface of the conductive layer 120b in the depressed portion 191 and the slopes of the side surfaces of the insulating layer 180, the conductive layer 140a, and the conductive layer 140b in the opening portion 190 are different from one another in some cases depending on the materials, processing conditions, and the like of the conductive layer 120b, the conductive layer 140a, the conductive layer 140b, and the insulating layer 180.

For example, in the formation process of the opening portion 190, a region containing a halogen element is sometimes provided in at least one of the top surface and the side surface of the conductive layer 120b in the depressed portion 191, side surfaces of the insulating layer 180, the conductive layer 140a, and the conductive layer 140b in the opening portion 190, and the top surface of the conductive layer 140b. Examples of the region include a region containing fluorine, a region containing chlorine, and a region containing fluorine and chlorine. In some cases, a halogen element derived from an etching gas used in dry etching remains in the region, for example.

Next, heat treatment may be performed. The heat treatment is performed, for example, at a temperature higher than or equal to 250 ° C and lower than or equal to 650 ° C, preferably higher than or equal to 300 ° C and lower than or equal to 500 ° C, further preferably higher than or equal to 320 ° C and lower than or equal to 450 ° C

The heat treatment is performed in an atmosphere of a nitrogen gas or an inert gas or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under a reduced pressure. Alternatively, the heat treatment may be performed in the following manner: heat treatment is performed in an atmosphere of a nitrogen gas or an inert gas, and then another heat treatment is performed in an atmosphere containing an oxidizing gas at 10 ppm or more, 1% or more, or 10% or more in order to compensate for released oxygen. By the above-described heat treatment, impurities such as water contained in the insulating layer 180, for example, can be reduced before the semiconductor layer 130 is formed.

The gas used in the above heat treatment preferably has high purity. For example, the amount of moisture contained in the gas used in the above heat treatment is preferably 1 ppb or less, further preferably 0.1 ppb or less, still further preferably 0.05 ppb or less. The heat treatment using a highly purified gas can, for example, prevent the entry of moisture into the insulating layer 180 as much as possible.

Next, as illustrated in FIG. 12C, the semiconductor layer 130 is formed to cover the opening portion 190. The semiconductor layer 130 is formed in contact with the top surface of the conductive layer 140b. Furthermore, the semiconductor layer 130 is formed in contact with the bottom portion and the sidewall of the depressed portion 191. Moreover, the semiconductor layer 130 is formed in contact with the side surface of the insulating layer 180, the side surface of the conductive layer 140a, and the side surface of the conductive layer 140b in the opening portion 190.

The semiconductor layer 130 can be formed by a sputtering method, a CVD method, an MBE method, a PLD method, or an ALD method, for example.

The semiconductor layer 130 is preferably formed to have a thickness as uniform as possible along the top surface and the side surface of the conductive layer 120b in the depressed portion 191, the side surfaces of the insulating layer 180, the conductive layer 140a, and the conductive layer 140b in the opening portion 190, and the top surface of the conductive layer 140b. The use of an ALD method allows formation of a thin film with good controllability. Therefore, the semiconductor layer 130 is preferably formed by an ALD method.

In addition, when the semiconductor layer 130 has high crystallinity, diffusion of impurities in the semiconductor layer 130 is inhibited, leading to a small variation in electrical characteristics and high reliability of the transistor. The semiconductor layer 130 is preferably formed by a sputtering method, in which case a layer with high crystallinity can be obtained easily as compared with the case of using an ALD method.

In the case where the semiconductor layer 130 is formed by a sputtering method, oxygen or a mixed gas of oxygen and a noble gas is used as a sputtering gas. An increase in the proportion of oxygen in the sputtering gas can increase the amount of excess oxygen contained in the oxide film to be formed. Moreover, when the oxide film is formed by a sputtering method, a target of the In-M-Zn oxide can be used, for example.

In the case where the semiconductor layer 130 is formed by a sputtering method and the proportion of oxygen in the sputtering gas is higher than 30% and lower than or equal to 100%, preferably higher than or equal to 70% and lower than or equal to 100%, an oxygen-excess oxide semiconductor is formed. A transistor including an oxygen-excess oxide semiconductor in its channel formation region can have relatively high reliability. However, one embodiment of the present invention is not limited thereto. When the proportion of oxygen in the sputtering gas is higher than or equal to 1% and lower than or equal to 30%, preferably higher than or equal to 5% and lower than or equal to 20%, an oxygen-deficient oxide semiconductor is formed. A transistor including an oxygen-deficient oxide semiconductor in its channel formation region can have relatively high field-effect mobility. In addition, when the oxide semiconductor is formed while the substrate is being heated, the crystallinity of the oxide semiconductor layer can be improved.

The semiconductor layer 130 preferably includes both a layer formed by an ALD method and a layer formed by a sputtering method. In that case, the semiconductor layer 130 can be formed with good coverage and have higher crystallinity. The semiconductor layer 130 preferably includes, for example, a layer formed by a sputtering method and a layer formed by an ALD method that are stacked in this order. A oxide semiconductor layer formed by a sputtering method is likely to have crystallinity. Thus, when a oxide semiconductor layer having crystallinity is provided as the lower layer of the semiconductor layer 130, the crystallinity of the upper layer of the semiconductor layer 130 can be increased. Even when a pin hole, disconnection, or the like is formed in the oxide semiconductor layer formed by a sputtering method, the oxide semiconductor layer formed by an ALD method with good coverage can fill the pin hole, the disconnection, or the like.

Specifically, the semiconductor layer 130 can have a two-layer structure of a layer formed by a sputtering method and a layer formed by an ALD method that are stacked in this order; a two-layer structure of a layer formed by an ALD method and a layer formed by a sputtering method that are stacked in this order; a three-layer structure of a layer formed by an ALD method, a layer formed by a sputtering method, and a layer formed by an ALD method that are stacked in this order; a three-layer structure of a layer formed by a sputtering method, a layer formed by an ALD method, and a layer formed by a sputtering method that are stacked in this order; or the like.

Next, heat treatment is preferably performed. The heat treatment is preferably performed in a temperature range where the semiconductor layer 130 does not become polycrystal. The heat treatment temperature is, for example, preferably higher than or equal to 100 °C and lower than or equal to 650 °C, further preferably higher than or equal to 250 °C and lower than or equal to 600 °C, still further preferably higher than or equal to 350 °C and lower than or equal to 550 °C For the details of the heat treatment, the above description can be referred to.

The gas used in the above heat treatment preferably has high purity. The heat treatment using a highly purified gas can prevent, for example, the entry of moisture or the like into the semiconductor layer 130 as much as possible.

In this embodiment, heat treatment is performed at 450 °C for an hour at a flow rate ratio of a nitrogen gas to an oxygen gas of 4:1. With the heat treatment using the above-described oxygen gas, impurities such as carbon, water, and hydrogen in the semiconductor layer 130 can be reduced. Impurities in the film are reduced in the above manner, whereby the crystallinity of the semiconductor layer 130 can be improved and a dense structure can be obtained. Accordingly, the crystal region in the semiconductor layer 130 can be increased, and an in-plane variation in the crystal region in the semiconductor layer 130 can be reduced. Thus, an in-plane variation in electrical characteristics of the transistor can be reduced.

In the case where the insulating layer 180 contains oxygen, oxygen is preferably supplied from the insulating layer 180 to the channel formation region of the semiconductor layer 130 by the heat treatment. Accordingly, oxygen vacancies and VoH can be reduced.

In this manner, oxygen (also referred to as excess oxygen) that is released by heating from the insulating layer in contact with or in the vicinity of the semiconductor layer 130 is supplied to the semiconductor layer 130 in some cases. Since excess oxygen has a function of trapping electrons, a negative charge is likely to be formed. Accordingly, the threshold voltage of the transistor can be shifted positively to enable the transistor to be normally-off.

Next, as illustrated in FIG. 12D, the semiconductor layer 130, the conductive layer 140a, and the conductive layer 140b are each processed into an island shape, so that part of the top surface of the insulating layer 180 is exposed. The semiconductor layer 130, the conductive layer 140a, and the conductive layer 140b can be processed using the same mask. This is preferable because the number of masks required for manufacturing the semiconductor device can be reduced compared with the case where the semiconductor layer 130, the conductive layer 140a, and the conductive layer 140b are processed using different masks, for example.

Next, as illustrated in FIG. 12E, the insulating layer 150 is formed to include a region located over the conductive layer 140b and a region located over the semiconductor layer 130 in the opening portion 190. Next, the conductive layer 220a is formed over the insulating layer 150, and the conductive layer 220b is formed over the conductive layer 220a. The insulating layer 150 is formed to cover the semiconductor layer 130, the conductive layer 140a, and the conductive layer 140b. Specifically, the insulating layer 150 can be formed in contact with the semiconductor layer 130, the insulating layer 180, the conductive layer 140a, and the conductive layer 140b.

The insulating layer 150 is formed along the semiconductor layer 130 covering the sidewall of the opening portion 190 with a high aspect ratio. Therefore, a film formation method that provides good coverage is preferably employed for forming the insulating layer 150. For example, tan ALD method is preferably used for forming the insulating layer 150. The conductive layer 220a is formed to fill at least part of the depressed portion of the insulating layer 150. Thus, a film formation method with favorable embeddability is preferably employed for the conductive layer 220a. The conductive layer 220a is preferably formed by a CVD method, for example. The conductive layer 220a can have a stacked-layer structure of a layer formed by an ALD method with good coverage and a layer formed by a CVD method with good embeddability, for example. The conductive layer 220b can be formed by a method similar to that for forming the conductive layer 220a. The conductive layer 220b can be formed by a CVD method, for example.

Planarization treatment may be performed on the top surface of the conductive layer 220a. For example, after the conductive layer 220a is formed and subjected to planarization treatment, the conductive layer 220a can be processed by an etching method, for example. As the planarization treatment, CMP treatment is suitable. Note that planarization treatment may be performed on the top surface of the conductive layer 220b.

The conductive layer 220a is formed to include a region facing the semiconductor layer 130 with the insulating layer 150 therebetween in the opening portion 190. The conductive layer 220a and the conductive layer 220b are each formed to include a region overlapping with the conductive layer 140a and the conductive layer 140b with the insulating layer 150 therebetween. As described above, the larger region where the conductive layer 140 and the conductive layer 220 overlap with each other with the insulating layer 150 therebetween enables the memory cell 10 to retain data for a long time. Note that FIG. 12E illustrates an example in which part of the side surface of the conductive layer 140a and part of the side surface of the conductive layer 140b are covered with the conductive layer 220a with the insulating layer 150 therebetween.

Next, as illustrated in FIG. 12F, the insulating layer 280 is formed over the conductive layer 220b and the insulating layer 150, the conductive layer 240a is formed over the insulating layer 280, and the conductive layer 240b is formed over the conductive layer 240a. After that, the opening portion 290 is formed in the conductive layer 240b, the conductive layer 240a, and the insulating layer 280 in a position overlapping with the conductive layer 220b. At that time, the depressed portion 291 is formed in the conductive layer 220b such that the depressed portion 291 and the opening portion 290 overlap with each other. For the formation of the insulating layer 280, the conductive layer 240a, the conductive layer 240b, the opening portion 290, and the depressed portion 291, the above description of the formation of the insulating layer 180, the conductive layer 140a, the conductive layer 140b, the opening portion 190, and the depressed portion 191 can be referred to.

The opening portion 290 is formed such that at least part of the opening portion 290 overlaps with the opening portion 190. As described above, the depressed portion 191 is formed in a position overlapping with the opening portion 190. Accordingly, at least part of the depressed portion 191, the opening portion 190, the depressed portion 291, and the opening portion 290 overlap with one another. Thus, the area occupied by the memory cell 10 can be smaller than in the case where the opening portion 190 and the opening portion 290 do not overlap with each other, for example. Thus, a semiconductor device that can be miniaturized or highly integrated can be manufactured. Furthermore, a semiconductor device having large storage capacity per unit area can be manufactured.

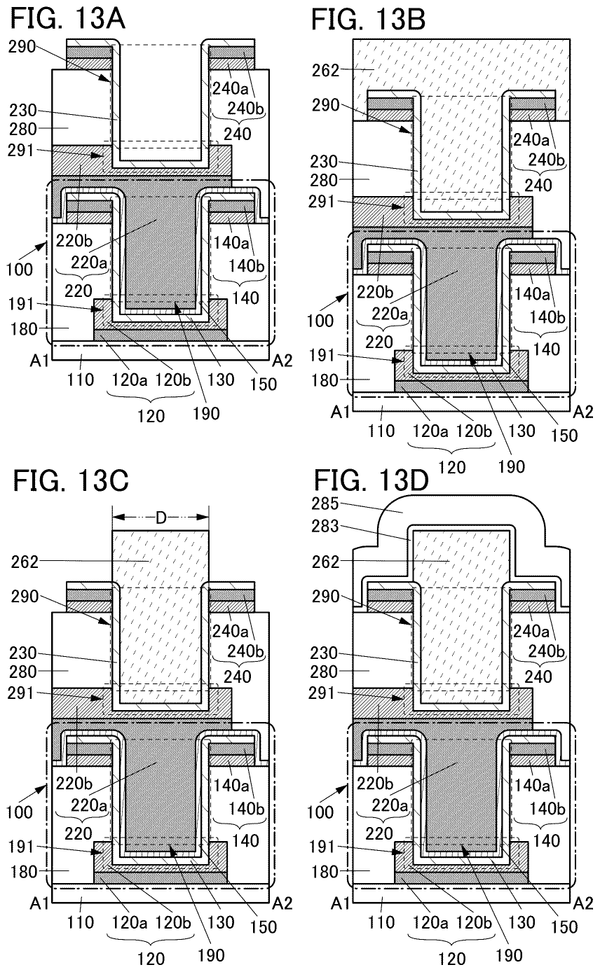

Next, as illustrated in FIG. 13A, the semiconductor layer 230 is formed to cover the opening portion 290. The semiconductor layer 230 is formed in contact with the top surface of the conductive layer 240b. Furthermore, the semiconductor layer 230 is formed in contact with the bottom portion and the sidewall of the depressed portion 291. Moreover, the semiconductor layer 230 is formed in contact with the side surface of the insulating layer 280, the side surface of the conductive layer 240a, and the side surface of the conductive layer 240b in the opening portion 290. For the formation of the semiconductor layer 230, the above description of the formation of the semiconductor layer 130 can be referred to.

Next, as illustrated in FIG. 13B, a sacrificial layer 262 is formed to cover the conductive layer 240a, the conductive layer 240b, and the semiconductor layer 230. The sacrificial layer 262 is formed to be at least partly located in the opening portion 290. As the sacrificial layer 262, a spin on carbon (SOC) film and a spin on glass (SOG) film are suitable. The sacrificial layer 262 preferably has a two-layer structure of an SOC film and an SOG film over the SOC film, for example.

Subsequentially, as illustrated in FIG. 13C, part of the sacrificial layer 262 is removed. In a region where the sacrificial layer 262 remains, a gate insulating layer and a gate electrode (the insulating layer 250 and the conductive layer 260) are provided in a later process. Thus, the sacrificial layer 262 preferably has a small region overlapping with the top surface of the conductive layer 240b or no region overlapping with the top surface of the conductive layer 240b. Thus, a semiconductor device having a small parasitic capacitance between the conductive layer 240b and the conductive layer 260 can be manufactured. In a cross-sectional view, the width of the sacrificial layer 262 is preferably less than the sum of the width D of the opening portion 290 and twice the thickness of the insulating layer 250 to be formed later. FIG. 13C illustrates an example where the width of the sacrificial layer 262 corresponds to the width D of the opening portion 290.

Next, as illustrated in FIG. 13D, the insulating layer 283 is formed to cover the insulating layer 280, the conductive layer 240a, the conductive layer 240b, the semiconductor layer 230, and the sacrificial layer 262, and the insulating layer 285 is formed over the insulating layer 283.

When the insulating layer 285 is made thick, the distance between the conductive layer 240b and the gate wiring (the conductive layer 260 or the conductive layer 265) can be increased, so that the parasitic capacitance therebetween can be reduced. Specifically, when the thickness of the insulating layer 285 is larger than the thickness of the insulating layer 150, the parasitic capacitance between the conductive layer 240b and the conductive layer 265 formed in a later step can be smaller than the capacitance Cp between the conductive layer 140b and the conductive layer 220.

A silicon oxide film is preferably formed by a sputtering method as the insulating layer 285, for example.

Here, in the case where the insulating layer 283 is not provided, the sacrificial layer 262 is exposed to plasma containing oxygen in forming a silicon oxide film by a sputtering method as the insulating layer 285. Thus, part or the whole of the sacrificial layer 262 is etched in some cases. As described above, depending on the formation method of the insulating layer 285, the sacrificial layer 262 might be shrunk or disappear. For this reason, the insulating layer formed over the sacrificial layer 262 preferably has not a single-layer structure of the insulating layer 285 but a stacked-layer structure of the insulating layer 283 and the insulating layer 285. This can produce effects of widening the range of choices of the materials for the sacrificial layer 262 and the insulating layer 285, lowering the difficulty of manufacturing the semiconductor device, and the like.

In the case where an oxide film is used as the insulating layer 283, the oxide film is preferably formed by a method other than a sputtering method, e.g., an ALD method. For example, an aluminum oxide film, a hafnium oxide film, or a nitride film (e.g., a silicon nitride film) is preferably formed as the insulating layer 283 by an ALD method. Thus, the sacrificial layer 262 can be inhibited from being unintentionally processed in forming the insulating layer 283.

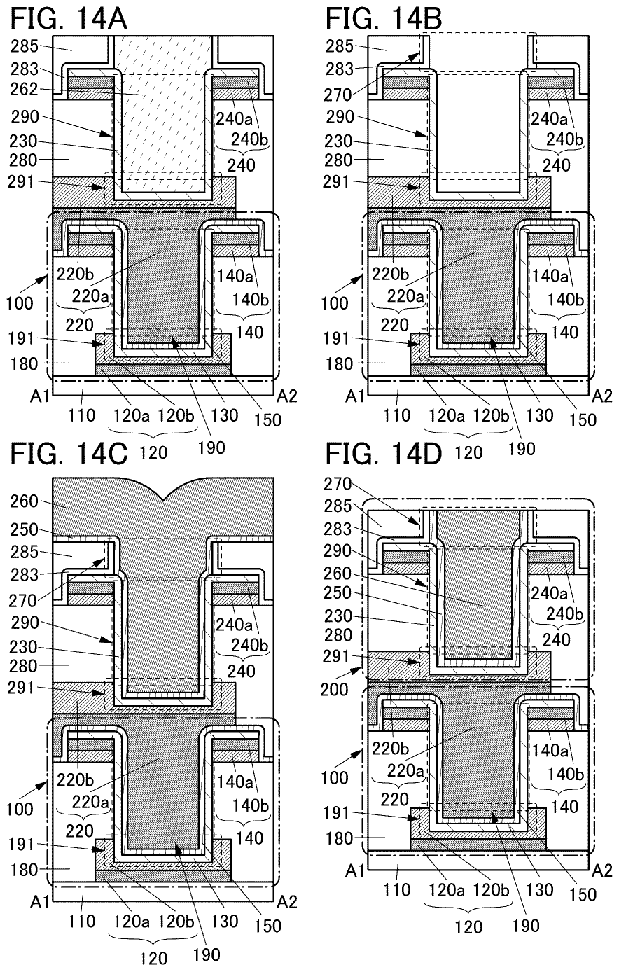

Next, as illustrated in FIG. 14A, planarization treatment is performed on the insulating layer 285 and the sacrificial layer 262. Thus, the top surface of the sacrificial layer 262 is exposed and the top surfaces of the sacrificial layer 262, the insulating layer 283, and the insulating layer 285 are planarized. As the planarization treatment, CMP treatment is suitable. At least part of the insulating layer 283 and part of the insulating layer 285 are removed by the planarization treatment. In addition, part of the sacrificial layer 262 may be removed.

Next, as illustrated in FIG. 14B, the sacrificial layer 262 is removed. There is no particular limitation on the method for removing the sacrificial layer 262. Here, as illustrated in FIG. 14B, the opening portion 270 including a region overlapping with the opening portion 290 is formed in the insulating layer 285. In other words, the opening portion 270 including a region overlapping with the opening portion 290 is formed in the insulating layer 283.

Next, as illustrated in FIG. 14C, the insulating layer 250 is formed to cover the opening portion 270 and the opening portion 290, and the conductive layer 260 is formed over the insulating layer 250. The insulating layer 250 is provided in contact with the semiconductor layer 230, the insulating layer 283, and the insulating layer 285.

The insulating layer 250 and the conductive layer 260 are each formed in the opening portion 290 and the opening portion 270 with a high aspect ratio, respectively. Thus, the insulating layer 250 and the conductive layer 260 are preferably formed by a film formation method with favorable coverage or embeddability, e.g., a CVD method or an ALD method. The insulating layer 250 is preferably formed by an ALD method, for example. The conductive layer 260 is preferably formed by a CVD method. For example, in the case where the conductive layer 260 has a stacked-layer structure, a CVD method is preferably used for forming at least one layer of the stacked-layer structure.

Next, as illustrated in FIG. 14D, planarization treatment is performed on the conductive layer 260 to expose the top surfaces of the insulating layer 283 and the insulating layer 285 and planarize the top surfaces of the conductive layer 260, the insulating layer 250, the insulating layer 283, and the insulating layer 285. As the planarization treatment, CMP treatment is suitable. In the planarization treatment, at least regions of the conductive layer 260 and the insulating layer 250 that overlap with the top surface of the insulating layer 285 are removed. Thus, a region of the conductive layer 260 that overlaps with the top surface of the conductive layer 240b can be removed. This can inhibit generation of parasitic capacitance between the conductive layer 260 and the conductive layer 240b.

By removing the region of the conductive layer 260 overlapping with the top surface of the conductive layer 240b by the CMP treatment, an increase in the number of masks can be inhibited as compared with the case of using dry etching, for example.

As illustrated in FIG. 14D, the top surface of the insulating layer 285 and the top surface of the conductive layer 260 are preferably level with each other. Alternatively, one of the top surface of the insulating layer 285 and the top surface of the conductive layer 260 may be higher than the other. Owing to the difference in polishing rate between the materials for the insulating layer 285 and the conductive layer 260, the top surface levels of the two layers can be controlled.

Next, as illustrated in FIG. 1F, the conductive layer 265 is formed over the insulating layer 285, the insulating layer 283, the insulating layer 250, and the conductive layer 260. The conductive layer 265 is formed in contact with the top surface of the conductive layer 260. Furthermore, the conductive layer 265 can be formed in contact with the top surface of the insulating layer 285, the top surface of the insulating layer 283, and the top surface of the insulating layer 250.

The insulating layer 283 and the insulating layer 285 are located between the conductive layer 265 and the conductive layer 240b. Thus, the parasitic capacitance between the conductive layer 240 and the conductive layer 260 can be smaller than the capacitance Cp between the conductive layer 140 and the conductive layer 220.

In the above manner, the semiconductor device of one embodiment of the present invention can be manufactured.

### Element Addition

As described above, a region containing a halogen element may be provided in each of the insulating layer 180 and the insulating layer 280. A region containing a halogen element may be provided in each of the semiconductor layer 130 and the semiconductor layer 230. A region containing the above-described first element may be provided in each of the semiconductor layer 130 and the semiconductor layer 230. A region containing the first element may be provided in at least one of the conductive layer 120a, the conductive layer 120b, the conductive layer 140a, the conductive layer 140b, the conductive layer 220a, the conductive layer 220b, the conductive layer 240a, and the conductive layer 240b. An example of providing a region containing a halogen element in the insulating layer 180 or the semiconductor layer 130 and an example of providing a region containing the first element in at least one of the semiconductor layer 130, the conductive layer 120a, the conductive layer 120b, the conductive layer 140a, and the conductive layer 140b are described below. Note that when the insulating layer 180, the semiconductor layer 130, the conductive layer 120a, the conductive layer 120b, the conductive layer 140a, and the conductive layer 140b are replaced with the insulating layer 280, the semiconductor layer 230, the conductive layer 220a, the conductive layer 220b, the conductive layer 240a, and the conductive layer 240b, respectively, the following description can also be applied to the case where a halogen element or the first element is supplied to the insulating layer 280, the semiconductor layer 230, the conductive layer 220a, the conductive layer 220b, the conductive layer 240a, and the conductive layer 240b, for example.

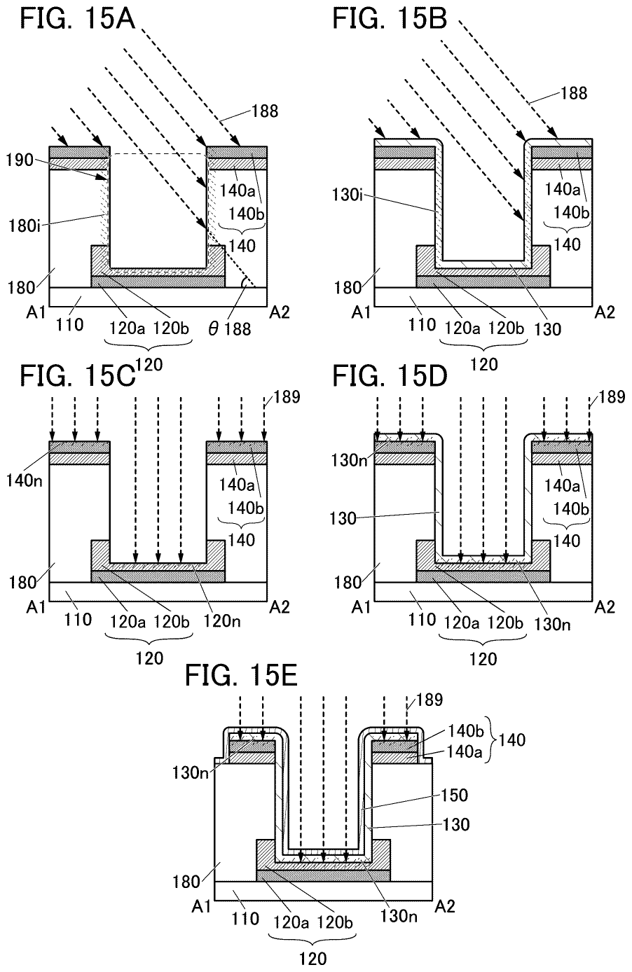

For example, as illustrated in FIG. 15A, after the structure illustrated in FIG. 12B is formed, a halogen element 188 is supplied to the side surface of the insulating layer 180 in the opening portion 190. A region of the insulating layer 180 supplied with the halogen element 188 is referred to as the region 180i. The region 180i includes at least the side surface of the insulating layer 180 in the opening portion 190. Note that the halogen element 188 may also be supplied to one or more of the conductive layer 140a, the conductive layer 140b, the conductive layer 120a, and the conductive layer 120b.

Here, FIG. 15A illustrates an example where the sidewall of the opening portion 190 is perpendicular to the top surface of the substrate. In the semiconductor device of one embodiment of the present invention, the sidewall of the opening portion 190 is perpendicular or substantially perpendicular to the top surface of the substrate or has a tapered shape. Accordingly, when the halogen element 188 is added perpendicularly or substantially perpendicularly to the top surface of the substrate, it is sometimes difficult to supply the halogen element 188 uniformly to a desired region.

Thus, as illustrated in FIG. 15A, the halogen element 188 is preferably added from a direction that is inclined to the top surface of the substrate at greater than 0° and less than 90°. FIG. 15A illustrates an example where the halogen element 188 is added with an inclination at an angle θ188 to the top surface of the insulating layer 110. The angle θ188 is preferably greater than 0° and less than 90°, further preferably greater than or equal to 15° and less than or equal to 80°. Thus, the halogen element can be easily supplied to the side surface of the insulating layer 180 in the opening portion 190. The adding direction is not limited to one direction; the halogen element 188 is preferably supplied step by step at different angles, in which case the halogen element 188 can be supplied to a desired region more uniformly.

An element that can be used as the halogen element 188 is as described above.

A plasma ion doping method or an ion implantation method can be suitably used for the supply of the halogen element 188. In the above methods, the concentration profile in the depth direction can be controlled with high accuracy by the acceleration voltage and the dose of ions, for example.

Note that when one or both of the substrate to be processed and the ion irradiation portion of the apparatus are inclined, for example, the angle θ188 can be within the above range.

With the use of an ion implantation method in which a source gas is ionized and the ions are subjected to mass separation and then added, the purity of the halogen element 188 to be supplied can be increased. The region 180i is in contact with the channel formation region of the semiconductor layer 130. Thus, when another impurity element is supplied to the region 180i at the time of supplying the halogen element 188, the impurity element diffuses into the channel formation region of the semiconductor layer 130, which might adversely affect the characteristics and reliability of the transistor. Thus, the halogen element 188 with high purity is preferably supplied to the region 180i by an ion implantation method.

Furthermore, with the use of a plasma ion doping method in which the source gas is ionized and the ions are added without mass separation, the productivity can be increased.

An ion implantation apparatus or an ion doping apparatus used for supplying the halogen element 188 is used also in manufacturing a Si transistor such as an LTPS transistor, which is preferable because an apparatus for an existing LTPS manufacturing line can be used and new capital investment is not required. Thus, capital investment for manufacturing the semiconductor device can be reduced.

As the source gas of the halogen element 188, a gas containing the above-described halogen element can be used. As the gas, a gas of halogen alone or a halide gas can also be used. In the case where fluorine is supplied, an F₂ gas, a BF₃ gas, a C₄F₆ gas, a C₅F₆ gas, a C₄F₈ gas, a CF₄ gas, an SF₆ gas, a CHF₃ gas, a CH₂F₂ gas, a CH₃F gas, or the like can be typically used. In the case where chlorine is supplied, a Cl₂ gas, a BCl₃ gas, an SiCl₄ gas, or a CCl₄ gas can be typically used. A mixed gas in which the above source gas is diluted with hydrogen or a noble gas may be used. The ion source is not limited to a gas, and a solid or a liquid may be vaporized by heating.

The supply of the halogen element 188 can be controlled by setting the conditions such as the acceleration voltage and the dose in consideration of the composition, the density, the thickness, and the like of the insulating layer 180.

Note that there is no limitation on the method for supplying the halogen element 188, and for example, plasma treatment, treatment using thermal diffusion by heating, or the like may be used. In the case of a plasma treatment method, an impurity element can be supplied in such a manner that plasma is generated in a gas atmosphere containing the halogen element to be supplied and plasma treatment is performed. A dry etching apparatus, an ashing apparatus, a plasma CVD apparatus, a high-density plasma CVD apparatus, or the like can be used to generate the plasma.

The step of supplying the halogen element 188 may be performed while the substrate is heated. Thus, damage applied to the insulating layer 180 when the halogen element 188 is added can be repaired. That is, the addition of the halogen element 188 and the repair of damage due to the addition can be performed on the insulating layer 180 in parallel.

The substrate temperature in the step of supplying the halogen element 188 is preferably higher than or equal to 150 °C and lower than the strain point of the substrate, further preferably higher than or equal to 200 °C and lower than or equal to 500 °C, still further preferably higher than or equal to 200 °C and lower than or equal to 450 °C, yet further preferably higher than or equal to 250 °C and lower than or equal to 400 °C, yet still further preferably higher than or equal to 250 °C and lower than or equal to 350 °C, yet still further preferably higher than or equal to 300 °C and lower than or equal to 400 °C, yet still further preferably higher than or equal to 300 °C and lower than or equal to 350 °C.

When the semiconductor layer 130 is formed while the substrate is heated, the halogen element can be supplied from the region 180i to the semiconductor layer 130 in some cases. In the heat treatment performed after formation of the semiconductor layer 130, the halogen element can be supplied from the region 180i to the semiconductor layer 130 in some cases.

As described above, in the semiconductor device of one embodiment of the present invention, the halogen element 188 is added to the insulating layer 180 and then the halogen element 188 is supplied from the insulating layer 180 to the semiconductor layer 130; thus, damage to the channel formation region of the semiconductor layer 130 due to the element addition, decrease in crystallinity of the channel formation region due to the element addition, and the like can be inhibited. As a result, the reliability of the transistor can be increased.

Alternatively, as illustrated in FIG. 15B, after the structure illustrated in FIG. 12C is formed, the halogen element 188 may be supplied to the side surface of the semiconductor layer 130 located in the opening portion 190. A region of the semiconductor layer 130 supplied with the halogen element 188 is referred to as a region 130i. The region 130i includes at least the side surface of the semiconductor layer 130 located in the opening portion 190. Note that the halogen element 188 may also be supplied to one or more of the insulating layer 180, the conductive layer 140a, the conductive layer 140b, the conductive layer 120a, and the conductive layer 120b.

Alternatively, as illustrated in FIG. 15C, after the structure illustrated in FIG. 12B is formed, an impurity element 189 is supplied to the top surface of the conductive layer 120b and the top surface of the conductive layer 140b, for example. A region of the conductive layer 120b supplied with the impurity element 189 is referred to as a region 220n. Similarly, a region of the conductive layer 140b supplied with the impurity element 189 is referred to as a region 140n.

After that, when the semiconductor layer 130 is formed and heat treatment or the like is performed, the impurity element 189 can be supplied from the region 120n and the region 140n to the source region and the drain region of the semiconductor layer 130.

When the impurity element 189 is supplied to the semiconductor layer 130 through the conductive layer 120 or the conductive layer 140, a decrease in crystallinity of the semiconductor layer 130 can be inhibited as compared with the case where the impurity element 189 is directly added to the semiconductor layer 130. Thus, an increase in electric resistance due to the decrease in crystallinity can be inhibited.

Alternatively, as illustrated in FIG. 15D, after the structure illustrated in FIG. 12C is formed, the impurity element 189 may be supplied to the semiconductor layer 130. a region of the semiconductor layer 130 supplied with the impurity element 189 is referred to as the region 130n.

When the impurity element 189 is added to the semiconductor layer 130, the sheet resistance of the semiconductor layer 130, the contact resistance between the semiconductor layer 130 and the conductive layer 120, and the contact resistance between the semiconductor layer 130 and the conductive layer 140 can be reduced.

The insulating layer 150 is formed over the semiconductor layer 130 after the impurity element 189 is directly added to the semiconductor layer 130, whereby the insulating layer 150 can be inhibited from being damaged by addition of the impurity element 189.

The impurity element 189 is preferably added from a direction perpendicular or substantially perpendicular to the top surface of the substrate. In this case, in the semiconductor layer 130, the addition amount of the impurity element is smaller for a surface inclined to or perpendicular or substantially perpendicular to the top surface of the substrate than for a surface parallel or substantially parallel to the top surface of the substrate. That is, in the semiconductor layer 130, the addition amount of the impurity element is larger in the source region and the drain region than in the channel formation region. Thus, the resistances of the source region and the drain region can be reduced preferentially.

FIG. 15D illustrates an example where the region 130n is formed at and near the interface between the semiconductor layer 130 and the top surface of the conductive layer 120b and at and near the interface between the semiconductor layer 130 and the top surface of the conductive layer 140b.

An element that can be used as the impurity element 189 is as described above.

A plasma ion doping method or an ion implantation method can be suitably used for the supply of the impurity element 189. In the above methods, the concentration profile in the depth direction can be controlled with high accuracy by the acceleration voltage and the dose of ions, for example.

With the use of an ion implantation method in which the source gas is ionized and the ions are subjected to mass separation and then added, the purity of an impurity element to be supplied can be increased. In the case of using an ion implantation method, the above-described first element is preferably used as the impurity element 189, and boron or phosphorus is further preferably used. When an element that is stabilized by being bonded to oxygen is used as the impurity element 189, the region 130n can be stable in a low-electric-resistance state.

Furthermore, with the use of a plasma ion doping method in which the source gas is ionized and the ions are added without mass separation, the productivity can be increased. In the case of using a plasma ion doping method, the first element and hydrogen are each preferably used as the impurity element 189, and hydrogen and boron or phosphorus are further preferably used. When hydrogen and an element that is stabilized by being bonded to oxygen are each used as the impurity element 189, the electric resistance of the region 130n is easily reduced and the low-electric-resistance state can be kept stable.

An ion implantation apparatus or an ion doping apparatus used for supplying the impurity element 189 is used also in manufacturing a Si transistor such as an LTPS transistor, which is preferable because an apparatus for an existing LTPS manufacturing line can be used and new capital investment is not required. Thus, capital investment for manufacturing the semiconductor device can be reduced.

In the treatment for supplying the impurity element 189, the treatment conditions are preferably controlled such that the impurity element concentration in the semiconductor layer 130 is higher in a region overlapping with the top surface of the conductive layer 120b or the top surface of the conductive layer 140b than in the other regions. Thus, the impurity element 189 at an optimal concentration can be supplied to the source region and the drain region of the semiconductor layer 130.

A gas containing the above impurity element can be used as a source gas of the impurity element 189. In the case where boron is supplied, a B₂H₆ gas, a BF₃ gas, or the like can be typically used. In the case where phosphorus is supplied, a PH₃ gas can be typically used. A mixed gas in which the above source gas is diluted with hydrogen or a noble gas may be used.

Alternatively, as the source gas, CH₄, N₂, NH₃, AlH₃, AlCl₃, SiH₄, Si₂H₆, F₂, HF, H₂, (C₅H₅)₂Mg, a noble gas, or the like can be used. The ion source is not limited to a gas, and a solid or a liquid may be vaporized by heating.

For example, boron and hydrogen are preferably supplied as the impurity element 189 using a gas containing boron and hydrogen. This is preferable because the impurity element 189 can be added without mass separation and the resistance of the semiconductor layer 130 can be easily reduced, thereby improving both the productivity and characteristics of the semiconductor device.

Furthermore, the same source gas is preferably used in the step of supplying the halogen element 188 and the step of supplying the impurity element 189, in which case the manufacturing cost can be reduced. For example, by ionization of a BF₃ gas and mass separation of the ion, fluorine can be supplied as the halogen element 188 and boron can be supplied as the impurity element 189.

The supply of the impurity element 189 can be controlled by setting the conditions such as the acceleration voltage and the dose in consideration of the composition, the density, the thickness, and the like of the semiconductor layer 130.

Note that there is no limitation on the method for supplying the impurity element 189, and for example, plasma treatment, treatment using thermal diffusion by heating, or the like may be used. In the case of a plasma treatment method, an impurity element can be supplied in such a manner that plasma is generated in a gas atmosphere containing the impurity element to be supplied and plasma treatment is performed. A dry etching apparatus, an ashing apparatus, a plasma CVD apparatus, a high-density plasma CVD apparatus, or the like can be used to generate the plasma.

The step of supplying the impurity element 189 is preferably performed while the substrate is heated. Thus, damage applied to the semiconductor layer 130 when the impurity element 189 is added can be repaired. That is, the addition of the impurity element 189 and the repair of damage due to the addition can be performed on the semiconductor layer 130 in parallel.

The substrate temperature in the step of supplying the impurity element 189 is preferably higher than or equal to 150 °C and lower than the strain point of the substrate, further preferably higher than or equal to 200 °C and lower than or equal to 500 °C, still further preferably higher than or equal to 200 °C and lower than or equal to 450 °C, yet further preferably higher than or equal to 250 °C and lower than or equal to 400 °C, yet still further preferably higher than or equal to 250 °C and lower than or equal to 350 °C, yet still further preferably higher than or equal to 300 °C and lower than or equal to 400 °C, yet still further preferably higher than or equal to 300 °C and lower than or equal to 350 °C

Heat treatment may be performed after the impurity element 189 is supplied. By the heat treatment, damage to the semiconductor layer 130 in the step of supplying the impurity element 189 can be repaired.

When an element that is stabilized by being bonded to oxygen is used as the impurity element 189, the impurity element 189 can be inhibited from being released by heat applied during the manufacturing process of the semiconductor device, for example. Thus, even when heat treatment is performed or a film formation step or the like is performed while the substrate is heated after the addition of the impurity element 189, the region 130n can keep the low-electric-resistance state.

As illustrated in FIG. 15E, the impurity element 189 may be added to the semiconductor layer 130 through the insulating layer 150. Note that in this case, the impurity element 189 is also supplied to the insulating layer 150 in some cases. The region 130n preferably includes a region having a higher concentration of the impurity element 189 than the insulating layer 150, in which case the electric resistance of the region 130n can be further reduced.

When the impurity element 189 is supplied to the semiconductor layer 130 through the insulating layer 150, the decrease in crystallinity of the semiconductor layer 130 can be inhibited as compared with the case where the impurity element 189 is directly added to the semiconductor layer 130. Thus, an increase in electric resistance due to the decrease in crystallinity can be inhibited.

When the insulating layer 150 is formed after the addition of the impurity element 189, the film formation chamber of the insulating layer 150 might be contaminated. Thus, the impurity element 189 is preferably added after the insulating layer 150 is formed.

Here, the thickness of the insulating layer 150 in the direction where the impurity element 189 is added is larger in a region provided along the side surface of the insulating layer 180 than in a region provided along the top surface of the conductive layer 120b or the top surface of the conductive layer 140b. Thus, in the semiconductor layer 130, the addition amount of the impurity element 189 is larger in the region provided along the top surface of the conductive layer 120b or the top surface of the conductive layer 140b than in the region provided along the side surface of the insulating layer 180. In this manner, the impurity element 189 can be inhibited from entering the channel formation region of the semiconductor layer 130, so that the resistances of the source region and the drain region can be reduced preferentially.

As described above, the semiconductor device of one embodiment of the present invention has a structure where a gate electric field is easily applied to the semiconductor layer. Accordingly, the transistor can have favorable electrical characteristics. The semiconductor device of one embodiment of the present invention has a structure in which data can be retained even when a capacitor is not provided. Thus, a low-cost semiconductor device can be provided.

This embodiment can be combined with the other embodiments as appropriate. In this specification, in the case where a plurality of structure examples are shown in one embodiment, the structure examples can be combined as appropriate.

### Embodiment 2

In this embodiment, a memory device of one embodiment of the present invention will be described with reference to drawings. Specifically, a memory device including the memory cell described in the above embodiment will be described with reference to drawings.

The memory cells 10 are arranged in a matrix three-dimensionally, whereby a memory cell array can be formed.

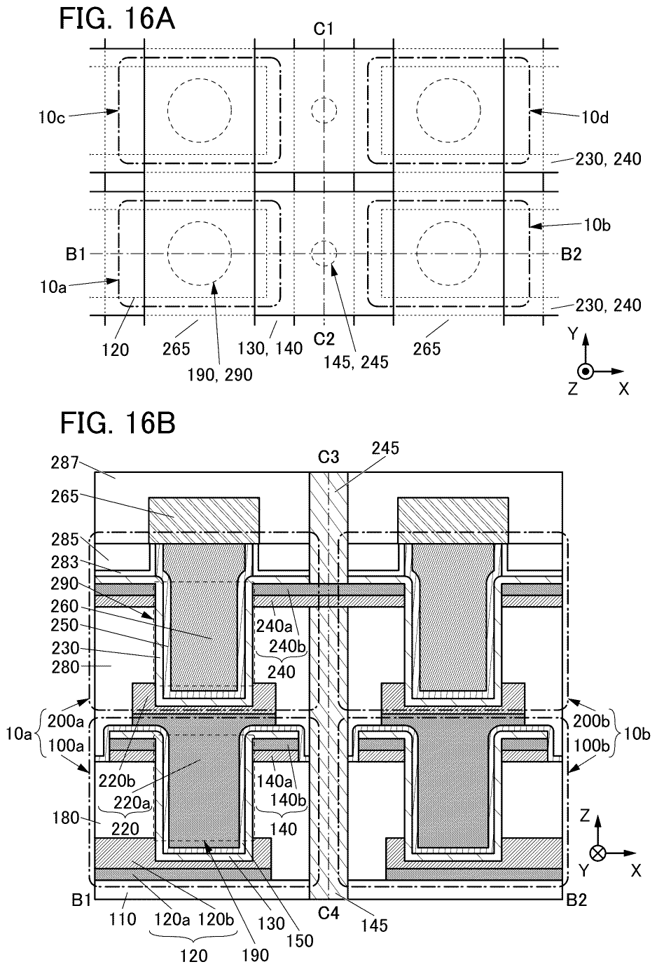

FIG. 16A is a plan view of the memory device. FIG. 16A illustrates an example where 2 ×2 memory cells 10 (a memory cell 10a to a memory cell 10d) are arranged in the X direction and the Y direction.

FIG. 16B is a cross-sectional view along the dashed-dotted line B1-B2 in FIG. 16A. In the example illustrated in FIG. 16A and FIG. 16B, the two memory cells are connected to common wirings (a conductive layer 145 and a conductive layer 245).

As illustrated in FIG. 16A and FIG. 16B, the conductive layer 140 and the conductive layer 265 are provided in each of the memory cell 10a and the memory cell 10b. As illustrated in FIG. 16A, one conductive layer 140 and one conductive layer 265 are provided so as to be shared by the memory cell 10a and the memory cell 10c. That is, the conductive layer 140 is in contact with the semiconductor layer 130 of the memory cell 10a and the semiconductor layer 130 of the memory cell 10c. Furthermore, another conductive layer 140 and another conductive layer 265 are provided so as to be shared by the memory cell 10b and the memory cell 10d.

One conductive layer 240 is provided so as to be shared by the memory cell 10a and the memory cell 10b. That is, the conductive layer 240 is in contact with the semiconductor layer 230 of the memory cell 10a and the semiconductor layer 230 of the memory cell 10b. Furthermore, another conductive layer 240 is provided so as to be shared by the memory cell 10c and the memory cell 10d.

Here, the memory device illustrated in FIG. 16A and FIG. 16B includes an insulating layer 287 located over the conductive layer 265 and the insulating layer 283. Here, the memory device illustrated in FIG. 16A and FIG. 16B includes the conductive layer 145 and the conductive layer 245 functioning as plugs (which also can be referred to as connection electrodes) electrically connected to the memory cell 10a and the memory cell 10b. The conductive layer 145 is placed in an opening portion formed in the insulating layer 110, the insulating layer 180, the insulating layer 150, and the insulating layer 280, and is in contact with the bottom surface of the conductive layer 240a. The conductive layer 245 is placed in an opening portion formed in the insulating layer 287, the insulating layer 285, the insulating layer 283, and the semiconductor layer 230, and is in contact with the top surface of the conductive layer 240b. Note that a conductive material that can be used for the conductive layer 140 and the conductive layer 240, or the like can be used for the conductive layer 145 and the conductive layer 245.

The conductive layer 245 can be in contact with the top surface of the conductive layer 240a. Alternatively, the conductive layer 245 can be in contact with the top surface of the semiconductor layer 230. That is, the conductive layer 240b may include an opening portion in a position overlapping with the conductive layer 245. The semiconductor layer 230 does not necessarily include an opening portion in a position overlapping with the conductive layer 245. As a connection portion between the memory cell and the plug, a layer having a low contact resistance with the conductive layer 245 among the layers included in the conductive layer 240 and the semiconductor layer 230 is preferably in contact with the conductive layer 245.

Similarly, the conductive layer 145 can be in contact with the bottom surface of the conductive layer 240b or the bottom surface of the semiconductor layer 230. That is, the conductive layer 240a may include an opening portion in a position overlapping with the conductive layer 245. Among the layers included in the conductive layer 240 and the semiconductor layer 230, a layer having a low contact resistance with the conductive layer 145 is preferably in contact with the conductive layer 145.

Among the layers included in the conductive layer 240 and the semiconductor layer 230, a layer with a low wiring resistance is preferably in contact with the conductive layer 145 and the conductive layer 245.

The insulating layer 287 functions as an interlayer film and thus preferably has a low dielectric constant. In the case where a material with a low dielectric constant is used for an interlayer film, parasitic capacitance between wirings can be reduced.

The concentration of impurities such as water and hydrogen in the insulating layer 287 is preferably reduced. This can inhibit entry of impurities such as water or hydrogen into the channel formation region of the semiconductor layer 230.

The conductive layer 145 and the conductive layer 245 each function as a plug or a wiring for electrically connecting the memory cell 10a and the memory cell 10b to a wiring, an electrode, a terminal, or a circuit element such as a switch, a transistor, a capacitor, an inductor, a resistor, or a diode. For example, the conductive layer 145 can be electrically connected to a sense amplifier (not illustrated) provided below the memory device illustrated in FIG. 16B, and the conductive layer 245 can be electrically connected to a similar memory device (not illustrated) provided above the memory device illustrated in FIG. 16B. In that case, the conductive layer 145 and the conductive layer 245 function as part of the wiring 23 described in the above embodiment. When the memory device or the like is provided above or below the memory device illustrated in FIG. 16B in this manner, the storage capacity per unit area can be increased.

The memory cell 10a and the memory cell 10b have a line-symmetric structure with a perpendicular bisector C1-C2 of the dashed-dotted line B1-B2 illustrated in FIG. 16A as the symmetric axis. The memory cell 10a and the memory cell 10b have a line-symmetric structure with a perpendicular bisector C3-C4 of the dashed-dotted line B1-B2 illustrated in FIG. 16B as the symmetric axis. Thus, a transistor 200a and a transistor 200b are also placed symmetrically with the conductive layer 145 and the conductive layer 245 therebetween. Note that the conductive layer 240 has a function of the other of the source electrode and the drain electrode of the transistor 200a and a function of the other of the source electrode and the drain electrode of the transistor 200b. The transistor 200a and the transistor 200b share the conductive layer 145 and the conductive layer 245 functioning as plugs. With the above connection structure between the two transistors and the plugs, a memory device that can be miniaturized or highly integrated can be provided. Similarly, the transistor 100a and the transistor 100b are also placed symmetrically with the conductive layer 145 and the conductive layer 245 therebetween.

The conductive layer 120 may be provided in each of the memory cell 10a and the memory cell 10b or may be provided so as to be shared by the memory cell 10a and the memory cell 10b. Note that as illustrated in FIG. 16B, the conductive layer 120 and the conductive layer 145 are provided to be apart from each other so as not to be short-circuited.

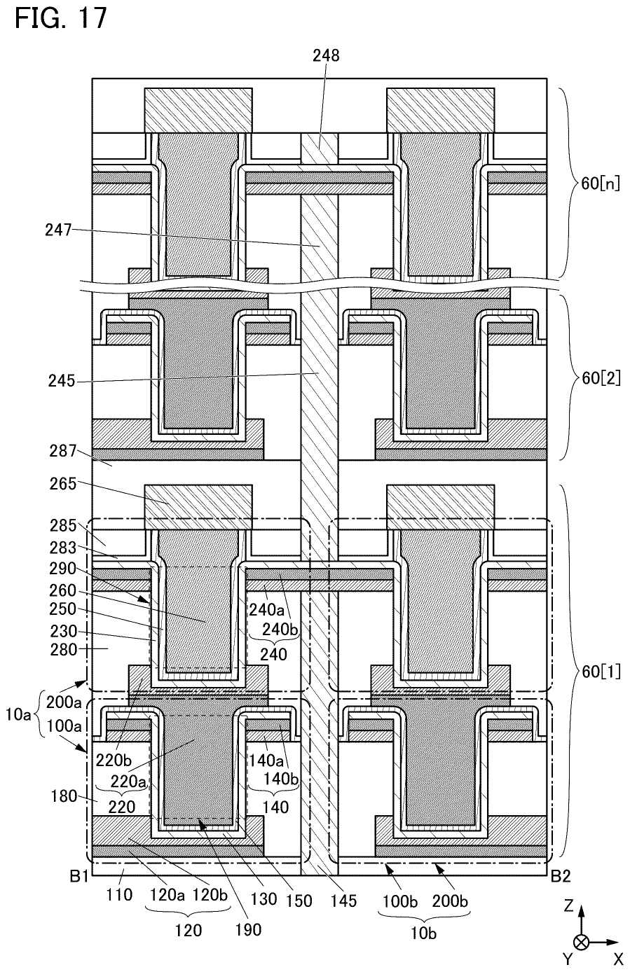

FIG. 17 illustrates an example where four memory cells illustrated in FIG. 16A are stacked in n layers (n is an integer greater than or equal to 3) in the Z direction. FIG. 17 is a cross-sectional view along the dashed-dotted line B1-B2 in FIG. 16A.

The memory device illustrated in FIG. 17 includes n memory layers 60. Specifically, a memory layer 60[2] is provided over a memory layer 60[1], (n-2) memory layers are provided over the memory layer 60[2], and a memory layer 60[n] is provided in the uppermost stage. There is no particular limitation on the number of memory cells included in one memory layer 60, and two or more memory cells can be included. Through the conductive layer 145, the conductive layer 245, a conductive layer 247, a conductive layer 248 and the like, memory cells included in the n memory layers 60 are electrically connected to a sense amplifier (not illustrated) provided below the n memory layers 60.

FIG. 17 illustrates an example where the conductive layer 145 is in contact with the bottom surface of the conductive layer 240 and the conductive layer 245 is in contact with the top surface of the semiconductor layer 230. As described above, a connection portion between the plug such as the conductive layer 145, the conductive layer 245, or the like and each memory cell can have any of a variety of modes and is not limited to the structure in FIG. 17.

When a plurality of memory cells are stacked as illustrated in FIG. 17, the cells can be placed in an integrated manner without increasing the area occupied by the memory cell array. That is, a 3D memory cell array can be formed.

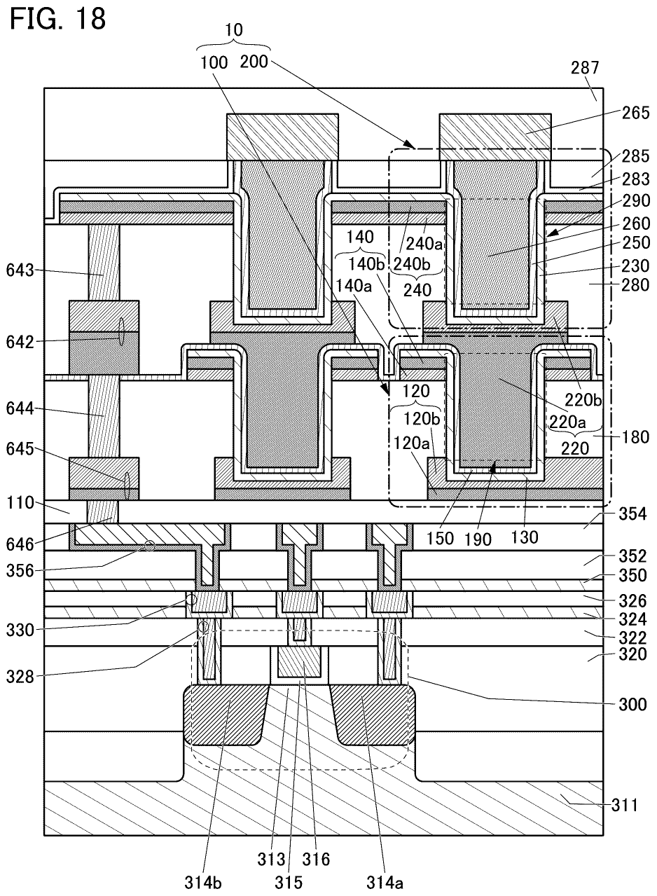

FIG. 18 illustrates a cross-sectional structure example of a memory device in which a layer including a memory cell is stacked over a layer including a driver circuit provided with a sense amplifier.

In FIG. 18, the memory cell 10 (the transistor 100 and the transistor 200) is provided above a transistor 300.

The transistor 300 is one of transistors included in the sense amplifier.

When the sense amplifier is provided to overlap with the memory cell 10 as illustrated in FIG. 18, a bit line can be shortened. This reduces bit line capacitance, which reduces the storage capacitance of the memory cell.

The memory device illustrated in FIG. 18 can correspond to a semiconductor device 900 described in Embodiment 3. Specifically, the transistor 300 corresponds to a transistor included in a sense amplifier 927 in the semiconductor device 900. The memory cell 10 corresponds to a memory cell 950.

The transistor 300 is provided on a substrate 311 and includes a conductive layer 316 functioning as a gate, an insulating layer 315 functioning as a gate insulating layer, a semiconductor region 313 that is a part of the substrate 311, and a low-resistance region 314a and a low-resistance region 314b functioning as a source region and a drain region. The transistor 300 may be either a p-channel transistor or an n-channel transistor.

In the transistor 300 illustrated in FIG. 18, the semiconductor region 313 (part of the substrate 311) where a channel is formed has a projecting shape. Furthermore, the conductive layer 316 is provided to cover the side surface and the top surface of the semiconductor region 313 with the insulating layer 315 therebetween. Note that the conductive layer 316 may be formed using a material for adjusting the work function. The transistor 300 having such a structure is also referred to as a FIN transistor because the projecting portion of the semiconductor substrate is utilized. Note that an insulating layer serving as a mask for forming the projecting portion may be provided in contact with the top of the projecting portion. Although the case where the projecting portion is formed by processing part of the semiconductor substrate is described here, a semiconductor film having a projecting shape may be formed by processing an SOI substrate.

Note that the transistor 300 illustrated in FIG. 18 is just an example and is not limited to having the structure illustrated therein; an appropriate transistor can be used in accordance with a circuit structure or a driving method.

Wiring layers including an interlayer film, a wiring, a plug, and the like may be provided between the structure bodies. A plurality of wiring layers can be provided in accordance with the design. Here, a plurality of conductive layers functioning as plugs or wirings are collectively denoted by the same reference numeral in some cases. Furthermore, in this specification and the like, a wiring and a plug electrically connected to the wiring may be a single component. That is, in some cases, part of a conductive layer functions as a wiring or part of a conductive layer functions as a plug.

For example, an insulating layer 320, an insulating layer 322, an insulating layer 324, and an insulating layer 326 are stacked over the transistor 300 in this order as interlayer films. A conductive layer 328 is embedded in the insulating layer 320 and the insulating layer 322, and a conductive layer 330 is embedded in the insulating layer 324 and the insulating layer 326. Note that the conductive layer 328 and the conductive layer 330 function as a plug or a wiring.

The insulating layer functioning as an interlayer film may also function as a planarization film that covers an uneven shape therebelow. For example, the top surface of the insulating layer 322 may be planarized by planarization treatment using a CMP method or the like to have improved planarity.

A wiring layer may be provided over the insulating layer 326 and the conductive layer 330. For example, in FIG. 18, an insulating layer 350, an insulating layer 352, and an insulating layer 354 are stacked in this order. Furthermore, a conductive layer 356 is formed in the insulating layer 350, the insulating layer 352, and the insulating layer 354. The conductive layer 356 functions as a plug or a wiring.

As the insulating layer 352, the insulating layer 354, and the like functioning as interlayer films, the above-described insulating layer that can be used for the semiconductor device or the memory device can be used.

For each of the conductive layers functioning as plugs or wirings, such as the conductive layer 328, the conductive layer 330, and the conductive layer 356, the conductive material that can be used for the conductive layer 140 and the conductive layer 240 can be used. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

The conductive layer 240 included in the transistor 200 is electrically connected to the low-resistance region 314b functioning as the source region or the drain region of the transistor 300 through a conductive layer 643, a conductive layer 642, a conductive layer 644, a conductive layer 645, a conductive layer 646, the conductive layer 356, the conductive layer 330, and the conductive layer 328.

The conductive layer 643 is embedded in the insulating layer 280. The conductive layer 644 is embedded in the insulating layer 180 and the insulating layer 150. The conductive layer 646 is embedded in the insulating layer 110. The conductive layer 642 is provided between the conductive layer 644 and the insulating layer 150, and the conductive layer 643 and the insulating layer 280. The conductive layer 645 is provided between the conductive layer 646 and the insulating layer 110, and the conductive layer 644 and the insulating layer 180. The conductive layer 642 can be formed using the same material in the same process as the conductive layer 220. The conductive layer 645 can be formed using the same material in the same process as the conductive layer 120. The transistor 300 and the conductive layer 120 are electrically insulated from each other by the insulating layer 110.

This embodiment can be combined with any of the other embodiments as appropriate. In this specification, in the case where a plurality of structure examples are shown in one embodiment, the structure examples can be combined as appropriate.

### Embodiment 3

In this embodiment, the semiconductor device 900 of one embodiment of the present invention will be described. The semiconductor device 900 can function as a memory device.

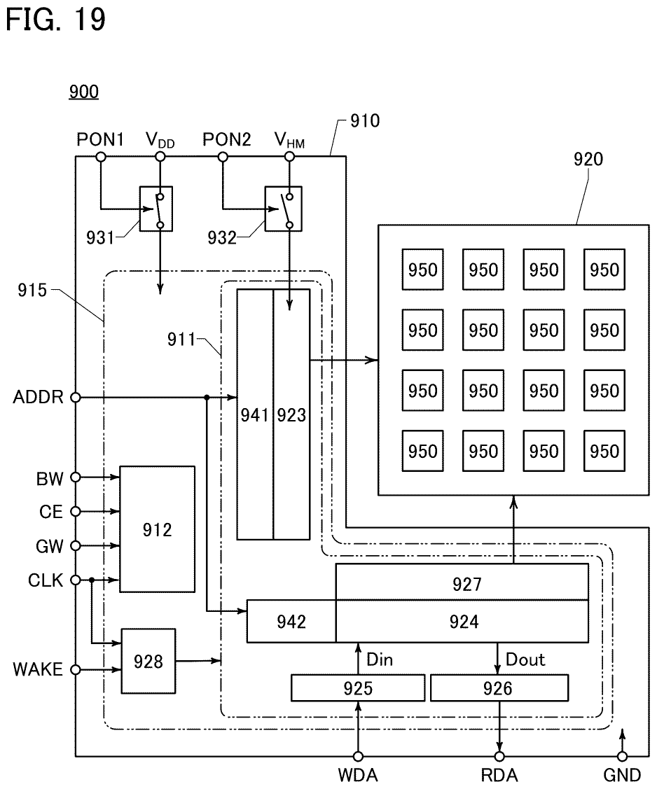

FIG. 19 is a block diagram illustrating a structure example of the semiconductor device 900. The semiconductor device 900 illustrated in FIG. 19 includes a driver circuit 910 and a memory array 920. The memory array 920 includes at least one memory cell 950. FIG. 19 illustrates an example in which the memory array 920 includes a plurality of memory cells 950 arranged in a matrix.

The memory device described in Embodiment 2 (the memory cell 10 or the like) can be used as the memory cell 950, for example.

The driver circuit 910 includes a power switch (PSW) 931, a PSW 932, and a peripheral circuit 915. The peripheral circuit 915 includes a peripheral circuit 911, a control circuit 912, and a voltage generator circuit 928.

In the semiconductor device 900, the circuits, signals, and voltages can be appropriately selected as needed. Another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal. The signal GW is a global write enable signal. The signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 912.

The control circuit 912 is a logic circuit having a function of controlling the overall operation of the semiconductor device 900. For example, the control circuit 912 performs logical operation on the signal CE, the signal GW, and the signal BW to determine the operating mode (e.g., write operation or read operation) of the semiconductor device 900. The control circuit 912 generates a control signal for the peripheral circuit 911 so that the operating mode is executed.

The voltage generator circuit 928 has a function of generating a negative voltage. The signal WAKE has a function of controlling the input of the signal CLK to the voltage generator circuit 928. For example, when an H-level signal is applied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925, an output circuit 926, and the sense amplifier 927.

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, reading data from the memory cell 950, and retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling the supply of VDD to the peripheral circuit 915. The PSW 932 has a function of controlling the supply of VHM to the row driver 923. Here, in the semiconductor device 900, a high power supply potential is VDD and a low power supply potential is GND (ground potential). In addition, V_{HM} is a high power supply potential used for setting a word line to high level, and is higher than V_{DD}. The on/off state of the PSW 931 is controlled by the signal PON1, and the on/off state of the PSW 932 is controlled by the signal PON2. The number of power domains to which V_{DD} is supplied is one in the peripheral circuit 915 in FIG. 19 but can be more than one. In that case, a power switch is provided for each power domain.

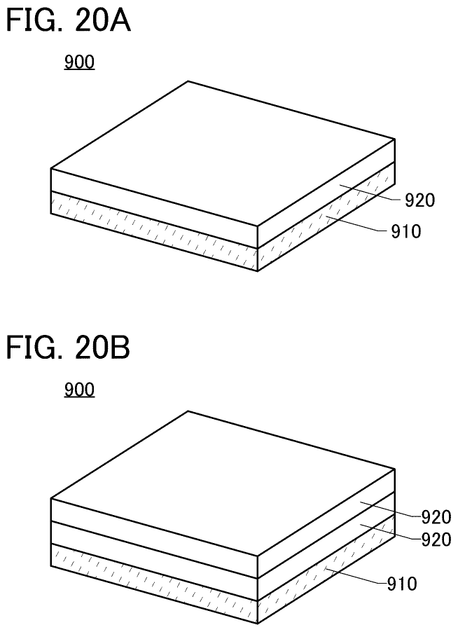

The driver circuit 910 and the memory array 920 included in the semiconductor device 900 may be provided on the same plane. Alternatively, as illustrated in FIG. 20A, the driver circuit 910 and the memory array 920 may be provided to overlap with each other. Overlapping the driver circuit 910 and the memory array 920 can shorten a signal propagation distance. As illustrated in FIG. 20B, a plurality of memory arrays 920 may be stacked over the driver circuit 910.

Next, description is made on an example of an arithmetic processing device that can include the semiconductor device, such as the memory device described above.

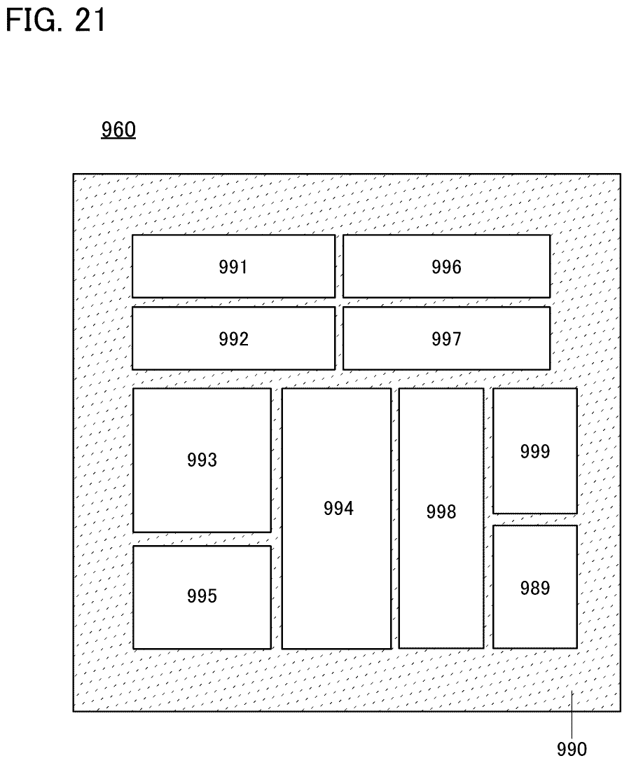

FIG. 21 is a block diagram of an arithmetic device 960. The arithmetic device 960 illustrated in FIG. 21 can be used for a CPU, for example. The arithmetic device 960 can also be used for a processor including a larger number of (several tens to several hundreds of) processor cores capable of parallel processing than a CPU, such as a graphics processing unit (GPU), a tensor processing unit (TPU), or a neural processing unit (NPU).

The arithmetic device 960 illustrated in FIG. 21 includes, over a substrate 990, an arithmetic logic unit (ALU) 991, an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in this case, the driver circuit 910 is preferably included in part of the cache interface 989.

Note that it is also possible that the cache 999 is not provided and only the memory array 920 is used as a cache.

The arithmetic device 960 illustrated in FIG. 21 is only an example with a simplified configuration, and the actual arithmetic device 960 has a variety of configurations depending on the application. For example, what is called a multicore configuration is preferably employed in which a plurality of cores each including the arithmetic device 960 in FIG. 21 operate in parallel. The larger number of cores can further enhance the arithmetic performance. The number of cores is preferably larger; for example, the number is preferably 2, further preferably 4, still further preferably 8, still further preferably 12, yet still further preferably 16 or larger. For application requiring extremely high arithmetic performance, e.g., a server, it is preferable to employ the multicore configuration including 16 or more, preferably 32 or more, further preferably 64 or more cores. The number of bits that the arithmetic device 960 can handle with an internal arithmetic circuit or a data bus can be 8, 16, 32, or 64, for example.

An instruction input to the arithmetic device 960 through the bus interface 998 is input to the instruction decoder 993 and decoded, and then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. The interrupt controller 994 judges and processes an interrupt request from an external input/output device, a peripheral circuit, or the like on the basis of its priority, a mask state, or the like while the arithmetic device 960 is executing a program. The register controller 997 generates the address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above circuits.

In the arithmetic device 960 in FIG. 21, the register controller 997 selects operation of retaining data in the register 996 in accordance with an instruction from the ALU 991. That is, the register controller 997 selects whether data is retained by a flip-flop or by a capacitor in a memory cell included in the register 996. When data retention by the flip-flop is selected, a power supply potential is supplied to the memory cell in the register 996. When data retention by the capacitor is selected, the data is rewritten into the capacitor, and supply of the power supply potential to the memory cell in the register 996 can be stopped.

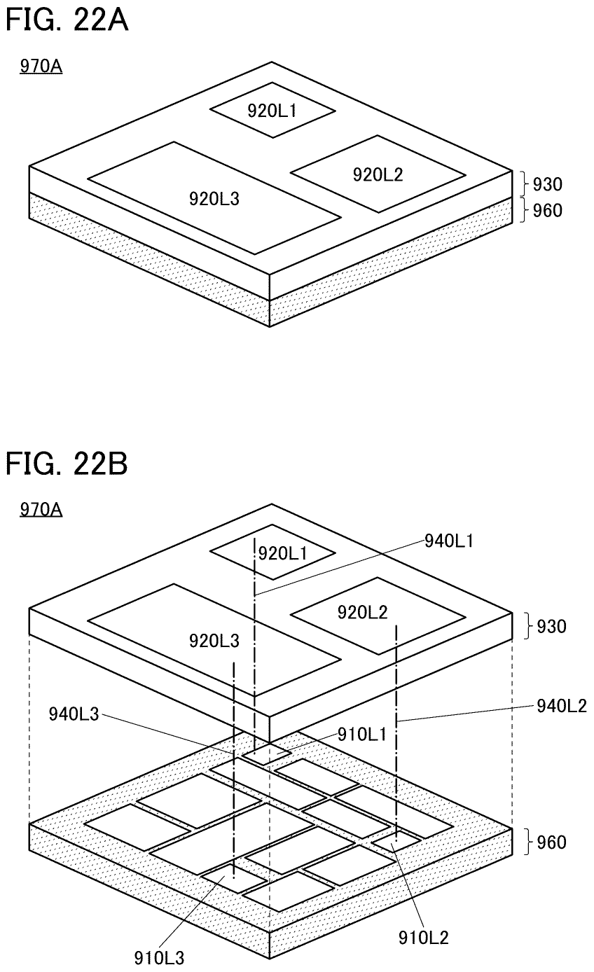

The memory array 920 and the arithmetic device 960 can be provided to overlap with each other. FIG. 22A and FIG. 22B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays include a region where they overlap with each other. For easy understanding of the structure of the semiconductor device 970A, the arithmetic device 960 and the layer 930 are separately illustrated in FIG. 22B.

Overlapping the arithmetic device 960 and the layer 930 including the memory arrays can shorten the connection distance therebetween. Accordingly, the communication speed therebetween can be increased. Moreover, a short connection distance leads to lower power consumption.

As a method for stacking the layer 930 including the memory arrays and the arithmetic device 960, either of the following methods may be employed: a method in which the layer 930 including the memory arrays is stacked directly on the arithmetic device 960 (also referred to as monolithic stacking) and a method in which the arithmetic device 960 and the layer 930 are formed over two different substrates, the substrates are bonded to each other, and the arithmetic device 960 and the layer 930 are electrically connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory arrays 920L1, 920L2, and 920L3 provided in the layer 930 are each used as a cache. In this case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 22B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Note that although the case where three memory arrays function as caches is described here, the number of memory arrays may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuit 910L2 and the driver circuit 910L3 may function as part of the cache interface 989 or be connected thereto.

Whether the memory array 920 functions as the cache or the main memory is determined by the control circuit 912 included in each of the driver circuits 910. The control circuit 912 can make some of the memory cells 950 in the semiconductor device 900 function as RAM in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

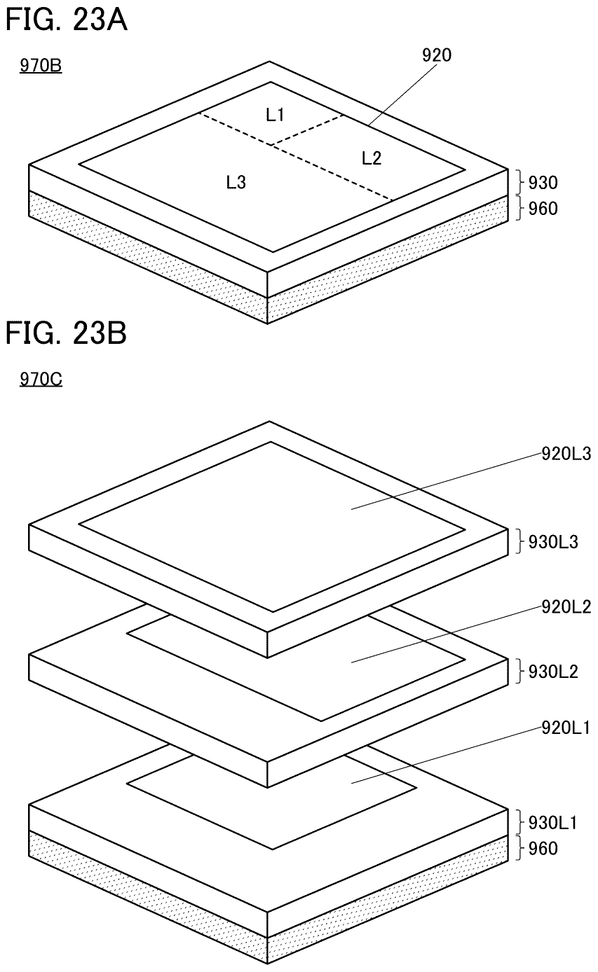

The layer 930 including one memory array 920 may be provided to overlap with the arithmetic device 960. FIG. 23A is a perspective view of a semiconductor device 970B.

In the semiconductor device 970B, one memory array 920 can be divided into a plurality of areas having different functions. FIG. 23A illustrates an example in which a region L1, a region L2, and a region L3 are used as the L1 cache, the L2 cache, and the L3 cache, respectively.

In the semiconductor device 970B, the capacity of each of the region L1 to the region L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 23B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

This embodiment can be combined with any of the other embodiments as appropriate. In this specification, in the case where a plurality of structure examples are shown in one embodiment, the structure examples can be combined as appropriate.

### Embodiment 4

In this embodiment, application examples of the memory device of one embodiment of the present invention will be described.

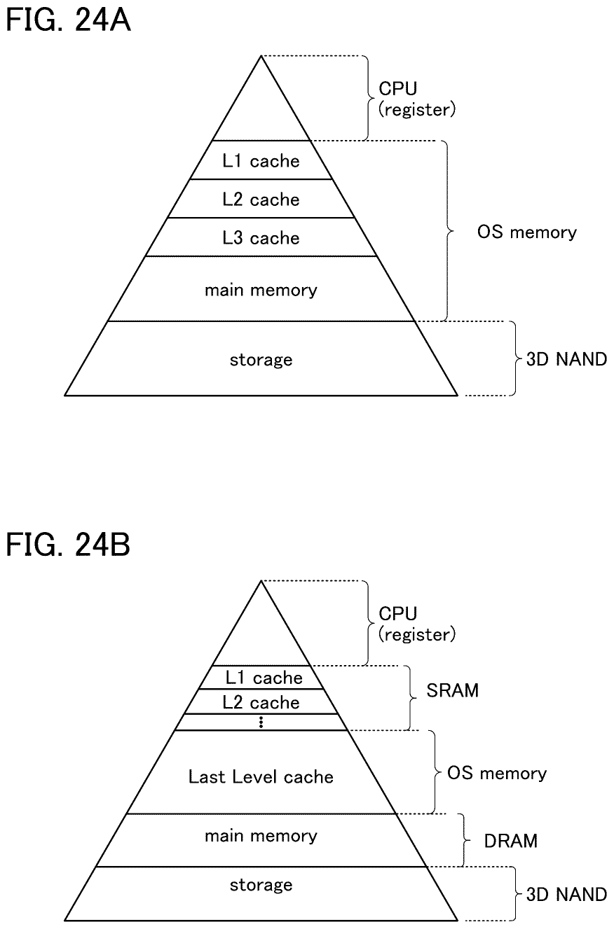

In general, a variety of memory devices are used in semiconductor devices such as computers in accordance with the intended use. FIG. 24A illustrates the hierarchy of various memory devices used in a semiconductor device. The memory devices at the upper levels require a higher operating speed, whereas the memory devices at the lower levels require a larger memory capacity and a higher memory density. FIG. 24A illustrates, for example, a memory included as a register in an arithmetic processing device such as a CPU, the L1 cache, the L2 cache, the L3 cache, a main memory, and a storage in this order from the uppermost layer. Although the caches up to the L3 cache are included in this example, a lower-level cache may be further included.

A memory included as a register in an arithmetic processing device such as a CPU is used for temporary storage of arithmetic operation results, for example, and thus is very frequently accessed by the arithmetic processing device. Accordingly, rapid operation is more important than the memory capacity of the memory. The register also has a function of retaining settings of the arithmetic processing device, for example.

The cache has a function of duplicating and retaining part of data retained in the main memory. Duplicating frequently used data and retaining the duplicated data in the cache facilitates rapid data access. The cache requires a smaller memory capacity than the main memory but a higher operating speed than the main memory. Data that is rewritten in the cache is duplicated, and the duplicated data is supplied to the main memory.

The main memory has a function of retaining a program and data that are read from the storage.

The storage has a function of retaining data that needs to be stored for a long time and programs used in an arithmetic processing device, for example. Therefore, the storage needs to have a high memory capacity and a high memory density rather than operating speed. For example, a high-capacity nonvolatile memory device such as a 3D NAND memory device can be used.

The memory device including an oxide semiconductor (the OS memory) of one embodiment of the present invention operates fast and can retain data for a long time. Thus, as illustrated in FIG. 24A, the memory device of one embodiment of the present invention can be favorably used at both the level including the cache and the level including the main memory. The memory device of one embodiment of the present invention can also be used at the level including the storage.

FIG. 24B illustrates an example in which an SRAM is used as some of the caches and the OS memory of one embodiment of the present invention is used as another one of the caches.

The lowest-level cache can be referred to as a last level cache (LLC). The LLC does not require a higher operation speed than a higher-level cache, but desirably has large storage capacity. The OS memory of one embodiment of the present invention operates at high speed and can retain data for a long time, and thus can be suitably used as the LLC. Note that the OS memory of one embodiment of the present invention can also be used as a final level cache (FLC).

For example, as illustrated in FIG. 24B, an SRAM can be used as the higher-level caches (the L1 cache, the L2 cache, and the like), and the OS memory of one embodiment of the present invention can be used as the LLC. Moreover, instead of the OS memory, a DRAM can be used as the main memory as illustrated in FIG. 24B.

This embodiment can be combined with any of the other embodiments as appropriate. In this specification, in the case where a plurality of structure examples are shown in one embodiment, the structure examples can be combined as appropriate.

### Embodiment 5

In this embodiment, application examples of the semiconductor device of one embodiment of the present invention are described.

The semiconductor device of one embodiment of the present invention can be used for an electronic component, a large computer, a device for space, a data center (also referred to as DC), and a variety of electronic apparatuses, for example. With the use of the semiconductor device of one embodiment of the present invention, an electronic component, a large computer, a device for space, a data center, and a variety of electronic apparatuses can have lower power consumption and higher performance.

Examples of the electronic apparatuses include a digital camera, a digital video camera, a digital photo frame, a mobile phone, a portable game console, a portable information terminal, and an audio reproducing device, in addition to electronic apparatuses with a relatively large screen, such as a television device, desktop and laptop personal computers, a monitor of a computer and the like, digital signage, and a large game machine such as a pachinko machine.

The electronic apparatus in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic apparatus in this embodiment can have a variety of functions. For example, the electronic apparatus in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

### Electronic Component

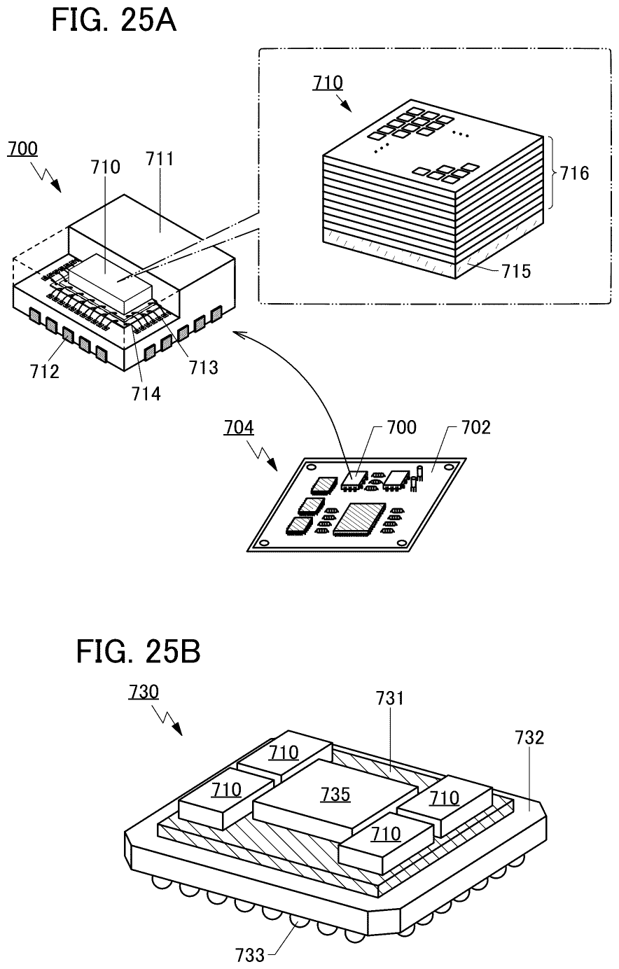

FIG. 25A is a perspective view of a substrate (a completed circuit board 704) provided with an electronic component 700. The electronic component 700 illustrated in FIG. 25A includes a semiconductor device 710 in a mold 711. FIG. 25A omits some components to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the completed circuit board 704.

The semiconductor device 710 includes a driver circuit layer 715 and a memory layer 716. The memory layer 716 has a structure where a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as a through silicon via (TSV) technique and a bonding technique such as Cu-Cu bonding. The monolithic stacked-layer structure of the driver circuit layer 715 and the memory layer 716 enables, for example, what is called an on-chip memory structure where a memory is directly formed on a processor. The on-chip memory structure allows an interface portion between the processor and the memory to operate at high speed.

With the on-chip memory structure, for example, the size of a connection wiring can be smaller than that in the case where the through electrode technique such as TSV is used, which means that the number of connection pins can be increased. The increase in the number of connection pins enables parallel operations, which can improve the bandwidth of the memory (also referred to as a memory bandwidth).

It is preferable that the plurality of memory cell arrays included in the memory layer 716 be formed with OS transistors and be monolithically stacked. Monolithically stacking the plurality of memory cell arrays can improve one or both of a memory bandwidth and a memory access latency. Note that the bandwidth refers to the data transfer volume per unit time, and the access latency refers to a period of time from data access to the start of data transmission. Note that in the case where the memory layer 716 is formed with Si transistors, the monolithic stacked-layer structure is difficult to form compared with the case where the memory layer 716 is formed with OS transistors. Therefore, an OS transistor is superior to a Si transistor in the monolithic stacked-layer structure.

The semiconductor device 710 may be called a die. Note that in this specification and the like, a die refers to a chip obtained by, for example, forming a circuit pattern on a disc-like substrate (also referred to as a wafer) and cutting the substrate with the pattern into dices in a manufacturing process of a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

FIG. 25B is a perspective view of an electronic component 730. The electronic component 730 is an example of a system in package (SiP) or a multi-chip module (MCM). In the electronic component 730, an interposer 731 is provided over a package substrate 732 (printed circuit board), and a semiconductor device 735 and a plurality of semiconductor devices 710 are provided over the interposer 731.

The electronic component 730 using the semiconductor device 710 as a high bandwidth memory (HBM) is illustrated as an example. The semiconductor device 735 can be used for an integrated circuit such as a CPU, a GPU, or a field programmable gate array (FPGA).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

In the case where a plurality of integrated circuits with different terminal pitches are electrically connected with use of a silicon interposer, a TSV, and the like, a space for a width of the terminal pitch and the like is needed. Accordingly, in the case where the size of the electronic component 730 is reduced, the width of the terminal pitch becomes an issue, which sometimes makes it difficult to provide a large number of wirings for obtaining a wide memory bandwidth. For this reason, the above-described monolithic stacked-layer structure with use of OS transistors is suitable. A composite structure combining memory cell arrays stacked using a TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on the bottom portion of the package substrate 732. FIG. 25B illustrates an example where the electrode 733 is formed of a solder ball. Solder balls are provided in a matrix on the bottom portion of the package substrate 732, so that ball grid array (BGA) mounting can be achieved. Alternatively, the electrode 733 may be formed of a conductive pin. When conductive pins are provided in a matrix on the bottom portion of the package substrate 732, pin grid array (PGA) mounting can be achieved.

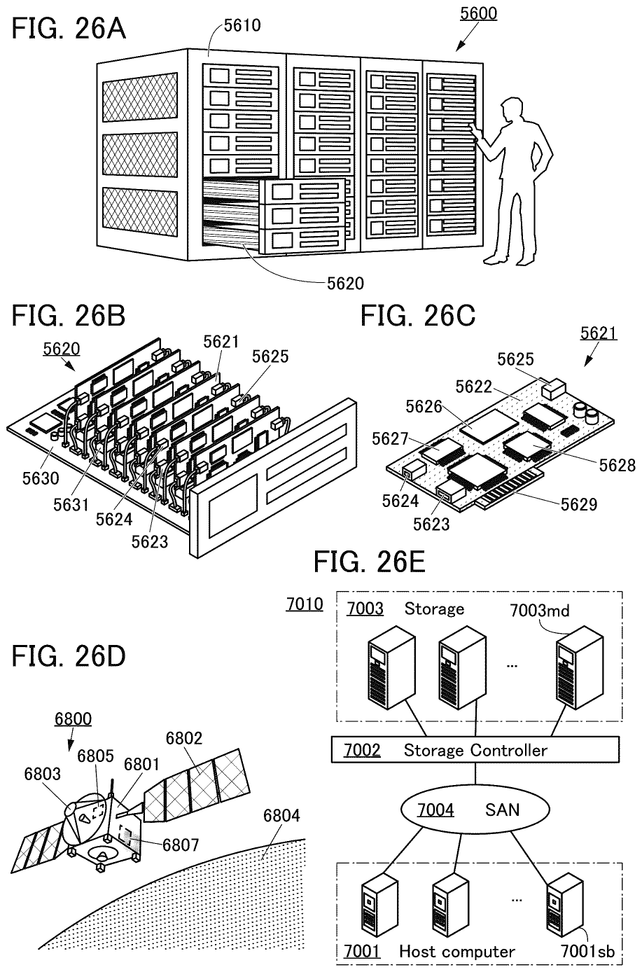

The electronic component 730 can be mounted on another substrate by various mounting methods other than BGA and PGA. Examples of a mounting method include staggered pin grid array (SPGA), land grid array (LGA), quad flat package (QFP), quad flat J-leaded package (QFJ), and quad flat non-leaded package (QFN).

[large Computer]
FIG. 26A is a perspective view of a large computer 5600. In the large computer 5600 illustrated in FIG. 26A, a plurality of rack mount computers 5620 are stored in a rack 5610. Note that the large computer 5600 may be referred to as a supercomputer.

The computer 5620 can have a structure illustrated in a perspective view in FIG. 26B, for example. In FIG. 26B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 26C is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 26C also illustrates semiconductor devices other than the semiconductor device 5626, the semiconductor device 5627, and the semiconductor device 5628, and the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. For another example, they can each serve as an interface for outputting a signal calculated by the PC card 5621. Examples of the standard for each of the connection terminal 5623, the connection terminal 5624, and the connection terminal 5625 include Universal Serial Bus (USB), Serial ATA (SATA), and Small Computer System Interface (SCSI). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### Device for Space

The semiconductor device of one embodiment of the present invention can be suitably used as a device for space.

The semiconductor device of one embodiment of the present invention includes an OS transistor. A change in electrical characteristics of the OS transistor due to radiation irradiation is small. That is, the OS transistor is highly resistant to radiation, and thus can be suitably used in an environment where radiation can enter. For example, the OS transistor can be suitably used in outer space. Specifically, the OS transistor can be used as a transistor in a semiconductor device provided in a space shuttle, an artificial satellite, or a space probe. Examples of radiation include X-rays and a neutron beam. Note that outer space refers to, for example, space at an altitude greater than or equal to 100 km, and outer space described in this specification may include one or more of thermosphere, mesosphere, and stratosphere.

FIG. 26D illustrates an artificial satellite 6800 as an example of a device for space. The artificial satellite 6800 includes a body 6801, a solar panel 6802, an antenna 6803, a secondary battery 6805, and a control device 6807. In FIG. 26D, a planet 6804 in outer space is illustrated as an example.

Although not illustrated in FIG. 26D, a battery management system (also referred to as BMS) or a battery control circuit may be provided in the secondary battery 6805. The battery management system or the battery control circuit preferably uses the OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics due to radiation irradiation is smaller in an OS transistor than in a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

As described above, an OS transistor has excellent effects of achieving a wide memory bandwidth and high radiation tolerance as compared with a Si transistor.

### Data Center

The semiconductor device of one embodiment of the present invention can be suitably used for, for example, a storage system in a data center. Long-term management of data, such as guarantee of data immutability, is required for the data center. The long-term management of data needs setting a storage and a server for retaining a huge amount of data, stable power supply for retaining data, cooling equipment for retaining data, an increase in building size, and the like.

With use of the semiconductor device of one embodiment of the present invention for a storage system in a data center, electric power used for retaining data can be reduced and a semiconductor device for retaining data can be downsized. Accordingly, downsizing of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

FIG. 26E illustrates a storage system that can be used in a data center. A storage system 7010 illustrated in FIG. 26E includes a plurality of servers 7001sb as a host 7001 (indicated as “Host Computer” in the diagram). The storage system 7010 includes a plurality of memory devices 7003md as a storage 7003 (indicated as “Storage” in the diagram). In the illustrated example, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in the storage to shorten the time taken for storing and outputting data.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

With a structure in which an OS transistor is used as a transistor for storing data in the cache memory to retain a potential based on data, the frequency of refreshing can be decreased, so that power consumption can be reduced. Furthermore, downscaling is possible by stacking memory cell arrays.

This embodiment can be combined with any of the other embodiments as appropriate. In this specification, in the case where a plurality of structure examples are shown in one embodiment, the structure examples can be combined as appropriate.

### REFERENCE NUMERALS

10a: memory cell, 10b: memory cell, 10c: memory cell, 10d: memory cell, 10: memory cell, 13: wiring, 15: wiring, 21: wiring, 23: wiring, 60: memory layer, 100A: transistor, 100a: transistor, 100B: transistor, 100b: transistor, 100C: transistor, 100D: transistor, 100E: transistor, 100F: transistor, 100G: transistor, 100H: transistor, 100: transistor, 110: insulating layer, 120a: conductive layer, 120b: conductive layer, 120n: region, 120: conductive layer, 122: insulating layer, 130a: oxide layer, 130b: oxide layer, 130i: region, 130n: region, 130: semiconductor layer, 140a: conductive layer, 140b: conductive layer, 140n: region, 140: conductive layer, 145: conductive layer, 150: insulating layer, 155: conductive layer, 180a: insulating layer, 180b: insulating layer, 180c: insulating layer, 180d: insulating layer, 180e: insulating layer, 180i: region, 180: insulating layer, 188: halogen element, 189: impurity element, 190a: opening portion, 190b: opening portion, 190: opening portion, 191: depressed portion, 200A: transistor, 200a: transistor, 200B: transistor, 200b: transistor, 200C: transistor, 200D: transistor, 200E: transistor, 200F: transistor, 200G: transistor, 200H: transistor, 200: transistor, 220a: conductive layer, 220b: conductive layer, 220: conductive layer, 230a: oxide layer, 230b: oxide layer, 230n: region, 230: semiconductor layer, 240a: conductive layer, 240b: conductive layer, 240: conductive layer, 245: conductive layer, 247: conductive layer, 248: conductive layer, 250: insulating layer, 255: conductive layer, 260a: conductive layer, 260b: conductive layer, 260: conductive layer, 262: sacrificial layer, 265: conductive layer, 270: opening portion, 280a: insulating layer, 280b: insulating layer, 280c: insulating layer, 280d: insulating layer, 280e: insulating layer, 280i: region, 280: insulating layer, 283: insulating layer, 285: insulating layer, 287: insulating layer, 290a: opening portion, 290b: opening portion, 290: opening portion, 291: depressed portion, 300: transistor, 311: substrate, 313: semiconductor region, 314a: low-resistance region, 314b: low-resistance region, 315: insulating layer, 316: conductive layer, 320: insulating layer, 322: insulating layer, 324: insulating layer, 326: insulating layer, 328: conductive layer, 330: conductive layer, 350: insulating layer, 352: insulating layer, 354: insulating layer, 356: conductive layer, 370a: oxide semiconductor layer, 370b: oxide semiconductor layer, 370c: oxide semiconductor layer, 370d: oxide semiconductor layer, 372a: region, 372b: region, 372c: region, 642: conductive layer, 643: conductive layer, 644: conductive layer, 645: conductive layer, 646: conductive layer, 700: electronic component, 702: printed circuit board, 704: completed circuit board, 710: semiconductor device, 711: mold, 712: land, 713: electrode pad, 714: wire, 715: driver circuit layer, 716: memory layer, 730: electronic component, 731: interposer, 732: package substrate, 733: electrode, 735: semiconductor device, 900: semiconductor device, 910: driver circuit, 911: peripheral circuit, 912: control circuit, 915: peripheral circuit, 920: memory array, 923: row driver, 924: column driver, 925: input circuit, 926: output circuit, 927: sense amplifier, 928: voltage generator circuit, 930: layer, 931: PSW, 932: PSW, 941: row decoder, 942: column decoder, 950: memory cell, 960: arithmetic device, 970A: semiconductor device, 970B: semiconductor device, 970C: semiconductor device, 989: cache interface, 990: substrate, 991: ALU, 992: ALU controller, 993: instruction decoder, 994: interrupt controller, 995: timing controller, 996: register, 997: register controller, 998: bus interface, 999: cache, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6800: artificial satellite, 6801: body, 6802: solar panel, 6803: antenna, 6804: planet, 6805: secondary battery, 6807: control device, 7001sb: server, 7001: host, 7002: storage control circuit, 7003md: memory device, 7003: storage, 7010: storage system

1. A semiconductor device comprising:
a first transistor, a second transistor, a first insulating layer, a second insulating layer and a third insulating layer,
wherein the first transistor comprises a first semiconductor layer, a first conductive layer, a second conductive layer, a third conductive layer and a fourth insulating layer,
wherein the second transistor comprises a second semiconductor layer, the third conductive layer, a fourth conductive layer, a fifth conductive layer and a fifth insulating layer,
wherein the first insulating layer is over the first conductive layer,
wherein the second conductive layer is over the first insulating layer,
wherein the first conductive layer comprises a first depressed portion,
wherein the first insulating layer and the second conductive layer have a first opening portion in a position overlapping with the first depressed portion,
wherein the first semiconductor layer is in contact with a top surface of the second conductive layer and the first depressed portion,
wherein the first semiconductor layer is in contact with a side surface of the second conductive layer and a side surface of the first insulating layer in the first opening portion,
wherein the fourth insulating layer comprises a first region and a second region,
wherein the first region is over the second conductive layer,
wherein the second region is over the first semiconductor layer in the first opening portion,
wherein the third conductive layer comprises a region facing the first semiconductor layer with the fourth insulating layer therebetween in the first opening portion,
wherein the third conductive layer comprises a region overlapping with the second conductive layer with the fourth insulating layer therebetween,
wherein the third conductive layer comprises a second depressed portion,
wherein the second insulating layer is over the third conductive layer,
wherein the fourth conductive layer is over the second insulating layer,
wherein the second insulating layer and the fourth conductive layer have a second opening portion in a position overlapping with the second depressed portion,
wherein the second semiconductor layer is in contact with a top surface of the fourth conductive layer and the second depressed portion,
wherein the second semiconductor layer is in contact with a side surface of the fourth conductive layer and a side surface of the second insulating layer in the second opening portion,
wherein the fifth insulating layer is located over the second semiconductor layer in the second opening portion,
wherein the third insulating layer comprises a region overlapping with the fourth conductive layer with the second semiconductor layer therebetween,
wherein the third insulating layer has a third opening portion,
wherein the third opening portion and the second opening portion overlap each other, and
wherein the fifth conductive layer comprises a region facing the second semiconductor layer with the fifth insulating layer therebetween in the second opening portion and a region located in the third opening portion.

2. The semiconductor device according to claim 1, wherein at least a part of the second opening portion overlaps with the first opening portion.

3. The semiconductor device according to claim 1, further comprising a sixth insulating layer,
wherein each of the first insulating layer and the first conductive layer is over the sixth insulating layer,
wherein a first top surface of the first conductive layer is in contact with the first insulating layer,
wherein a second top surface of the first conductive layer is in contact with the first semiconductor layer,
wherein a first bottom surface of the fourth insulating layer and the first depressed portion overlap each other,
wherein a second bottom surface of the fourth insulating layer is over the second conductive layer,
wherein a first top surface of the third conductive layer is in contact with the second insulating layer,
wherein a second top surface of the third conductive layer is in contact with the second semiconductor layer,
wherein a first bottom surface of the fifth insulating layer and the second depressed portion overlap each other,
wherein a shortest distance from a top surface of the sixth insulating layer to the first top surface of the first conductive layer is longer than a shortest distance from the top surface of the sixth insulating layer to the first bottom surface of the fourth insulating layer, and
wherein a shortest distance from the top surface of the sixth insulating layer to the first top surface of the third conductive layer is longer than a shortest distance from the top surface of the sixth insulating layer to the first bottom surface of the fifth insulating layer.

4. The semiconductor device according to claim 1, further comprising a sixth insulating layer,
wherein each of the first insulating layer and the first conductive layer is over the sixth insulating layer,
wherein a first top surface of the first conductive layer is in contact with the first insulating layer,
wherein a second top surface of the first conductive layer is in contact with the first semiconductor layer,
wherein a first bottom surface of the third conductive layer and the first depressed portion overlap each other,
wherein a second bottom surface of the third conductive layer is over the second conductive layer,
wherein a first top surface of the third conductive layer is in contact with the second insulating layer,
wherein a second top surface of the third conductive layer is in contact with the second semiconductor layer,
wherein a first bottom surface of the fifth conductive layer and the second depressed portion overlap each other,
wherein a second bottom surface of the fifth conductive layer is over the fourth conductive layer.
wherein a shortest distance from a top surface of the sixth insulating layer to the first top surface of the first conductive layer is longer than or equal to a shortest distance from the top surface of the sixth insulating layer to the first bottom surface of the third conductive layer, and
wherein a shortest distance from the top surface of the sixth insulating layer to the first top surface of the third conductive layer is longer than or equal to a shortest distance from the top surface of the sixth insulating layer to the first bottom surface of the fifth conductive layer.

5. The semiconductor device according to claim 1,
wherein the first conductive layer comprises a sixth conductive layer and a seventh conductive layer over the sixth conductive layer,
wherein the third conductive layer comprises an eighth conductive layer and a ninth conductive layer over the eighth conductive layer,
wherein the seventh conductive layer comprises the first depressed portion, and
wherein the ninth conductive layer comprises the second depressed portion.

6. The semiconductor device according to claim 1, further comprising a sixth conductive layer,
wherein the sixth conductive layer is provided in contact with a top surface of the fifth conductive layer.

7. The semiconductor device according to claim 6, wherein a thickness of the third insulating layer in a region overlapping with the fourth conductive layer and the second semiconductor layer is greater than a thickness of the fourth insulating layer.

8. The semiconductor device according to claim 1, wherein at least a part of the fifth insulating layer is located in the third opening portion.

9. The semiconductor device according to claim 1,
wherein the first transistor further comprises a sixth conductive layer,
wherein the second transistor further comprises a seventh conductive layer,
wherein the first insulating layer comprises a first layer and a second layer over the first layer,
wherein the second insulating layer comprises a third layer and a fourth layer over the third layer,
wherein the sixth conductive layer is over the first layer,
wherein the seventh conductive layer is over the third layer,
wherein the second layer covers a top surface and a side surface of the sixth conductive layer,
wherein the fourth layer covers a top surface and a side surface of the seventh conductive layer,
wherein, in a cross-sectional view, the first semiconductor layer comprises a region facing the sixth conductive layer with the second layer therebetween and facing the third conductive layer with the fourth insulating layer therebetween, and
wherein, in the cross-sectional view, the second semiconductor layer comprises a region facing the seventh conductive layer with the fourth layer therebetween and facing the fifth conductive layer with the fifth insulating layer therebetween.

10. The semiconductor device according to claim 1,
wherein each of the first semiconductor layer and the second semiconductor layer comprises an oxide semiconductor,
wherein the oxide semiconductor comprises one or more elements selected from indium, an element Mand zinc, and
wherein the element Mis one or more kinds of elements selected from aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium and antimony.

11. The semiconductor device according to claim 10,
wherein the first insulating layer comprises a third region in contact with the first semiconductor layer,
wherein the second insulating layer comprises a fourth region in contact with the second semiconductor layer, and
wherein each of the third region and the fourth region comprises a halogen element.

12. The semiconductor device according to claim 11, wherein the halogen element is one or more kinds selected from chlorine, fluorine, bromine and iodine.

13. The semiconductor device according to claim 10,
wherein the first semiconductor layer comprises a first portion in contact with a bottom surface of the first depressed portion and a second portion in contact with the top surface of the second conductive layer,
wherein the second semiconductor layer comprises a third portion in contact with a bottom surface of the second depressed portion and a fourth portion in contact with the top surface of the fourth conductive layer, and
wherein each of the first to fourth portions comprises boron or phosphorus.

14. A method for manufacturing a semiconductor device, the method comprising the steps of:
forming a first conductive layer;
forming a first insulating layer over the first conductive layer;
forming a second conductive layer over the first insulating layer;
processing the second conductive layer, the first insulating layer and the first conductive layer:
to form a first opening portion in the second conductive layer and the first insulating layer in a position overlapping with the first conductive layer; and
to form a first depressed portion in the first conductive layer;
forming a first semiconductor layer so that:
the first semiconductor layer is in contact with a top surface of the second conductive layer and the first depressed portion; and
the first semiconductor layer is in contact with a side surface of the second conductive layer and a side surface of the first insulating layer in the first opening portion;
processing the first semiconductor layer and the second conductive layer to expose a part of a top surface of the first insulating layer;
forming a second insulating layer so that:
a first region of the second insulating layer is over the second conductive layer; and
a second region of the second insulating layer is over the first semiconductor layer in the first opening portion;
forming a third conductive layer so that:
a first region of the third conductive layer and the first semiconductor layer face each other with the second insulating layer therebetween in the first opening portion; and
a second region of the third conductive layer and the second conductive layer with the second insulating layer therebetween;
forming a third insulating layer over the third conductive layer;
forming a fourth conductive layer over the third insulating layer;
processing the fourth conductive layer and the third insulating layer:
to form a second opening portion in the fourth conductive layer and the third insulating layer in a position overlapping with the third conductive layer; and
to form a second depressed portion in the third conductive layer;
forming a second semiconductor layer so that:
the second semiconductor layer is in contact with a top surface of the fourth conductive layer and the second depressed portion; and
the second semiconductor layer is in contact with a side surface of the fourth conductive layer and a side surface of the third insulating layer in the second opening portion;
processing the second semiconductor layer and the fourth conductive layer to expose a part of a top surface of the third insulating layer;
forming a sacrificial layer such that at least a part of the sacrificial layer is formed in the second opening portion;
forming a fourth insulating layer so as to cover the fourth conductive layer, the second semiconductor layer and the sacrificial layer;
performing planarization treatment on the fourth insulating layer and the sacrificial layer to planarize a top surface of the sacrificial layer;
removing the sacrificial layer after the planarization treatment;
forming a fifth insulating layer so as to cover the second opening portion;
forming a fifth conductive layer over the fifth insulating layer; and
performing planarization treatment on the fifth conductive layer to remove regions of the fifth conductive layer and the fifth insulating layer that overlap with a top surface of the fourth insulating layer,
wherein the first depressed portion and the first opening portion overlap each other, and
wherein the second depressed portion and the second opening portion overlap each other.

15. The method for manufacturing a semiconductor device, according to claim 14, wherein the second opening portion is formed such that at least a part of the second opening portion and the first opening portion overlap each other.

16. The method for manufacturing a semiconductor device, according to claim 14, further comprising the step of:
forming a sixth conductive layer so that the sixth conductive layer is in contact with a top surface of the fifth conductive layer.

17. The method for manufacturing a semiconductor device, according to claim 16, wherein the fourth insulating layer is formed to have a thickness greater than that of the second insulating layer.
